(19) United States
(12) Patent Application Publication
(10) Pub. No.: US 2007/0080317 A1
(43) Pub. Date: Apr. 12, 2007

(54) PIEZOELECTRIC CERAMIC COMPOSITION AND LAMINATED PIEZOELECTRIC ELEMENT

(75) Inventors: Kumiko Iezumi, Chuo-ku, Tokyo (JP); Junichi Yamazaki, Tokyo (JP); Takeo Tsukada, Chuo-ku, Tokyo (JP); Norimasa Sakamoto, Chuo-ku, Tokyo (JP); Tomohiro Sogabe, Chuo-ku, Tokyo (JP); Masaru Nanao, Chuo-ku, Tokyo (JP)

Correspondence Address: PEARNE & GORDON LLP, 1801 EAST 9TH STREET, SUITE 1200, CLEVELAND, OH, 44114-3108, US

(73) Assignee: TDK CORPORATION, Tokyo (JP)

(21) Appl. No.: 11/538,089

(22) Filed: Oct. 3, 2006

(30) Foreign Application Priority Data
Oct. 4, 2005 (JP) 2005-291761
Oct. 5, 2005 (JP) 2005-292637
Dec. 21, 2005 (JP) 2005-367444
Mar. 2, 2006 (JP) 2006-056767
Mar. 3, 2006 (JP) 2006-057079
Mar. 8, 2006 (JP) 2006-063243

(51) Int. Cl. C04B 35/00; H01L 41/00; H02N 2/00

(52) U.S. Cl. 252/62.9 PZ; 501/134; 310/311

(57) ABSTRACT

For the purpose of preventing the degradation of the piezoelectric strain properties when Cu is used for internal electrodes, there is provided a piezoelectric ceramic composition including: a composite oxide, as a main constituent thereof, represented by (Pb_{a-b}Me_{b}) [(Zn_{1/3}Nb_{2/3})ₓTi_{y}Zr_{z}]O₃ with the proviso that 0.96≦a≦1.03, 0≦b≦0.1, 0.05≦x≦0.15, 0.25≦y≦0.5, 0.35≦z≦0.6, and x+y+z=1, and Me represents at least one selected from Sr, Ca and Ba; and at least one selected from Co, Mg, Ni, Cr and Ga as a first additive to the main constituent in a content of 0.5% by mass or less (not inclusive of 0) in terms of oxide, wherein an electrode made of Cu is to be disposed on the piezoelectric ceramic composition.

### BACKGROUND OF THE INVENTION

1. Field of the Invention

The present invention relates to a piezoelectric ceramic composition suitable for piezoelectric layers in various piezoelectric elements in devices such as an actuator, piezoelectric buzzer, a sound component and a sensor, in particular, to a piezoelectric ceramic composition also suitable for piezoelectric layers in a laminated piezoelectric element using Cu for internal electrodes and a laminated piezoelectric element using the composition concerned.

2. Description of the Related Art

Piezoelectric ceramic compositions to be used in piezoelectric elements are required to be large in piezoelectric properties, in particular, in piezoelectric strain constant. As piezoelectric ceramic compositions satisfying such properties, there have been developed, for example, a ternary piezoelectric ceramic composition containing lead titanate (PbTiO₃), lead zirconate (PbZrO₃) and lead zincate niobate [Pb(Zn_{1/3}Nb_{2/3})O₃], a piezoelectric ceramic composition in which the Pb in the above-mentioned ternary piezoelectric ceramic composition is partially substituted with Sr, Ba, Ca or the like, and other piezoelectric ceramic compositions.

However, these conventional piezoelectric ceramic compositions require sintering at relatively high temperatures exceeding 1200° C., and undergo sintering in an oxidative atmosphere; consequently, for example, in laminated piezoelectric elements in which internal electrodes are simultaneously sintered, it has been necessary to use noble metals (such as Pt and Pd) that are high in melting point and are not oxidized even when sintered in an oxidative atmosphere. As a result, the increase in cost is caused to offer an obstacle to price reduction of manufactured laminated piezoelectric elements.

Under these circumstances, the present applicant has proposed to enable low temperature sintering by adding a first additive containing at least one selected from Fe, Co, Ni and Cu and a second additive containing at least one selected from Sb, Nb and Ta to the above-mentioned ternary piezoelectric ceramic compositions, and consequently to make low price materials such as a Ag—Pd alloy usable for internal electrodes (see Japanese Patent Laid-Open No. 2004-137106).

The invention of Japanese Patent Laid-Open No. 2004-137106 is such that there is realized a piezoelectric ceramic composition having a high piezoelectric strain constant, and being densified without impairing various piezoelectric properties and being increased in mechanical strength even when sintered at low temperatures, by adding the first additive containing at least one selected from Fe, Co, Ni and Cu, and the second additive containing at least one selected from Sb, Nb and Ta in the above-mentioned ternary piezoelectric ceramic composition and in the piezoelectric ceramic composition in which Pb in the above-mentioned ternary piezoelectric ceramic composition is partially substituted with Sr, Ba, Ca or the like, and there is also provided a piezoelectric element having piezoelectric layers formed by using the thus realized piezoelectric ceramic composition.

### SUMMARY OF THE INVENTION

When internal electrodes are formed with a lower price metal (such as Cu), there occurs a disadvantage such that sintering in an oxidative atmosphere (for example, in air) oxidizes the internal electrodes to impair the conductivity even in a case where the sintering is carried out at a low temperature. To overcome such a disadvantage, the sintering is required to be carried out in a reductive atmosphere having a low oxygen partial pressure (for example, an oxygen partial pressure of the order of 1×10⁻¹⁰ to 1×10⁻⁶ atm). However, such sintering in a reductive atmosphere has encountered a problem that the piezoelectric properties are impaired although the oxidation of the internal electrodes themselves can be prevented.

Such sintering in a reductive atmosphere abundantly generates oxygen vacancies in the crystal of a piezoelectric ceramic composition because of the extreme scarcity of oxygen in the atmosphere, as compared to sintering in air. The presence of such oxygen vacancies degrades the electric resistance of the piezoelectric ceramic composition at high temperatures (for example, 150° C.). A temperature region about 150° C. is sometimes included in a specified operating temperature range of a product, and accordingly, the degradation of the electric resistance of a piezoelectric ceramic composition seriously affects the reliability of the product.

In these years, demand for size reduction and sophistication of various products leads to demand for size reduction and sophistication for actuators to be used in such products. Size reduction of an actuator element while preserving the displacement magnitude thereof necessitates a piezoelectric ceramic composition that has further higher piezoelectric properties. In particular, a development challenge is to search out a piezoelectric ceramic composition that attains high piezoelectric properties even by low temperature sintering.

Accordingly, an object of the present invention is to provide a piezoelectric ceramic composition that does not degrade the piezoelectric properties even when Cu is used as a conductive material for internal electrodes, and further even when low temperature sintering is carried out.

Another object of the present invention is to provide a piezoelectric ceramic composition that can inhibit the degradation of the electric resistance to be caused by the oxygen vacancies due to sintering at low temperatures and in a reductive atmosphere.

Yet another object of the present invention is to provide a laminated piezoelectric element using such a piezoelectric ceramic composition.

The present inventors have investigated the cause for the degradation of the piezoelectric properties in a case where Cu is used as a conductive material for internal electrodes, and have found that Cu diffuses from the internal electrodes into the piezoelectric layers and the grain growth in the piezoelectric layers is inhibited. Consequently, the present inventors have interpreted that the diffusion of Cu into the piezoelectric layers and the insufficient grain growth cause the piezoelectric property degradation. Accordingly, the present inventors have studied the additives to be added to a piezoelectric ceramic composition, and have found that: a trace addition, as an additive, of a component containing at least one selected from Co, Mg, Ni, Cr and Ga can serve to maintain high piezoelectric properties even in a case where Cu diffuses into the piezoelectric layers; and specification of the additive amount of such an additive amazingly leads to an extremely special effect that higher piezoelectric properties are attained with Cu diffusion than without Cu diffusion.

The present invention is based on the above-mentioned findings, and is a piezoelectric ceramic composition containing: a composite oxide, as a main constituent thereof, represented by a composition formula A, (Pb_{a-b}Me_{b}) [(Zn_{1/3}Nb_{2/3})ₓTi_{y}Zr_{z}]O₃, with the proviso that 0.96≦a≦1.03, 0≦b≦0.1, 0.05≦x≦0.15, 0.25≦y≦0.5, 0.35≦z≦0.6, and x+y+z=1, Me in the formula representing at least one selected from Sr, Ca and Ba; and at least one selected from Co, Mg, Ni, Cr and Ga, as a first additive to the main constituent, in a content of 0.5% by mass or less (not inclusive of 0) in terms of oxide, wherein electrodes made of Cu are to be disposed on the piezoelectric ceramic composition.

The first additive preferably contains at least one selected from Co, Mg and Ga in a content of 0.03 to 0.4% by mass in terms of oxide.

The present inventors have also found that, in addition to the above-mentioned first additive, addition of one or both of a rare earth metal oxide and Ag₂O attains further higher piezoelectric properties.

More specifically, the present invention contains the composite oxide represented by the composition formula A as the main constituent, and at least one selected from Co, Mg, Ni, Cr and Ga as the first additive in a content of 0.5% by mass or less (not inclusive of 0) in terms of oxide in relation to the main constituent. The present invention also contains a rare earth metal element as a second additive in a content of 0.15% by mass or less (not inclusive of 0) in terms of oxide in relation to the main constituent. Yet also, the present invention contains Ag as a third additive in a content of 0.08% by mass or less (not inclusive of 0) in terms of Ag₂O in relation to the main constituent. One or both of the second additive and the third additive are contained, with the proviso that the content of the third additive for the case where both additives are contained is such that Ag is contained in a content of 0.35% by mass or less (not inclusive of 0) in terms of Ag₂O.

In the piezoelectric ceramic composition, preferably, Co is selected as the first additive and is contained in a content of 0.5% by mass or less in terms of oxide, and Dy is selected as the second additive and is contained in a content of 0.15% by mass or less in terms of oxide.

Also, preferably, the first additive is contained in a content of 0.03 to 0.4% by mass in terms of oxide, and as for the second additive, a rare earth metal element is contained in a content of 0.02 to 0.1% by mass in terms of oxide, and as for the third additive, Ag is contained in a content of 0.02 to 0.25% by mass in terms of Ag₂O. The preferable amount of the third additive as referred to herein means a value for the concomitant inclusion of the second additive.

The above-mentioned piezoelectric ceramic composition preferably contains at least one selected from Ta, Sb, Nb and W, as a fourth additive, in a content of 1.0% by mass or less (not inclusive of 0) in terms of oxide.

The present invention provides a laminated piezoelectric element using the above-mentioned piezoelectric ceramic composition. The laminated piezoelectric element includes a plurality of piezoelectric layers formed of the piezoelectric ceramic composition, and a plurality of Cu-containing internal electrode layers formed between the piezoelectric layers. This laminated piezoelectric element can attain high piezoelectric properties even when the Cu contained in the internal electrodes diffuses into the piezoelectric layers.

In the laminated piezoelectric element of the present invention, the above-mentioned main constituent composition and the inclusion of the fourth additive are acceptable.

The present invention also provides a below described laminated piezoelectric element containing the second additive and the third additive. This laminated piezoelectric element includes a plurality of piezoelectric layers containing a composite oxide represented by the composition formula A as a main constituent and a plurality of internal electrode layers formed between the piezoelectric layers, wherein the piezoelectric layers are formed of a sintered body containing, in relation to the main constituent: at least one selected from Co, Mg, Ni, Cr and Ga, as the first additive, in a content of 0.5% by mass or less (not inclusive of 0) in terms of oxide; a rare earth metal element, as the second additive, in a content of 0.15% by mass or less (not inclusive of 0) in terms of oxide; and Ag, as the third additive, in a content of 0.35% by mass or less (not inclusive of 0) in terms of Ag₂O.

The above-mentioned laminated piezoelectric elements according to the present invention can be manufactured by carrying out a step for obtaining a laminate in which composite oxide-containing piezoelectric layer precursors and Cu-containing internal electrode precursors are laminated with each other, and a sintering step for sintering the laminate in a reductive atmosphere. The sintering in a reductive atmosphere is preferably carried out at a sintering temperature of 800° C. to 1200° C. under an oxygen partial pressure of 1×10⁻¹⁰ to 1×10⁻⁶ atm.

As described above, the presence of Cu in the piezoelectric layers degrades the piezoelectric properties. However, there has been obtained a finding that the presence of Cu in the piezoelectric layers overcomes the electric resistance degradation at high temperatures. On the other hand, the above-mentioned second additive is effective against the degradation of the piezoelectric properties. Accordingly, the presence of Cu and the concomitant inclusion of the second additive make it possible to obtain a piezoelectric ceramic composition excellent in electric resistance at high temperatures and in piezoelectric properties.

Consequently, the present invention provides a piezoelectric ceramic composition containing: the composite oxide represented by the composition formula A as the main constituent; at least one of the components represented by CuO_{α} (α≧0) in a content of 3.0% by mass or less (not inclusive of 0) in terms of CuO in relation to the main constituent; and a rare earth metal element in a content of 0.8% by mass or less (not inclusive of 0) in terms of oxide.

The piezoelectric ceramic composition of the present invention preferably contains at least one selected from Ta, Sb, Nb and W in a content of 1.0% by mass or less (not inclusive of 0) in terms of oxide.

The laminated piezoelectric element of the present invention, using the above-mentioned piezoelectric ceramic composition, includes a plurality of piezoelectric layers containing a composite oxide as the main constituent and a plurality of Cu-containing internal electrode layers formed between the piezoelectric layers, wherein the piezoelectric layers contain: the composite oxide represented by the composition formula A as the main constituent; at least one of the components represented by CuO_{α} (α≧0) in a content of 3.0% by mass or less (not inclusive of 0) in terms of CuO in relation to the main constituent; and a rare earth metal element in a content of 0.8% by mass or less (not inclusive of 0) in terms of oxide.

As described above, the piezoelectric layers preferably contains at least one selected from Ta, Sb, Nb and W, in a content of 1.0% by mass or less (not inclusive of 0) in terms of oxide.

The above-mentioned laminated piezoelectric element has as one of the features thereof a fact that the piezoelectric layers contain at least one of the components represented by CuO_{α} (α≧0), in a content of 3.0% by mass or less (not inclusive of 0) in terms of CuO. The CuO_{α} (α≧0) in the piezoelectric layers can be formed by diffusing CuO_{α} (α≧0) from the internal electrode layers or by adding CuO_{α} (α≧0) into the piezoelectric layers. Accordingly, the present invention is a production method of a laminated piezoelectric element including a plurality of piezoelectric layers containing the composite oxide as the main constituent and a plurality of Cu-containing internal electrode layers formed between the piezoelectric layers, wherein: involved is a sintering step for sintering in a reductive atmosphere a laminate in which the composite oxide-containing piezoelectric layer precursors and the Cu-containing internal electrode precursors are laminated with each other; the piezoelectric layer precursors contain the composite oxide represented by the composition formula A as the main constituent, and a rare earth metal element, in a content of 0.8% by mass or less (not inclusive of 0) in terms of oxide in relation to the main constituent; and the laminated piezoelectric element of the present invention can be manufactured by diffusing the Cu contained in the internal electrode precursors into the piezoelectric layers in the sintering step.

The present invention is also a production method of a laminated piezoelectric element including a plurality of piezoelectric layers containing the composite oxide as the main constituent and a plurality of Cu-containing internal electrode layers formed between the piezoelectric layers, wherein: involved is a sintering step for sintering in a reductive atmosphere a laminate in which the composite oxide-containing piezoelectric layer precursors and the Cu-containing internal electrode precursors are laminated with each other; the piezoelectric layer precursors contain the composite oxide represented by the composition formula A as the main constituent, at least one of the components represented by CuO_{α} (α≧0) in a content of 3.0% by mass or less (not inclusive of 0) in terms of CuO, and a rare earth metal element in a content of 0.8% by mass or less (not inclusive of 0) in terms of oxide, in relation to the main constituent; and thus the laminated piezoelectric element of the present invention can also be manufactured. Also in this embodiment, the Cu contained in the internal electrode precursors can be diffused into the piezoelectric layers in the sintering step.

In the above-mentioned production methods of a laminated piezoelectric element, the sintering in a reductive atmosphere can be carried out at a sintering temperature of 800° C. to 1200° C. under an oxygen partial pressure of 1×10⁻¹⁰ to 1×10⁻⁶ atm, and these conditions allow the diffusion of the Cu contained in the internal electrode precursors into the piezoelectric layers.

To enjoy the advantageous effect, due to the presence of Cu, of overcoming the degradation of the electric resistance at high temperatures, the use of Ag₂O is also effective against the degradation of the piezoelectric properties; Ag₂O contributes to the improvement of the piezoelectric properties through lowering the sintering temperature. When Ag₂O is added alone, the electric resistance and the insulation life tend to be degraded with increasing Ag₂O content; however, the concomitant presence of Cu has prevented the electric resistance degradation due to Ag₂O. It has been revealed that in a piezoelectric ceramic composition containing Cu and Ag₂O, the improvement degree of the piezoelectric properties at high voltages (1 to 3 kV/mm) is more remarkable than the improvement degree of the piezoelectric properties at low voltages (1 V/mm or lower).

Because a laminated piezoelectric element is driven at high voltages (1 to 3 kV/mm), it is necessary to attain satisfactory piezoelectric properties at high voltages. There are two or more physical property values to evaluate the piezoelectric properties; however, when laminated piezoelectric elements are used, the electromechanical coupling coefficient kr (%) and the displacement magnitude are significant. Because it is cumbersome to evaluate materials by giving the materials displacements at such high voltages, usually displacements are not measured, but actually a simple impedance measurement and a measurement with a d33 meter are carried out at a low voltage (1 V/mm or lower). By assuming that the piezoelectric properties at a low voltage and the piezoelectric properties at a high voltage link with each other, evaluation of the piezoelectric ceramic compositions has hitherto been carried out. However, as described above, the present invention has found that the improvement of the piezoelectric properties at high voltages is remarkable.

Another piezoelectric ceramic composition of the present invention based on the above-mentioned findings is characterized by containing: the composite oxide represented by the composition formula A as the main constituent; and Cu in a content of 1.0% by mass or less (not inclusive of 0) in terms of Cu₂O, and Ag in a content of 0.5% by mass or less (not inclusive of 0) in terms of Ag₂O, in relation to the main constituent.

The piezoelectric ceramic composition preferably contains Cu in a content of 0.01 to 0.8% by mass in terms of Cu₂O, and Ag in a content of 0.01 to 0.4% by mass in terms of Ag₂O, in relation to the main constituent.

The piezoelectric ceramic composition preferably contains at least one selected from Ta, Sb, Nb and W in a content of 0.5% by mass or less (not inclusive of 0) in terms of oxide.

The piezoelectric ceramic composition of the present invention can be used for a laminated piezoelectric element. The laminated piezoelectric element includes a plurality of piezoelectric layers containing a composite oxide as the main constituent and a plurality of Cu-containing internal electrode layers formed between the piezoelectric layers, wherein the piezoelectric layers are formed of a sintered body containing: the composite oxide represented by the composition formula A as the main constituent; and Cu in a content of 1.0% by mass or less (not inclusive of 0) in terms of Cu₂O, and Ag in a content of 0.5% by mass or less (not inclusive of 0) in terms of Ag₂O, in relation to the main constituent.

In this case, the Cu contained in a part or the whole of the piezoelectric layers can be derived from the diffusion during sintering of a part of the Cu contained in the internal electrode layers.

The above-mentioned laminated piezoelectric element can be obtained by involving a sintering step for sintering a laminate in which composite oxide-containing piezoelectric layer precursors and Cu-containing internal electrode precursors are laminated with each other, wherein: the piezoelectric layer precursors contain the composite oxide represented by the composition formula A as the main constituent, and Ag in a content of 0.5% by mass or less (not inclusive of 0) in terms of Ag₂O in relation to the main constituent; and the Cu contained in the internal electrode precursors is diffused into the piezoelectric layers in the sintering step.

In the above-mentioned production method of a laminated piezoelectric element, sintering can be carried out at a sintering temperature of 800 to 1200° C. under an oxygen partial pressure of 1×10⁻¹⁰ to 1×10⁻⁶ atm.

The present invention provides a piezoelectric ceramic composition that attains high piezoelectric properties even by low-temperature sintering. The piezoelectric ceramic composition is characterized by containing: the composite oxide represented by the composition formula A as the main constituent; and a rare earth metal element in a content of 0.15% by mass or less (not inclusive of 0) in terms of oxide and Ag in a content of 0.35% by mass or less (not inclusive of 0) in terms of Ag₂O, in relation to the main constituent.

In the present invention, preferably, a rare earth metal element is contained in a content of 0.02 to 0.1% by mass in terms of oxide and Ag in a content of 0.02 to 0.3% by mass in terms of Ag₂O. The rare earth metal element is preferably at least one selected from Dy, Nd, Gd and Tb.

Also in the present invention, preferably, at least one selected from Ta, Sb, Nb and W is contained in a content of 0.6% by mass or less (not inclusive of 0) in terms of oxide.

The piezoelectric ceramic composition of the present invention can be used for a laminated piezoelectric element. The laminated piezoelectric element includes a plurality of piezoelectric layers containing a composite oxide as a main constituent and a plurality of internal electrode layers formed between the piezoelectric layers, wherein the piezoelectric layers are formed of a sintered body containing: the composite oxide represented by the composition formula A as the main constituent; and a rare earth metal element in a content of 0.15% by mass or less (not inclusive of 0) in terms of oxide and Ag in a content of 0.35% by mass or less (not inclusive of 0) in terms of Ag₂O, in relation to the main constituent. The adoption of Cu as the conductive material for the internal electrode layers contributes to the cost reduction for the laminated piezoelectric element. Additionally, the present invention can attain high piezoelectric properties even by low temperature sintering in the case where Cu is adopted as the conductive material for the internal electrode layers.

As described above, according to the present invention, even when a low-price metal material, namely, Cu is used as a conductive material for the internal electrodes, it is possible to provide a piezoelectric ceramic composition high in piezoelectric properties such as the electromechanical coupling coefficient kr (%). Consequently, according to the present invention, it is possible to provide a laminated piezoelectric element that is excellent in piezoelectric properties although low in price. In particular, the present invention can attain a specific advantageous effect that the diffusion of Cu into the piezoelectric layers improves the piezoelectric properties.

Further, the present invention provides a piezoelectric ceramic composition that can inhibit the electric resistance degradation caused by the oxygen vacancies due to sintering at a low temperature in a reductive atmosphere.

### BRIEF DESCRIPTION OF THE DRAWINGS

FIG. 1 is a view illustrating a construction example of a laminated piezoelectric element in an embodiment of the present invention;

FIG. 2 is a flow chart showing production procedures of the laminated piezoelectric element in an embodiment of the present invention;

FIG. 3 shows a TEM image and EDS point analysis results of a piezoelectric layer in the vicinity of an internal electrode layer in a laminated piezoelectric element obtained by using Cu in the internal electrode layer;

FIG. 4 is a table showing the compositions, and the measurement results of the electromechanical coupling coefficient kr (%) and the electric resistance IR in Example 1;

FIG. 5 is a graph showing the relation between the content of Mg (MgO) and the electromechanical coupling coefficient kr (%) in Example 1;

FIG. 6 shows the SEM images of the samples in Example 1;

FIG. 7 is a table showing the compositions and the measurement results of the electromechanical coupling coefficient kr (%) in Example 2;

FIG. 8 is a table showing the compositions and the measurement results of the electromechanical coupling coefficient kr (%) in Example 3;

FIG. 9 is a table showing the compositions and the measurement results of the electromechanical coupling coefficient kr (%) in Example 4;

FIG. 10 is a table showing the compositions and the measurement results of the electromechanical coupling coefficient kr (%) in Example 5;

FIG. 11 is a table showing the compositions and the measurement results of the electromechanical coupling coefficient kr (%) in Example 6;

FIG. 12 is a table showing the compositions and the measurement results of the electromechanical coupling coefficient kr (%) in Example 7;

FIG. 13 is a table showing the compositions and the measurement results of the electromechanical coupling coefficient kr (%) in Example 8;

FIG. 14 is a graph showing the relation between the content of Co (CoO) and the electromechanical coupling coefficient kr (%);

FIG. 15 is a table showing the compositions and the measurement results of the electromechanical coupling coefficient kr (%) in Example 9;

FIG. 16 is a table showing the compositions and the measurement results of the electromechanical coupling coefficient kr (%) in Example 10;

FIG. 17 is a table showing the compositions and the measurement results of the electromechanical coupling coefficient kr (%) in Example 11;

FIG. 18 is a table showing the compositions and the measurement results of the electromechanical coupling coefficient kr (%) in Example 12;

FIG. 19 is a table showing the compositions and the measurement results of the electromechanical coupling coefficient kr (%) in Example 13;

FIG. 20 is a table showing the compositions and the measurement results of the electromechanical coupling coefficient kr (%) in Example 14;

FIG. 21 is a table showing the compositions and the measurement results of the electromechanical coupling coefficient kr (%) in Example 15;

FIG. 22 is a graph showing the relation between the content of Ga (Ga₂O₃) and the electromechanical coupling coefficient kr (%);

FIG. 23 is a table showing the compositions and the measurement results of the electromechanical coupling coefficient kr (%) in Example 16;

FIG. 24 is a table showing the compositions and the measurement results of the electromechanical coupling coefficient kr (%) in Example 17;

FIG. 25 is a table showing the compositions and the measurement results of the electromechanical coupling coefficient kr (%) in Example 18;

FIG. 26 is a table showing the compositions and the measurement results of the electromechanical coupling coefficient kr (%) in Example 19;

FIG. 27 is a table showing the compositions and the measurement results of the electromechanical coupling coefficient kr (%) in Example 20;

FIG. 28 is a table showing the compositions and the measurement results of the electromechanical coupling coefficient kr (%) in Example 21;

FIG. 29 is a table showing the compositions and the measurement results of the electromechanical coupling coefficient kr (%) in Example 22;

FIG. 30 is a table showing the displacement magnitude of the samples prepared in Example 23;

FIG. 31 is a table showing the compositions and the measurement results of the piezoelectric constant d33 in Example 24;

FIG. 32 is a microstructure photograph of a sintered body in Example 24 obtained by sintering a compacted body containing a fourth additive but not containing any of a first additive to a third additive without coating a Cu paste on the compacted body;

FIG. 33 is a microstructure photograph of a sintered body in Example 24 obtained by sintering a compacted body containing a fourth additive but not containing any of a first additive to a third additive with coating the Cu paste on the compacted body;

FIG. 34 is a microstructure photograph of a sintered body in Example 24 obtained by sintering a compacted body containing a first additive and a fourth additive but not containing any of a second additive and a third additive with coating the Cu paste on the compacted body;

FIG. 35 is a microstructure photograph of a sintered body in Example 24 containing a first additive to a fourth additive;

FIG. 36 is a table showing the compositions and the measurement results of the piezoelectric constant d33 in Example 25;

FIG. 37 is a table showing the compositions and the measurement results of the piezoelectric constant d33 and the resistivity at 150° C. in Example 26;

FIG. 38 is a table showing the compositions, and the measurement results of the piezoelectric constant d33 and the resistivity at 150° C. in Example 27;

FIG. 39 is a table showing the compositions and the measurement results of the piezoelectric constant d33 in Example 28;

FIG. 40 is a table showing the compositions and the measurement results of the piezoelectric constant d33 in Example 29;

FIG. 41 is a table showing the compositions and the measurement results of the piezoelectric constant d33 in Example 30;

FIG. 42 is a table showing the compositions and the measurement results of the piezoelectric constant d33 in Example 31;

FIG. 43 is a table showing the compositions and the measurement results of the piezoelectric constant d33 in Example 32;

FIG. 44 is a table showing the compositions, and the measurement results of the high temperature load life and the piezoelectric property in Example 33;

FIG. 45 is a table showing the content of Eu, and the measurement results of the high temperature load life and the piezoelectric property when Eu was used as a rare earth metal element in Example 34;

FIG. 46 is a table showing the content of Y, and the measurement results of the high temperature load life and the piezoelectric property when Y was used as a rare earth metal element in Example 34;

FIG. 47 is a table showing the content of Gd, and the measurement results of the high temperature load life and the piezoelectric property when Gd was used as a rare earth metal element in Example 34;

FIG. 48 is a table showing the content of La, and the measurement results of the high temperature load life and the piezoelectric property when La was used as a rare earth metal element in Example 34;

FIG. 49 is a table showing the content of Yb, and the measurement results of the high temperature load life and the piezoelectric property when Yb was used as a rare earth metal element in Example 34;

FIG. 50 is a table showing the content of Nd, and the measurement results of the high temperature load life and the piezoelectric property when Nd was used as a rare earth metal element in Example 34;

FIG. 51 is a table showing the content of Dy, and the measurement results of the high temperature load life and the piezoelectric property when Dy was used as a rare earth metal element in Example 34;

FIG. 52 is a table showing the content of Ho, and the measurement results of the high temperature load life and the piezoelectric property when Ho was used as a rare earth metal element in Example 34;

FIG. 53 is a table showing the content of Tb, and the measurement results of the high temperature load life and the piezoelectric property when Tb was used as a rare earth metal element in Example 34;

FIG. 54 is a table showing the content of Er, and the measurement results of the high temperature load life and the piezoelectric property when Er was used as a rare earth metal element in Example 34;

FIG. 55 is a table showing the compositions, and the measurement results of the high temperature load life and the piezoelectric property in Example 35;

FIG. 56 is a table showing the compositions, and the measurement results of the high temperature load life and the piezoelectric property in Example 36;

FIG. 57 is a table showing the compositions, and the measurement results of the high temperature load life and the piezoelectric property in Example 37;

FIG. 58 is a table showing the compositions, and the measurement results of the high temperature load life and the piezoelectric property in Example 38;

FIG. 59 is a table showing the compositions, and the measurement results of the high temperature load life and the piezoelectric property in Example 39;

FIG. 60 is a table showing the forms, and the measurement results of the high temperature load life and the piezoelectric property in Example 40;

FIG. 61 is an EPMA photograph of a section of a piezoelectric layer of a laminated piezoelectric element prepared in Example 40;

FIG. 62 is a table showing the compositions, and the measurement results of the electric resistance in Example 41;

FIG. 63 is a table showing the compositions, and the electromechanical coupling coefficients kr (%), the d values, the (d/kr)/(d_{STD}/kr_{STD}) values, and the resistivity at 150° C. in Example 42;

FIG. 64 is a table showing the compositions, the d values, and the (d/kr)/(d_{STD}/kr_{STD}) values in Example 43;

FIG. 65 is a table showing the compositions, the d values, and the (d/kr)/(d_{STD}/kr_{STD}) values in Example 44;

FIG. 66 is a table showing the compositions, the d values, and the (d/kr)/(d_{STD}/kr_{STD}) values in Example 45;

FIG. 67 is a table showing the compositions, the d values, and the (d/kr)/(d_{STD}/kr_{STD}) values in Example 46;

FIG. 68 is a table showing the compositions, the d values, and the (d/kr)/(d_{STD}/kr_{STD}) values in Example 47;

FIG. 69 is a table showing the compositions, the d values, and the (d/kr)/(d_{STD}/kr_{STD}) values in Example 48;

FIG. 70 is a table showing the compositions, the d values, the (d/kr)/(d_{STD}/kr_{STD}) values, and the resistivity values at 150° C. in Example 49;

FIG. 71 is a table showing the compositions, the d values, the (d/kr)/(d_{STD}/kr_{STD}) values, and the resistivity values at 150° C. in Example 50;

FIG. 72 is a table showing the compositions and the measurement results of the piezoelectric constant d33 in Example 51;

FIG. 73 is a graph showing the relation between the contents of Dy₂O₃ and Ag₂O and the piezoelectric constant d33 in Example 51;

FIG. 74 is a table showing the compositions and the measurement results of the piezoelectric constant d33 in Example 52;

FIG. 75 is a table showing the compositions and the measurement results of the piezoelectric constant d33 in Example 53;

FIG. 76 is a table showing the compositions and the measurement results of the piezoelectric constant d33 in Example 54;

FIG. 77 is a table showing the compositions and the measurement results of the piezoelectric constant d33 in Example 55;

FIG. 78 is a table showing the compositions and the measurement results of the piezoelectric constant d33 in Example 56;

FIG. 79 is a table showing the compositions and the measurement results of the piezoelectric constant d33 in Example 57;

FIG. 80 is a table showing the compositions and the measurement results of the piezoelectric constant d33 in Example 58; and

FIG. 81 is a table showing the compositions and the measurement results of the piezoelectric constant d33 in Example 59.

### DETAILED DESCRIPTION OF THE PREFERRED EMBODIMENTS

Detailed description will be made below on the present invention on the basis of the embodiments shown in the accompanying drawings.

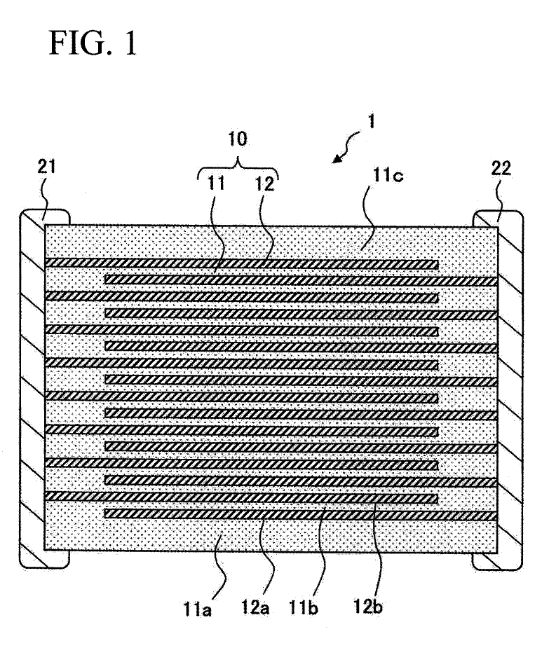

FIG. 1 is a sectional view illustrating a construction example of a laminated piezoelectric element 1 obtained by the present invention. FIG. 1 shows one example, and needless to say, the present invention is not limited to the laminated piezoelectric element 1 shown in FIG. 1. The laminated piezoelectric element 1 has a laminate 10 in which a plurality of piezoelectric layers 11 and a plurality of internal electrode layers 12 are alternately laminated with each other. The thickness of one piezoelectric layer 11 is set at, for example, 1 to 200 μm, preferably at 20 to 150 μm, and more preferably at 50 to 100 μm. The lamination number of the piezoelectric layers 11 is determined according to the targeted displacement magnitude.

The piezoelectric ceramic composition forming the piezoelectric layers 11 contains as a main constituent a composite oxide that contains Pb, Ti and Zr as the constituent elements. Examples of the composite oxide include a ternary composite oxide constituted with lead titanate (PbTiO₃), lead zirconate (PbZrO₃) and lead zincate niobate [Pb(Zn_{1/3}Nb_{2/3})O₃], and a composite oxide in which the Pb contained in the above-mentioned ternary composite oxide is partially substituted with Sr, Ba, Ca or the like.

Examples of the specific compositions of the composite oxides may include the composite oxides represented by the following formulas (1) and (2), respectively. In these formulas, the composition of the oxygen is derived stoichiometrically; in the actual compositions, deviations from the stoichiometric compositions are allowed.
Pbₐ[(Zn_{1/3}Nb_{2/3})ₓTi_{y}Zr_{z}]O₃ (1)
wherein 0.96≦a≦1.03, 0.05≦x≦0.15, 0.25≦y≦0.5, 0.35≦z≦0.6, and x+y+z=1.
(Pb_{a-b}Me_{b}) [(Zn_{1/3}Nb_{2/3})ₓTi_{y}Zr_{z}]O₃ (2)
wherein 0.96≦a≦1.03, 0<b≦0.1, 0.05≦x≦0.15, 0.25≦y≦0.5, 0.35≦z≦0.6, and x+y+z=1, Me representing at least one selected from Sr, Ca and Ba.

The above-mentioned composite oxide has a so-called perovskite structure, wherein Pb and the substitutional element Me in formula (2) are located at the so-called A site in the perovskite structure, and Zn, Nb, Ti and Zr are located at the so-called B site in the perovskite structure.

In each of the composite oxides represented by above formulas (1) and (2), the A-site element ratio (molar ratio) “a” preferably satisfies the relation that 0.96≦a≦1.03 with the B-site molar ratio assumed to be 1. If the A-site element ratio “a” is less than 0.96, sintering at low temperatures may become difficult. If the A-site element ratio “a” exceeds 1.03, the density of the piezoelectric ceramic to be obtained may be degraded, which may result in poor piezoelectric properties and a lower mechanical strength. The A-site element ratio “a” more preferably satisfies the relation that 0.97≦a≦1.02, and furthermore preferably 0.98≦a≦1.01.

In the composite oxide represented by above formula (2), Pb is partially substituted with the substitutional element Me (Sr, Ca, Ba), and the piezoelectric strain constant can thereby be made larger. However, when the substitution amount b of the substitutional element Me becomes too large, the piezoelectric strain constant becomes smaller and the mechanical strength is also degraded. The Curie temperature also tends to be decreased with the increase of the substitution amount b. Consequently, the substitution amount b of the substitutional element Me is preferably set at 0.1 or less, and more preferably set to satisfy 0.005≦b≦0.08, and furthermore preferably 0.007≦b≦0.05.

Among the B-site elements, the ratio (molar ratio) x of Zn and Nb is preferably set to satisfy 0.05≦x≦0.15. The ratio x affects the sintering temperature. If the value of x is less than 0.05, the effect of lowering the sintering temperature may be insufficient. If the value of x exceeds 0.15, the sinterability is affected by such a x value, leading to a fear that the piezoelectric strain constant becomes small and the mechanical strength is degraded. The ratio x of Zn and Nb more preferably satisfies 0.07≦x≦0.13 and furthermore preferably 0.08≦x≦0.12.

Among the ratios of the B-site elements, the preferable ranges for the ratio y (molar ratio) of Ti and the ratio z (molar ratio) of Zr are set from the viewpoint of the piezoelectric properties. Specifically, the ratio y of Ti preferably satisfies 0.25≦y≦0.5, and the ratio z of Zr preferably satisfies 0.35≦z≦0.6. By setting these ratios to fall within the above-mentioned ranges, there can be obtained a large piezoelectric strain constant in the vicinity of the morphotropic phase boundary (MPB). The ratio y of Ti more preferably satisfies 0.3≦y≦0.48, and furthermore preferably 0.4≦y≦0.46. The ratio z of Zr more preferably satisfies 0.37≦z≦0.55, and furthermore preferably 0.4≦z≦0.5.

The above descriptions give the fundamental structure of the laminated piezoelectric element 1 of the present invention. One of the features of the laminated piezoelectric element 1 of the present invention is the fact that the piezoelectric layers 11 contain at least one selected from Co, Mg, Ni, Cr and Ga, as the first additive to be describe below, in a content of 0.5% by mass or less (not inclusive of 0) in terms of oxide (CoO, MgO, NiO, CrO or Ga₂O₃). The first additive has an advantageous effect to promote the grain growth in the piezoelectric layers 11, and to thereby recover the reduction and/or loss of the piezoelectric strain constant caused by the diffusion of the Cu constituting the internal electrodes 12 into the piezoelectric layers 11.

The present invention can attain a further improvement of the piezoelectric strain constant by containing at least one of the second additive and the third additive to be described below. The present invention preferably contains both of the second additive and the third additive. However, it is essential that the further improvement of the piezoelectric strain constant due to the second additive and the third additive is not attained without containing the first additive. This point will be clarified by the examples to be described below.

Second additive: A rare earth metal element in a content of 0.15% by mass or less in terms of oxide.

Third additive: Ag in a content of 0.08% by mass or less in terms of Ag₂O; however, in a content of 0.35% by mass or less when contained with the second additive.

When the content of the first additive exceeds 0.5% by mass in terms of oxide, the improvement effect of the piezoelectric strain constant cannot be fully enjoyed. The content of the first additive is preferably 0.03 to 0.4% by mass, more preferably 0.05 to 0.35% by mass, and furthermore preferably 0.08 to 0.35% by mass, in terms of oxide. It may be noted that the content (% by mass) of the first additive means the ratio to the mass of 1 mole of the main constituent; this is also the case for the second to fifth additives to be described below.

Among the first additives, Co, Mg and Ni are preferably selected from the viewpoint of the piezoelectric strain constant; Co is preferably selected from the additional view point of the electric resistance.

By containing the second additive, the piezoelectric strain constant can be improved; however, when the content of the second additive is such that the content of the rare earth metal element exceeds 0.15% by mass in terms of oxide, the advantageous effect of the second additive becomes insufficient. The content of the rare earth metal element is preferably 0.02 to 0.1% by mass, and more preferably 0.03 to 0.07% by mass, in terms of oxide.

The rare earth metal elements in the present invention mean a concept that includes Y (yttrium); accordingly the rare earth metal elements can be selected from one or more of Y, La, Ce, Pr, Nd, Pm, Sm, Eu, Gd, Tb, Dy, Ho, Er, Tm, Yb and Lu. However, as the rare earth metal element(s), Dy, Nd, Gd and Tb are preferably selected from the viewpoint of the piezoelectric strain constant, and Dy is preferably selected from the additional viewpoint of the electric resistance.

The third additive (Ag₂O) is an effective material for lowering the sintering temperature, and serves to attain, even by low-temperature sintering, the piezoelectric strain constant that is intrinsically possessed by the main constituent. However, when the content of the third additive becomes too large, the third additive adversely affects the piezoelectric strain constant. As described above, the content of the third additive is different in the appropriate content thereof from the case where the second additive is contained to the case where the second additive is not contained. When the second additive is not contained, the content of the third additive is set at 0.08% by mass or less, preferably at 0.02 to 0.08% by mass, and more preferably at 0.03 to 0.07% by mass. When the second additive is contained, the content of the third additive is set at 0.35% by mass or less, preferably at 0.02 to 0.25% by mass, and more preferably at 0.05 to 0.15% by mass.

Most preferably, both the second additive and the third additive are contained. The oxide of a rare earth metal element has such a property that the oxide makes it impossible to obtain a dense sintered body without elevating the sintering temperature; thus, when the oxide of a rare earth metal element is contained, it is necessary to set the sintering temperature at a high temperature for the purpose of fully attaining the improvement effect of the piezoelectric strain constant. However, the addition of Ag₂O, effective for low temperature sintering, makes it possible to carry out sintering to a sufficient extent even when the oxide of a rare earth metal element is contained. Consequently, it can be interpreted that even by sintering at a low temperature, the improvement effect of the piezoelectric strain constant due to the oxide of a rare earth metal element can be enjoyed. As can be inferred from this interpretation, when the third additive is contained but the second additive is not contained, the sintering proceeds beyond necessity, and hence, the improvement effect of the piezoelectric strain constant due to the third additive is saturated at the content of the third additive smaller than the content of the third additive in a case where the second additive is contained.

The piezoelectric ceramic composition of the present invention may contain yet another additive in addition to the main constituent and the above-mentioned first to third additives. This additional additive (the fourth additive) includes at lest one selected from Ta, Sb, Nb and W. The addition of this additive can improve the piezoelectric properties and the mechanical strength. However, the content of this additive is preferably 1.0% by mass or less in terms of oxide. For example, the content of Ta is 1.0% by mass or less in terms of Ta₂O₅, the content of Sb is 1.0% by mass or less in terms of Sb₂O₃, the content of Nb is 1.0% by mass or less in terms of Nb₂O₅, and the content of W is 1.0% by mass or less in terms of WO₃. If the content of this additive exceeds 1.0% by mass in terms of oxide, the sinterability may be lowered and the piezoelectric properties may be thereby degraded. The content of the fourth additive is more preferably 0.05 to 0.8% by mass, and furthermore preferably 0.1 to 0.5% by mass.

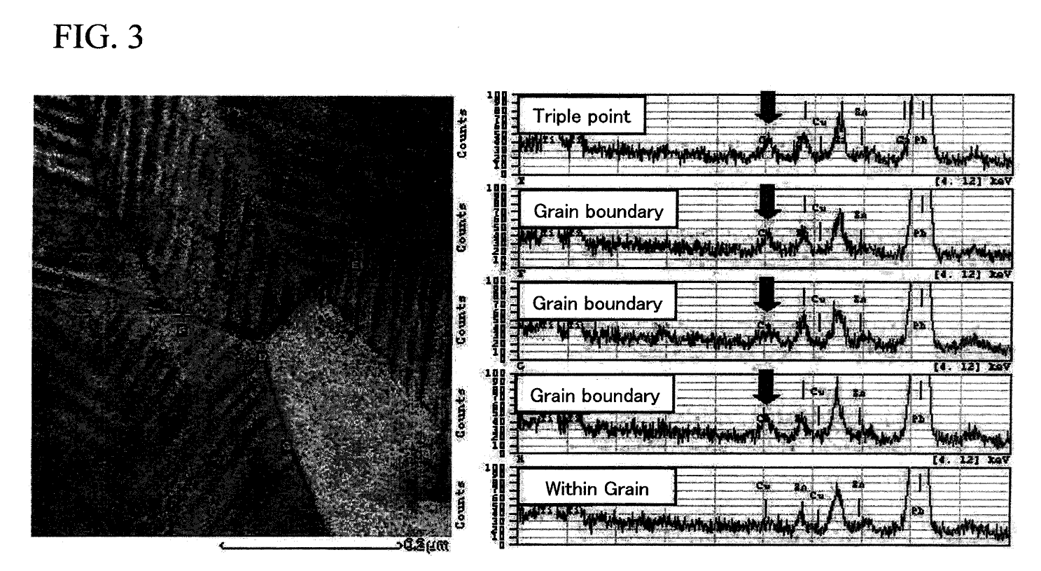

A laminated piezoelectric element 1 has been prepared by using Cu for the internal electrode layers 12, and the piezoelectric layers 11 in the vicinity of the internal electrode layers 12 have been subjected to an analysis based on TEM-EDS (field-emission type transmission electron microscope with energy dispersive X-ray spectroscopy). FIG. 3 shows a TEM image and point analysis results based on EDS. Cu is present at the triple points and the grain boundaries in the piezoelectric layers 11, and thus, it has been found that Cu diffuses from the internal electrode layers 12 in the sintering process. The Cu is present as CuO_{α} (α≧0) in the piezoelectric layers 11. When CuO_{α} (α≧0) is present as described above in the piezoelectric layers 11, the electric resistance degradation at high temperatures is inhibited and the high temperature load life is improved. However, if the content of CuO_{α} (α≧0) becomes too large, the electromechanical coupling coefficient kr (%) may be decreased. Consequently, the content of CuO_{α} (α≧0) is preferably 3.0% by mass or less (not inclusive of 0). When the content of CuO_{α} (α≧0) exceeds 3.0% by mass, the electromechanical coupling coefficient kr (%) may become 50 or less. The content of CuO_{α} (α≧0) is more preferably 0.01 to 3.0% by mass. Here, examples of CuO_{α} (α≧0) may include the Cu oxides having arbitrary oxidation states such as Cu₂O and CuO, and Cu(α=0); two or more of these CuO_{α} (α≧0) species may be contained.

The CuO_{α} (α≧0) contained in the piezoelectric layers 11 may be generated by the diffusion of the Cu contained in the internal electrode layers 12 into the piezoelectric layers 11, or may be contained by adding CuO_{α} to the piezoelectric layers 11 at the time of preparing the raw material composition thereof. In the present invention, it is essential that the piezoelectric layers 11 contain Cu, but the present invention is indifferent about the addition process and the form of occurrence of Cu.

Here, description will be made on the experiment for identifying the effect due to the diffusion of Cu into the piezoelectric layers 11.

A piezoelectric ceramic composition has been prepared as follows. First, as the raw materials for the main constituent, a PbO powder, a SrCO₃ powder, a ZnO powder, a Nb₂O₅ powder, a TiO₂ powder and a ZrO₂ powder were prepared, and were weighed out to give the following composition. Then, these raw materials were wet mixed in a ball mill for 16 hours, and the mixture thus obtained was calcined in air at 700 to 900° C. for 2 hours.

Main Constituent:
(Pb_{0.995-0.03}Sr_{0.03}) [(Zn_{1/3}Nb_{2/3})_{0.1}Ti_{0.43}Zr_{0.47}]O₃

The calcined mixture thus obtained was pulverized, and then wet milled in a ball mill for 16 hours. The milled mixture was dried, added with an acrylic resin as a binder, and then granulated. The granulated mixture was compacted into a disc of 17 mm in diameter and 1 mm in thickness with a uniaxial press molding machine under a pressure of approximately 445 MPa. After compacting, a Cu paste containing a Cu powder of 1.0 μm in particle size was printed on both sides of this disc. The pellet thus obtained was heat treated to evaporate the binder, and sintered at 950° C. for 8 hours in a low-oxygen reductive atmosphere (oxygen partial pressure: 1×10⁻¹⁰ to 1×10⁻⁶ atm). The sintered body thus obtained was subjected to slicing machining and lapping machining into a 0.6 mm thick disc; then the printed Cu paste was removed and at the same time machined into a shape suitable for the property evaluation. A silver paste was printed on both sides of the obtained sample, and baked at 350° C. The sample was subjected to a polarization treatment in a silicone oil set at 120° C. by applying an electric filed of 3 kV for 15 minutes.

A piezoelectric ceramic composition was prepared by following the above described method, and another piezoelectric ceramic composition for which no Cu paste printing was carried out was prepared. The two piezoelectric ceramic compositions thus prepared were subjected to a measurement of electric resistance (resistivity, hereinafter the same) IR and further a measurement of the electromechanical coupling coefficient kr (%) . The measurement of the electromechanical coupling coefficient kr (%) was carried out by using an impedance analyzer (HP4194A, manufactured by Hewlett-Packard Co.). The results thus obtained are shown below. It may be noted that the electric resistance IR (relative value) means a value obtained by dividing the resistance value at 150° C. of each of the piezoelectric ceramic compositions by the resistance value at 150° C. for the case where no Cu paste coating was carried out.
With Cu paste: Electric resistance IR (relative value)=124, kr (%)=66.1%
Without Cu paste: Electric resistance IR (relative value)=1, kr (%)=66.5%

As can be seen, in the piezoelectric ceramic composition printed with a Cu paste, the electric resistance at a high temperature has been drastically improved. However, the piezoelectric property (electromechanical coupling coefficient kr (%)) has been somewhat decreased.

The piezoelectric ceramic composition printed with a Cu paste was subjected to ICP (Inductively Coupled Plasma) analysis. A preparation method of a sample for ICP was as follows: first, 0.1 g of an analyte sample was added with 1 g of Li₂B₂O₇, and the mixture was melted at 1050° C. for 15 minutes; the obtained molten was added with 0.2 g of (COOH)₂ and 10 ml of HCl, heated to be dissolved, and then the sample solution volume was adjusted so as to be 100 ml. The ICP measurement was carried out by using ICP-AES (trade name ICPS-8000, manufactured by Shimadzu Corp.). Consequently, it was found that Cu was contained in a content of approximately 0.1% by mass in terms of CuO. The Cu can be identified to have diffused from the Cu paste during the sintering process, because no Cu was contained in the raw materials of the piezoelectric ceramic composition.

Next, description will be made on the experiment for identifying the effect due to the addition of Cu as a component of the piezoelectric layers.

As the raw materials for the main constituent, a PbO powder, a SrCO₃ powder, a ZnO powder, a Nb₂O₅ powder, a TiO₂ powder and a ZrO₂ powder were prepared, and were weighed out to give the following composition. Then, these raw materials were wet mixed for 16 hours in a ball mill, and the mixture thus obtained was calcined in air at 700 to 900° C. for 2 hours.

Main Constituent:
(Pb_{0.995-0.03}Sr_{0.03}) [(Zn_{1/3}Nb_{2/3})_{0.1}Ti_{0.43}Zr_{0.47}]O₃

The calcined mixture thus obtained was pulverized, added with CuO, and then wet milled for 16 hours in a ball mill. The milled mixture was dried, added with a vehicle, and then kneaded to prepare a piezoelectric layer paste. An internal electrode layer paste was also prepared by kneading a Cu powder as the conductive material with a vehicle. Then, by using the piezoelectric layer paste and the internal electrode layer paste, a green chip to be a precursor for a laminate was prepared by means of a printing method. The green chip was subject to a binder removal treatment, and then sintered under reductive sintering conditions to yield a laminate. The reductive sintering conditions were such that sintering was carried out in a reductive atmosphere (for example, under an oxygen partial pressure: 1×10⁻¹⁰ to 1×10⁻⁶ atm) at temperatures of 800 to 1200° C.

The obtained laminate was subjected to the electric resistance IR (relative value) measurement at a high temperature in the same manner as described above and a measurement of the dielectric constant ε. The results obtained are shown below.

Laminated body: Electric resistance IR (relative value)=112, dielectric constant ε=1646.

Bulk body: Electric resistance IR (relative value)=124, dielectric constant ε=1995.

The addition of Cu to the piezoelectric layers has drastically improved the electric resistance at a high temperature in the same manner as in the case where Cu was diffused from the internal electrode layers into the piezoelectric layers. And, the accompanying decrease of the dielectric constant ε has been identified to be small.

Next, the piezoelectric layers 11 containing CuO_{α} (α≧0) degrade the piezoelectric properties, and hence the present invention improves the piezoelectric strain constant by containing an oxide of a rare earth metal element in a content of 0.8% by mass or less (not inclusive of 0).

Preferred among the rare earth metal elements are Y and heavy rare earth metal elements; preferred among the heavy rare earth metal elements are Tb, Dy and Ho. Here, it is to be noted that the heavy rare earth metal elements mean the Gd and the elements listed thereafter in the above-listed rare earth metal elements.

The content of the oxide of a rare earth metal element to be contained in the piezoelectric layers 11 is 0.8% by mass or less (not inclusive of 0) in terms of the oxide concerned. This is because when the content of the oxide of a rare earth metal element exceeds 0.8% by mass, the piezoelectric properties are degraded as compared to the case where no oxide of a rare earth metal element is contained. The content of the oxide of a rare earth metal element is preferably 0.03 to 0.6% by mass, and more preferably 0.07 to 0.4% by mass.

Next, the piezoelectric layers 11 containing CuO_{α} (α≧0) degrade the piezoelectric properties, and hence the present invention may contain Ag, as the third additive, in a content of 0.5% by mass or less (not inclusive of 0) in terms of Ag₂O. Here, by containing Cu in the piezoelectric layers 11, the electric resistance degradation due to the reductive sintering and the addition of Ag is inhibited. However, if the content of Cu becomes too large, the piezoelectric properties may be degraded, and hence the content of Cu is set at 1.0% by mass or less (not inclusive of 0) in terms of Cu₂O; the content of Cu is more preferably 0.01 to 0.8% by mass, and furthermore preferably 0.02 to 0.5% by mass, in terms of Cu₂O. Examples of the form of occurrence of Cu may include the Cu oxides having arbitrary oxidation states such as Cu₂O and CuO, and metallic Cu; two or more of these species may be contained.

As described above, the Cu contained in the piezoelectric layers 11 may be generated by the diffusion of the Cu contained in the internal electrode layers 12 into the piezoelectric layers 11, or may be contained in the piezoelectric layers 11 by adding as, for example, Cu₂O to the precursors of the piezoelectric layers 11. And, these two ways of containing Cu may be combined. In the present invention, it is essential that the piezoelectric layers 11 contain Cu, but the present invention is indifferent about the addition process and the form of occurrence of Cu.

In the above case, the piezoelectric layers 11 contain Ag in a content of 0.5% by mass or less (not inclusive of 0) in terms of Ag₂O. Ag (Ag₂O) is effective for low temperature sintering, and is effective, by being contained together with Cu, in improving the piezoelectric properties at high voltages (1 to 3 kV/mm). On the other hand, the present invention inhibits the electric resistance degradation encountered when only Ag₂O is contained, by the concomitant presence of Cu.

However, when the content of Ag becomes too large, the improvement effect of the piezoelectric properties at high voltages cannot be attained, and hence the content of Ag is set at 0.5% by mass or less (not inclusive of 0) in terms of Ag₂O. The content of Ag is preferably 0.01 to 0.4% by mass, and more preferably 0.02 to 0.35% by mass in terms of Ag₂O.

The present invention can improve the piezoelectric properties by concomitantly containing a rare earth metal element, as the second additive, in a content of 0.15% by mass or less (not inclusive of 0) in terms of oxide and Ag, as the third additive, in a content of 0.35% by mass or less (not inclusive of 0) irrespective of whether or not Cu is present. In other words, when the oxide of a rare earth metal element is contained alone, the piezoelectric properties can be somewhat improved in low temperature sintering; however, by concomitantly containing Ag, the improvement effect of the piezoelectric properties due to the rare earth metal element becomes extremely remarkable. On the other hand, by containing Ag alone, no contribution to the piezoelectric property improvement was found.

The reason for the above described results is not clear at present, but the conceivable interpretation of the present inventors is as follows. When the oxide of a rare earth metal element is contained alone in the above-mentioned main constituent, the sintering temperature set at a temperature as high as approximately 1200° C. leads to the attainment of the improvement effect of the piezoelectric properties at approximately the same level as the level of such effect in the present invention. However, when the sintering temperature is lowered to 1000° C., the improvement effect of the piezoelectric properties fades away. Accordingly, when the oxide of a rare earth metal element is contained, sintering at a temperature as high as approximately 1200° C. is required in order to make the sintering proceed. In this connection, because Ag₂O is a material effective in lowering the sintering temperature, and hence the addition of Ag₂O makes it possible to make the sintering proceed even when the oxide of a rare earth metal element is contained; thus, even a sintering at a low temperature can sufficiently enjoy the improvement effect of the piezoelectric properties due to the oxide of a rare earth metal element.

In the above case, the content of the rare earth metal element contained in the piezoelectric layers 11 is preferably 0.02 to 0.1% by mass, and more preferably 0.03 to 0.07% by mass, in terms of oxide. The content of Ag contained in the piezoelectric layers 11 is preferably 0.02 to 0.3% by mass, and more preferably 0.07 to 0.15% by mass, in terms of Ag₂O. Also in this case, at least one selected from Ta, Sb, Nb and W, as the fourth additive, can be added. The addition of this additive can improve the piezoelectric properties and the mechanical strength. However, the content of this additive is preferably 0.6% by mass or less (not inclusive of 0) in terms of oxide. For example, the content of Ta is 0.6% by mass or less in terms of Ta₂O₅, the content of Sb is 0.6% by mass or less in terms of Sb₂O₃, the content of Nb is 0.6% by mass or less in terms of Nb₂O₅, and the content of W is 0.6% by mass or less in terms of WO₃. If the content of this additive exceeds 0.6% by mass in terms of oxide, the sinterability may be lowered and the piezoelectric properties may be thereby degraded. The content of the fourth additive is more preferably 0.05 to 0.4% by mass, and furthermore preferably 0.1 to 0.35% by mass.

The internal electrode layers 12 contain a conductive material. The present invention uses Cu as the conductive material. The use of Cu as the conductive material is useful for the low temperature sintering, for example, at 1050° C. or lower.

The plurality of internal electrode layers 12 are alternately extended in opposite directions, and a pair of terminal electrodes 21 and 22 are disposed to be electrically connected to the alternate extension ends of the internal electrode layers 12, respectively. The terminal electrodes 21 and 22 are, for example, electrically connected to an external power supply not shown in the figure through the lead wires not shown in the figure.

The terminal electrodes 21 and 22 may be formed by sputtering with Cu, or alternatively, by baking a paste for the terminal electrodes. The thickness of each of the terminal electrodes 21 and 22 is appropriately determined depending on the intended purposes and other factors, and is usually 10 to 50 μm.

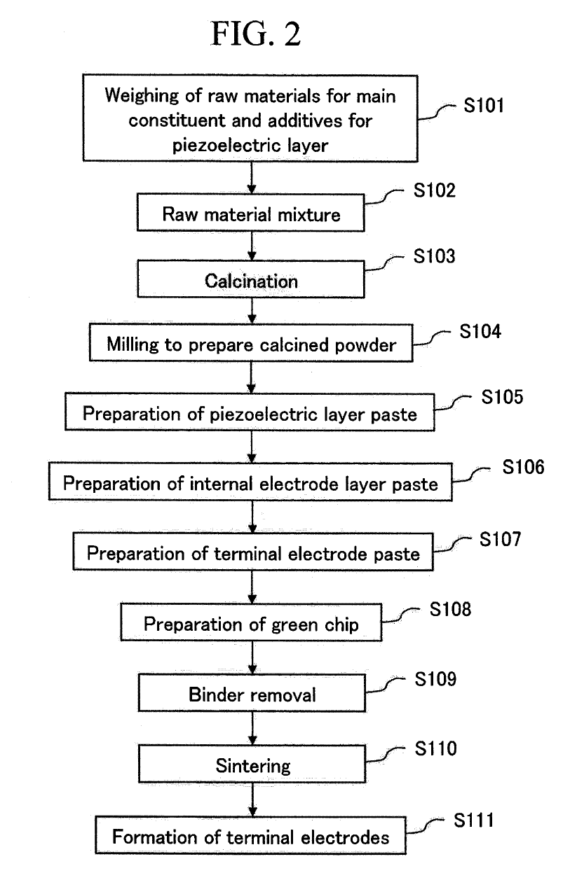

Next, description will be made on a preferable production method of the laminated piezoelectric element 1 with reference to FIG. 2. FIG. 2 is a flow chart showing a production process of the laminated piezoelectric element 1.

First, as the starting materials for the main constituent for the purpose of obtaining the piezoelectric layers 11, for example, the following are prepared and weighed out: the powders of PbO, TiO₂, ZrO₂, ZnO and Nb₂O₅, or the compounds that can be converted into these oxides by sintering; and the powder of at least one oxide selected from SrO, BaO and CaO or one selected from the compounds that can be converted into these oxides by sintering and the like (step S101). As the starting materials, instead of oxides, such materials as carbonates and oxalates that are converted into oxides by sintering may also be used. The raw material powders having an average particle size of 0.5 to 10 μm are usually used.

Each of the starting materials for the additives is prepared according to need and weighed out (step S101). As the starting material for the first additive, there can be used at least one oxide selected from CoO, MgO, NiO, CrO and Ga₂O₃. As the starting materials for the second additive, there can be used the oxides of the rare earth metal elements, more specifically, Dy₂O₃, Nd₂O₃, Gd₂O₃, Tb₂O₃, Ho₂O₃, Er₂O₃, Y₂O₃ and the like. As the starting material for the third additive, Ag₂O is used. Further, as the starting material for the fourth additive, there can be used at least one oxide selected from Ta₂O₅, Sb₂O₃, Nb₂O₅ and WO₃. As the starting materials for the additives, instead of oxides, such materials as carbonates and oxalates that are converted into oxides by sintering may also be used as described above.

Subsequently, the starting materials for the main constituents and the additives are wet milled and mixed, for example, in a ball mill to yield the raw material mixture (step S102).

The starting materials for the additives may be added before the calcination (step S103) to be described below, or may be added after the calcination. It is to be noted that the addition before the calcination is preferable because the more homogeneous piezoelectric layers 11 can thereby be prepared; when added after calcination, oxides are preferably used for the starting materials for the additives.

Next, the raw material mixture is dried and calcined, for example, at temperatures of 750 to 950° C. for 1 to 6 hours (step S103). This calcination may be carried out in air, in an atmosphere having an oxygen partial pressure higher than that in air, or in an atmosphere of pure oxygen. After calcination, the calcined mixture is wet milled and mixed, for example, in a ball mill to yield a calcined powder containing the main constituent and, if needed, additive(s) (step S104).

Next, the calcined powder is added with a binder to prepare a piezoelectric layer paste (step S105). Specifically, the involved procedures are as follows: first, for example, in a ball mill, a slurry is prepared by wet milling; at this time, as the solvent for the slurry, water, alcohols such as ethanol, or a mixed solvent composed of water and ethanol can be used; and the wet milling is preferably carried out until the average particle size of the calcined powder becomes approximately 0.5 to 2.0 μm.

Next, the obtained slurry is dispersed in an organic vehicle. The organic vehicle means a mixture in which a binder is dissolved in an organic solvent. No particular constraint is imposed on the binders usable for the organic vehicle; such a binder may be appropriately selected from common various binders such as ethyl cellulose, polyvinyl butyral and acryls. Also, no particular constraint is imposed on the organic solvent concerned; such a solvent may be appropriately selected from organic solvents such as terpineol, butylcarbitol, acetone, toluene, and MEK (methyl ethyl ketone), according to the method to be applied such as printing and sheet forming.

When the piezoelectric layer paste is made to take a form of an aqueous coating composition, the calcined powder may be kneaded with an aqueous vehicle in which a water-soluble binder, a water-soluble dispersant or the like is dissolved in water. No particular constraint is imposed on the water-soluble binder to be used for the aqueous vehicle; for example, polyvinyl alcohol, cellulose, a water-soluble acrylic resin or the like may be used.

Additionally, the internal electrode layer paste is also prepared (step S106).

The internal electrode layer paste is prepared by kneading the above-mentioned various conductive materials or various oxides, organometallic compounds, resinates and the like to be converted after sintering into the above-mentioned conductive materials, with the above-mentioned organic vehicle.

In the sintering step to be described below, the Cu contained in the internal electrode layer paste diffuses into the piezoelectric layers 2 to be formed by sintering of the piezoelectric layer paste. In this diffusion, the particle size of the Cu contained in the internal electrode layer paste affects the diffusion quantity. When the particle size of the Cu contained in the internal electrode layer paste is large, the diffusion quantity is increased; when the particle size of the CU is small, the diffusion quantity is decreased. For the purpose of preventing the decrease of the piezoelectric strain constant, the smaller diffusion quantity of the Cu is the more preferable. Accordingly, it is preferable that the particle size of Cu contained in the internal electrode layer paste is as small as possible.

A terminal electrode paste is also prepared in the same manner as the internal electrode layer paste (step S107).

In the above-mentioned case, the piezoelectric layer paste, the internal electrode layer paste and the terminal electrode paste are prepared sequentially in this order; however, needless to say, these pastes may be simultaneously prepared or in a reversed order.

No particular constraint is imposed on the content of the organic vehicle in each of the pastes; the typical content may be such that the content of the binder is approximately 5 to 10% by mass and the content of the solvent is approximately 10 to 50% by mass. Additionally, each of the pastes may contain additives selected from various dispersants, plasticizers, dielectrics, insulators and the like.

Next, by using the above-mentioned pastes, a green chip (laminate) to be sintered is prepared (step S108).

When the green chip is prepared by means of a printing method, the piezoelectric layer paste is printed two or more times, in a predetermined thickness for each time, for example, on a substrate made of polyethylene terephthalate and the like, to form an outer piezoelectric layer 11a in a green state. Then, on the outer piezoelectric layer 11a in a green state, the internal electrode layer paste is printed in a predetermined pattern to form an internal electrode layer (an internal electrode layer precursor) 12a in a green state. Then, on the internal electrode layer 12a in a green state, the piezoelectric layer paste is printed two or more times, in a predetermined thickness for each time, in the same manner as described above, to form a piezoelectric layer (a piezoelectric layer precursor) 11b in a green state. Then, on the piezoelectric layer 11b in a green state, the internal electrode layer paste is printed in a predetermined pattern, to form an internal electrode layer 12b in a green state. The internal electrode layers 12a and 12b each in a green state are formed so as to be exposed respectively to the different end surfaces facing each other. The above-mentioned operations are repeated predetermined number of times, and finally, on the internal electrode layer 12 in a green state, the piezoelectric layer paste is printed, in the same manner as described above, predetermined number of times, in a predetermined thickness for each time, to form the outer piezoelectric layer 11c in a green state. Hereafter, the laminate thus obtained is pressurized and bonded while being heated, and then cut into a predetermined shape to form a green chip (laminate).

In the above case, description is made on the preparation of a green chip by means of a printing method; however, such a green chip can also be prepared by means of a sheet forming method.

Next, the green chip is subjected to a binder removal treatment (step S109).

In the binder removal treatment, the atmosphere of the binder removal is needed to be determined according to the conductive material in the internal electrode layer precursor. When a noble metal is used as the conductive material, the binder removal may be carried out in air, in an atmosphere having an oxygen partial pressure higher than that in air, or in an atmosphere of pure oxygen. When Cu is used as the conductive material, it is necessary to consider the oxidation, and a heating in a reductive atmosphere is to be adopted. On the other hand, in the binder removal treatment, it is necessary to consider the fact that the oxide contained in the piezoelectric layer precursor, for example, PbO is reduced. For example, when Cu is used as the conductive material, it is preferable to determine what reductive atmosphere is to be applied to the binder removal treatment on the basis of the equilibrium oxygen partial pressure of Cu and Cu₂O (hereinafter, simply referred to as the equilibrium oxygen partial pressure of Cu) and the equilibrium oxygen partial pressure of Pb and PbO (hereinafter, simply referred to as the equilibrium oxygen partial pressure of Pb).

When the binder removal treatment temperature is lower than 300° C., the binder removal cannot be carried out smoothly. Also, when the binder removal treatment temperature exceeds 650° C., no binder removal effect commensurate with such a high temperature can be obtained to result in a waste of energy. The binder removal treatment time is needed to be determined according to the temperature and the atmosphere; the binder removal treatment time can be selected to fall within a range from 0.5 to 50 hours. Further, the binder removal treatment may be carried out separately and independently from the sintering, or may be carried out continuously with the sintering. When the binder removal treatment is carried out continuously with the sintering, the binder removal treatment may be carried out in the course of the temperature elevation in sintering.

After the binder removal treatment, the sintering (step S110) is carried out.

The laminated piezoelectric element 1 is preferably sintered under reductive sintering conditions. In the preparation of the laminated piezoelectric element 1, sintering in an oxidative atmosphere necessitates, for example, the use of a noble metal as the electrode material for the internal electrode layers 12. On the contrary, the laminated piezoelectric element 1 is a product obtained by sintering in the reductive sintering conditions, and hence low price Cu can be used for the internal electrode layers 12 in the present invention. The reductive sintering conditions are, for example, such that the sintering temperature is 800° C. to 1200° C. and the oxygen partial pressure is 1×10⁻¹⁰ to 1×10⁻⁶ atm.

When the sintering temperature is lower than 800° C., the sintering does not proceed to a sufficient extent. When the sintering temperature exceeds 1200° C., the melting of Cu is feared. The sintering temperature is preferably 850 to 1100° C. and more preferably 900 to 1050° C.

When the oxygen partial pressure is less than 1×10⁻¹⁰ atm, there is a fear that the oxide contained in the piezoelectric layer precursor, for example, PbO is reduced, metallic Pb is thereby deposited, and the piezoelectric properties of the finally obtained sintered body are degraded. When the oxygen partial pressure exceeds 1×10⁻⁶ atm, the oxidation of Cu as the electrode material is feared. The oxygen partial pressure is preferably 1×10⁻⁹ to 1×10⁻⁷ atm and more preferably 1×10⁻⁸ to 1×10⁻⁷ atm.

When the sintering is carried out under the above described reductive sintering conditions, the degradation of the electric resistance at high temperatures becomes an issue; however, in the case of the laminated piezoelectric element of the present invention, this issue can be avoided by containing CuO_{α} (α≧0) in the piezoelectric layers 11 as described above. In other words, the laminated piezoelectric element 1 of the present invention is a product obtained by sintering under the reductive sintering conditions, and hence Cu can be used for the internal electrode layers 12. In addition to this, the degradation of the high temperature load life accompanying the degradation of the electric resistance can be eliminated. Additionally, the degradation of the piezoelectric properties caused by containing CuO_{α} (α≧0) in the piezoelectric layers 11 can be avoided by containing a predetermined content of a rare earth metal element.

The laminate 10 prepared by carrying out the above-mentioned steps is subjected to end face polishing by means of, for example, barrel polishing or sandblast, and then the terminal electrodes 21 and 22 are formed by printing or baking the above-mentioned terminal electrode paste (step S111). The terminal electrodes 21 and 22 can also be formed by sputtering instead of printing or baking.

In the above described manner, the laminated piezoelectric element 1 shown in FIG. 1 can be obtained.

### EXAMPLES

Hereinafter, the present invention will be described on the basis of specific Examples.

### Example 1

An experiment carried out to verify the effect due to the addition of the first additive (MgO) will be described as Example 1.

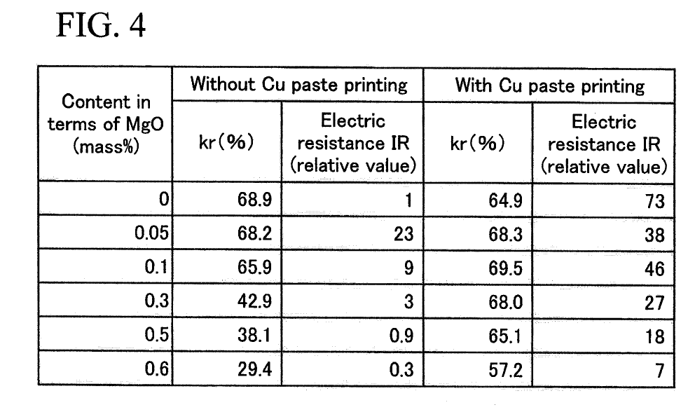

In the present experiment, Mg was added so as to give the contents in terms of MgO shown in FIG. 4, in relation to the main constituent shown below, and the effect of Mg was examined.

Main Constituent:
(Pb_{0.995-0.03}Sr_{0.03}) [(Zn_{1/3}Nb_{2/3})_{0.1}Ti_{0.43}Zr_{0.47}]O₃

Each of the piezoelectric ceramic composition samples, involving Cu paste printing, shown in FIG. 4 was prepared as follows. First, as the raw materials for the main constituent, a PbO powder, a SrCO₃ powder, a ZnO powder, a Nb₂O₅ powder, a TiO₂ powder and a ZrO₂ powder were prepared, and were weighed out to give the above-mentioned composition of the main constituent. Additionally, MgO was prepared as the addition species of Mg, and added to the base composition of the main constituent to give the content shown in FIG. 4. Then, these raw materials were wet mixed with a ball mill for 16 hours, and calcined in air at 700 to 900° C. for 2 hours.

The calcined mixture thus obtained was pulverized, and then wet milled with a ball mill for 16 hours. The milled mixture was dried, combined with an acrylic resin as a binder, and then granulated. The granulated mixture was compacted into a disc of 17 mm in diameter and 1 mm in thickness with a uniaxial press molding machine under a pressure of approximately 445 MPa. After compacting, a Cu paste containing a Cu powder of 1.0 μm in particle size was printed on both sides of this disc. The pellet thus obtained was heat treated to evaporate the binder, and sintered at 950° C. for 8 hours in a low-oxygen reductive atmosphere (oxygen partial pressure: 1×10⁻¹⁰ to 1×10⁻⁶ atm). The sintered body thus obtained was sliced and lapped into a 0.6 mm thick disc; then the printed Cu paste was removed and at the same time machined into a shape suitable for the property evaluation. A silver paste was printed on both sides of the obtained sample, and baked at 350° C. The sample was subjected to a polarization treatment in a silicone oil set at 120° C. by applying an electric field of 3 kV for 15 minutes. Additionally, other samples were prepared in the same manner as described above, inclusive of the polarization treatment, except that neither Cu paste printing nor heat treatment for evaporating the binder was carried out.

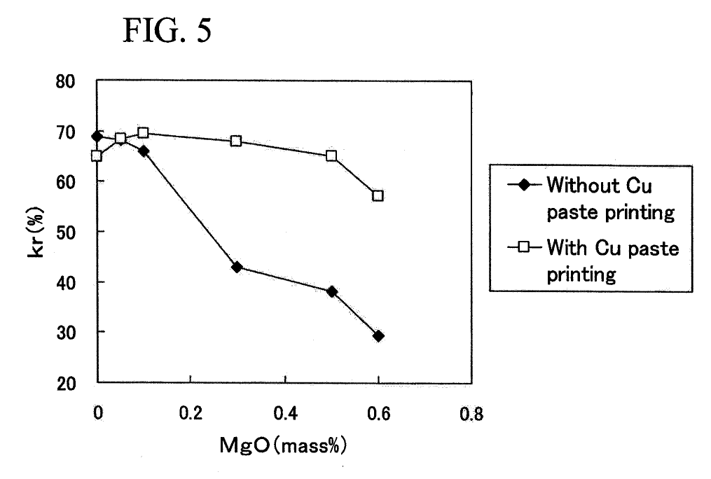

The 12 samples thus prepared were subjected to an electromechanical coupling coefficient kr (%) measurement. The electromechanical coupling coefficient kr (%) measurement was carried out by using an impedance analyzer (HP4194A, manufactured by Hewlett-Packard Co.). The results thus obtained are shown in FIG. 4. FIG. 5 shows the relation between the content of Mg(MgO) and the electromechanical coupling coefficient kr (%).

As shown in FIGS. 4 and 5, the addition of Mg(MgO) decreases the electromechanical coupling coefficient kr (%) when no Cu paste is printed, but improves the electromechanical coupling coefficient kr (%) when the Cu paste is printed. Consequently, it can be easily understood that when a laminated piezoelectric element using Cu as the conductive material for the internal electrodes is prepared, the addition of MgO can improve the electromechanical coupling coefficient kr (%) even if the above-mentioned diffusion of Cu into the piezoelectric layers occurs. Thus, according to the present invention, the electromechanical coupling coefficient kr (%) can be improved in addition to the cost reduction that can be attained by using Cu as the electrode material.

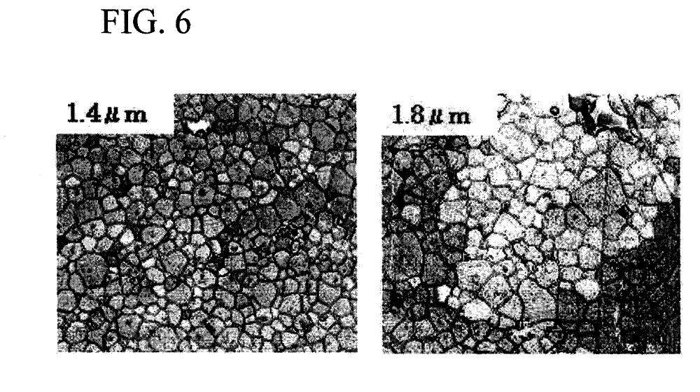

FIG. 6 shows the SEM image of a sample (left) in which the Cu paste was printed and the SEM image of a sample (right) in which MgO was added in a content of 0.1% by mass and the Cu paste was printed. From a comparison between these two images, it is interpreted that even in the presence of Cu, the addition of MgO promoted the grain growth and the electromechanical coupling coefficient kr (%) was thereby increased.

It is to be noted that the amount of the additive contained in each of the samples was the same as the added amount. This was also the case in each of following Examples.

### Example 2

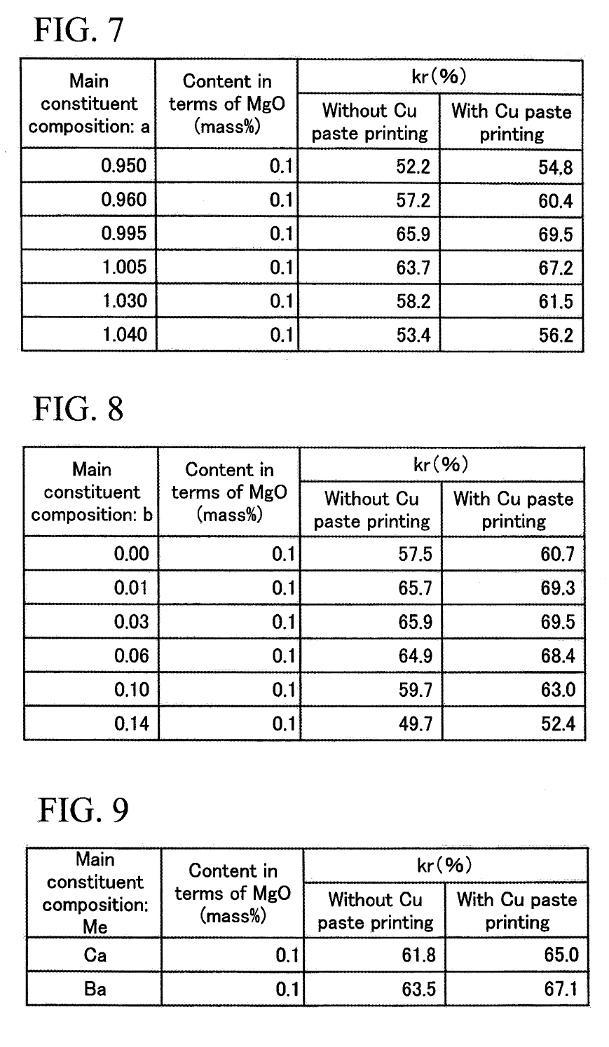

Samples were prepared in the same manner as in Example 1, except that “a” was set to have the values shown in FIG. 7 and Mg was added so as to give the content of Mg in terms MgO shown in FIG. 7, in relation to the main constituent shown below. The samples thus obtained were subjected to the electromechanical coupling coefficient kr (%) measurement in the same manner as in Example 1. The results thus obtained are shown in FIG. 7.

Main Constituent:
(Pb_{a-0.03}Sr_{0.03}) [(Zn_{1/3}Nb_{2/3})_{0.1}Ti_{0.43}Zr_{0.47}]O₃

As shown in FIG. 7, each of the samples in which the Cu paste was printed was able to attain an electromechanical coupling coefficient kr (%) of 60% or more when “a” fell within a range from 0.96 to 1.03.

### Example 3

Samples were prepared in the same manner as in Example 1, except that b was set to have the values shown in FIG. 8 and Mg was added so as to give the content of Mg in terms of MgO shown in FIG. 8, in relation to the main constituent shown below. The samples thus obtained were subjected to the electromechanical coupling coefficient kr (%) measurement in the same manner as in Example 1. The results thus obtained are shown in FIG. 8.

Main Constituent:
(Pb_{0.995-b}Sr_{b}) [(Zn_{1/3}Nb_{2/3})_{0.1}Ti_{0.43}Zr_{0.47}]O₃

As can be seen from FIG. 8, substitution of Pb in the main constituent with Sr improves the electromechanical coupling coefficient kr (%), and the substitution amount (molar ratio) of Sr is preferably 0.1 or less.

### Example 4

Samples were prepared in the same manner as in Example 1, except that Me was selected to be the elements shown in FIG. 9 and Mg was added so as to give the content of Mg in terms of MgO shown in FIG. 9, in relation to the main constituent shown below. The samples thus obtained were subjected to the electromechanical coupling coefficient kr (%) measurement in the same manner as in Example 1. The results thus obtained are shown in FIG. 9.

Main Constituent:
(Pb_{0.995-0.03}Me_{0.03}) [(Zn_{1/3}Nb_{2/3})_{0.1}Ti_{0.43}Zr_{0.47}]O₃

As can be seen from FIG. 9, when Ca or Ba is used as the substitutional element for Pb, similarly to the case where Sr is used, the improvement effect on the electromechanical coupling coefficient kr (%), due to the inclusion of MgO, can be enjoyed.

### Example 5

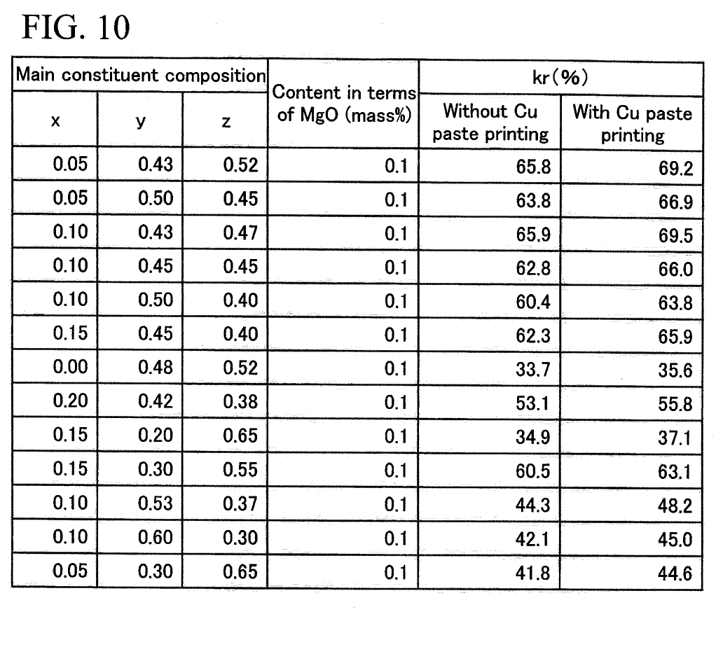

Samples were prepared in the same manner as in Example 1, except that x, y and z were set at the values shown in FIG. 10 and Mg was added so as to give the content of Mg in terms of MgO shown in FIG. 10, in relation to the main constituent shown below. The samples thus obtained were subjected to the electromechanical coupling coefficient kr (%) measurement in the same manner as in Example 1. The results thus obtained are shown in FIG. 10.

Main Constituent:
(Pb_{0.995-0.03}Sr_{0.03}) [(Zn_{1/3}Nb_{2/3})ₓTi_{y}Zr_{z}]O₃

As can be seen from FIG. 10, even when x, y and z for the B-site elements were varied, the effect due to the addition of MgO was also attained, and the electromechanical coupling coefficient kr (%) was increased by printing the Cu paste. However, when x, y and z fell outside the ranges of 0.05≦x≦0.15, 0.25≦y≦0.5 and 0.35≦z≦0.6, respectively, the electromechanical coupling coefficient kr (%) became small.

### Example 6

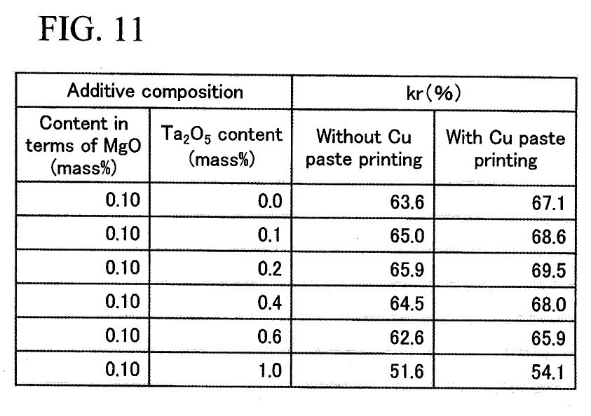

Samples were prepared in the same manner as in Example 1, except that Mg and Ta were added as additives so as to give the contents shown in FIG. 11, in terms of MqO and Ta₂O₅, respectively, in relation to the main constituent shown below. The samples thus obtained were subjected to the electromechanical coupling coefficient kr (%) measurement in the same manner as in Example 1. The results thus obtained are shown in FIG. 11.

Main Constituent:
(Pb_{0.995-0.03}Sr_{0.03}) [(Zn_{1/3}Nb_{2/3})_{0.1}Ti_{0.43}Zr_{0.47}]O₃

As can be seen from FIG. 11, the addition of Ta₂O₅ as an additive (the fourth additive) was able to improve the electromechanical coupling coefficient kr (%), the effect due to the addition of MgO was attained, and the electromechanical coupling coefficient kr (%) was increased when the Cu paste was printed. However, when the content of Ta₂O₅ became too large, the electromechanical coupling coefficient kr (%) was decreased.

### Example 7

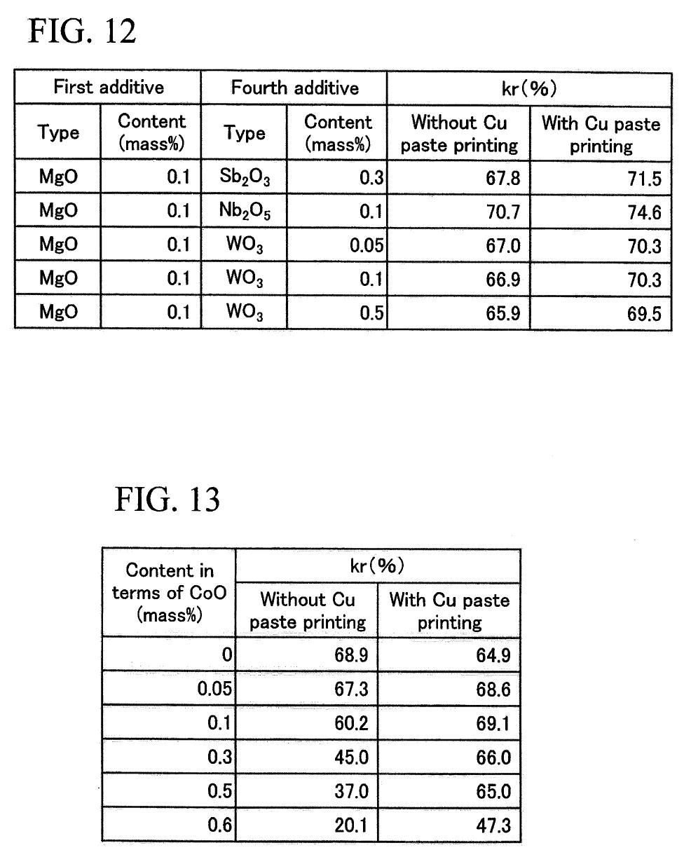

Samples were prepared in the same manner as in Example 1, except that additives (the first additive and the fourth additive) were added so as to give the contents shown in FIG. 12, in relation to the main constituent shown below. The samples thus obtained were subjected to the electromechanical coupling coefficient kr (%) measurement in the same manner as in Example 1. The results thus obtained are shown in FIG. 12.

Main Constituent:
(Pb_{0.995-0.03}Sr_{0.03}) [(Zn_{1/3}Nb_{2/3})_{0.1}Ti_{0.43}Zr_{0.47}]O₃

As can be seen from FIG. 12, the addition of Sb₂O₃, Nb₂O₅ or WO₃, as the additive (fourth additive), was able to improve the electromechanical coupling coefficient kr (%), the effect due to the addition of MgO was attained, and the electromechanical coupling coefficient kr (%) was increased when the Cu paste was printed. However, when the contents of these additives became too large, the electromechanical coupling coefficient kr (%) was decreased.

### Example 8

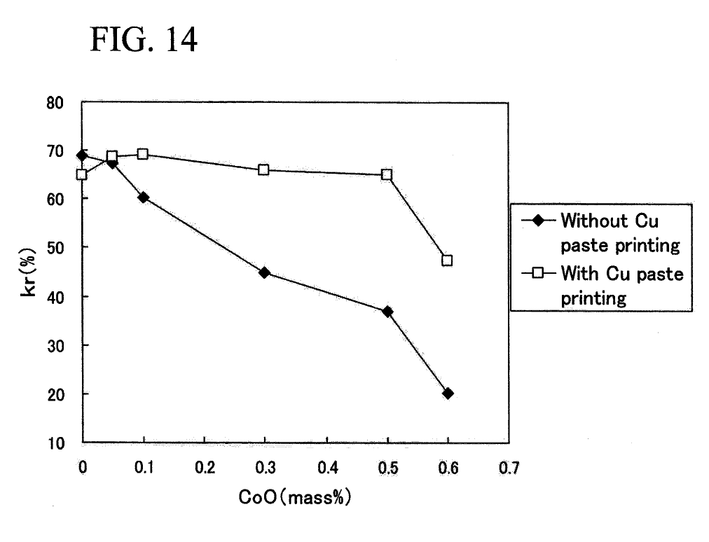

Samples were prepared in the same manner as in Example 1, except that Co was added, in place of MgO, so as to give the contents in terms of CoO shown in FIG. 13, in relation to the main constituent shown below. The samples thus obtained were subjected to the electromechanical coupling coefficient kr (%) measurement in the same manner as in Example 1. The results thus obtained are shown in FIG. 13. FIG. 14 shows the relation between the content of Co (CoO) and the electromechanical coupling coefficient kr (%).

Main Constituent:
(Pb_{0.995-0.03}Sr_{0.03}) [(Zn_{1/3}Nb_{2/3})_{0.1}Ti_{0.43}Zr_{0.47}]O₃

As shown in FIGS. 13 and 14, the addition of CoO decreases the electromechanical coupling coefficient kr (%) when no Cu paste is printed, but improves the electromechanical coupling coefficient kr (%) when the Cu paste is printed. Consequently, it can be easily understood that when a laminated piezoelectric element using Cu as the conductive material for the internal electrodes is prepared, the addition of CoO improves the electromechanical coupling coefficient kr (%) even if the above-mentioned diffusion of Cu into the piezoelectric layers occurs. Thus, according to the present invention, the electromechanical coupling coefficient kr (%) can be improved in addition to the cost reduction that can be attained by using Cu as the electrode material.

### Example 9

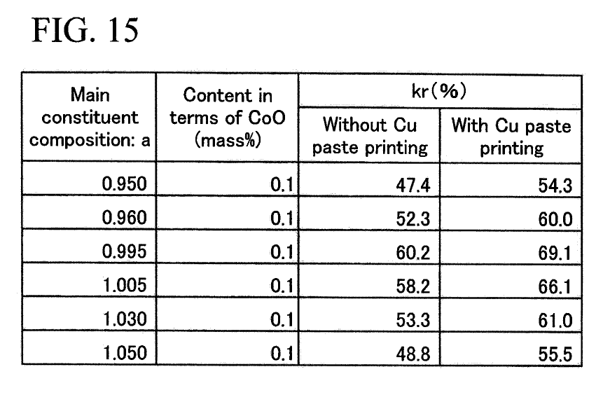

Samples were prepared in the same manner as in Example 1, except that “a” was set to have the values shown in FIG. 15 and Co was added so as to give the content of Co in terms of CoO shown in FIG. 15, in relation to the main constituent shown below. The samples thus obtained were subjected to the electromechanical coupling coefficient kr (%) measurement in the same manner as in Example 1. The results thus obtained are shown in FIG. 15.

Main Constituent:
(Pb_{a-0.03}Sr_{0.03}) [(Zn_{1/3}Nb_{2/3})_{0.1}Ti_{0.43}Zr_{0.47}]O₃

As shown in FIG. 15, each of the samples in which the Cu paste was printed was also able to attain an electromechanical coupling coefficient kr (%) of 60% or more when “a” fell within a range from 0.96 to 1.03.

### Example 10

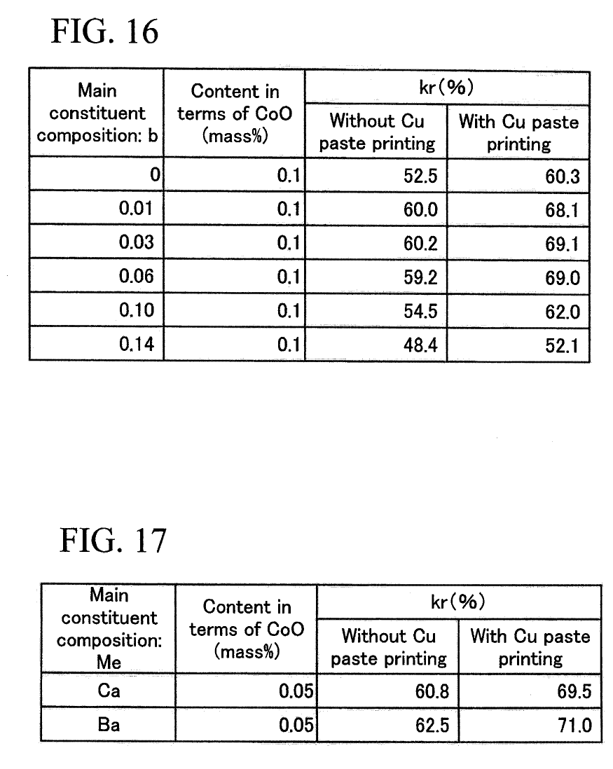

Samples were prepared in the same manner as in Example 1, except that b was set to have the values shown in FIG. 16 and Co was added so as to give the content of in terms of CoO shown in FIG. 16, in relation to the main constituent shown below. The samples thus obtained were subjected to the electromechanical coupling coefficient kr (%) measurement in the same manner as in Example 1. The results thus obtained are shown in FIG. 16.

Main Constituent:
(Pb_{0.995-b}Sr_{b}) [(Zn_{1/3}Nb_{2/3})_{0.1}Ti_{0.43}Zr_{0.47}]O₃

As can be seen from FIG. 16, substitution of Pb in the main constituent with Sr improves the electromechanical coupling coefficient kr (%), and the substitution amount (molar ratio) of Sr is preferably 0.1 or less.

### Example 11

Samples were prepared in the same manner as in Example 1, except that Me was selected to be the elements shown in FIG. 17 and Co was added so as to give the content of Co in terms of CoO shown in FIG. 17, in relation to the main constituent shown below. The samples thus obtained were subjected to the electromechanical coupling coefficient kr (%) measurement in the same manner as in Example 1. The results thus obtained are shown in FIG. 17.

Main Constituent:
(Pb_{0.995-0.03}Me_{0.03}) [(Zn_{1/3}Nb_{2/3})_{0.1}Ti_{0.43}Zr_{0.47}]O₃

As can be seen from FIG. 17, when Ca or Ba is used as the substitutional element for Pb, similarly to the case where Sr is used, the improvement effect on the electromechanical coupling coefficient kr (%), due to the inclusion of CoO, can be enjoyed.

### Example 12

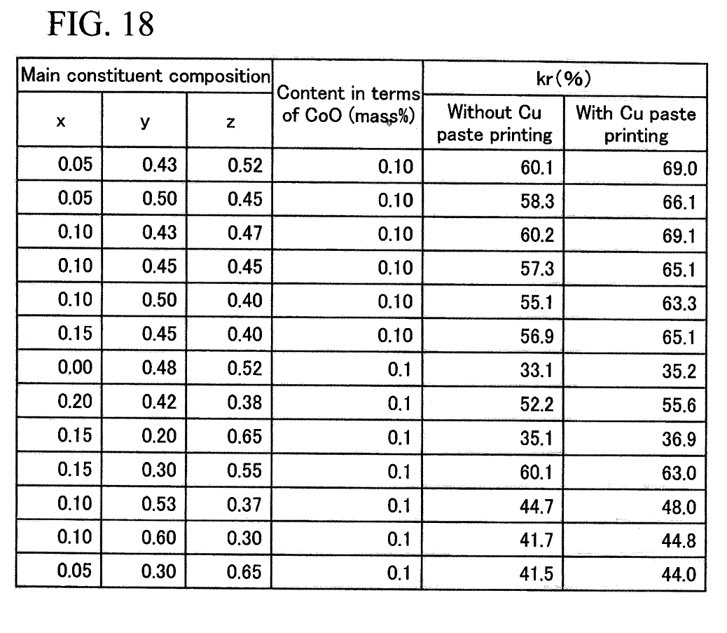

Samples were prepared in the same manner as in Example 1, except that x, y and z were set at the values shown in FIG. 18 and Co was added so as to give the content of Co in terms of CoO shown in FIG. 18, in relation to the main constituent shown below. The samples thus obtained were subjected to the electromechanical coupling coefficient kr (%) measurement in the same manner as in Example 1. The results thus obtained are shown in FIG. 18.

Main Constituent:
(Pb_{0.995-0.03}Sr_{0.03}) [(Zn_{1/3}Nb_{2/3})ₓTi_{y}Zr_{z}]O₃

As can be seen from FIG. 18, even when x, y and z for the B-site elements were varied, the effect due to the addition of CoO was also attained, and the electromechanical coupling coefficient kr (%) was increased by printing the Cu paste. However, when x, y and z fell outside the respective ranges, the electromechanical coupling coefficient kr (%) became small.

### Example 13

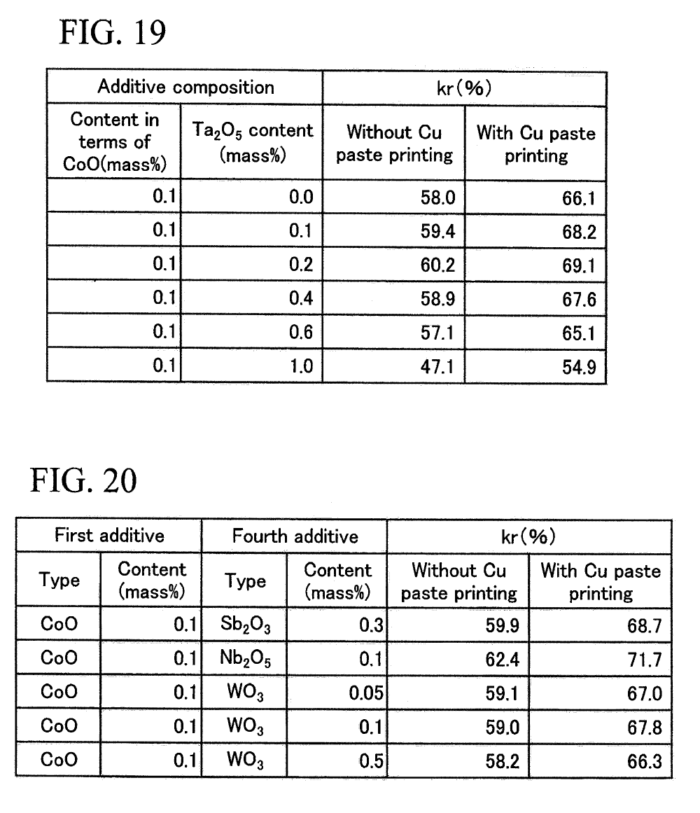

Samples were prepared in the same manner as in Example 1, except that additives (the first additive and the fourth additive) were added so as to give the contents shown in FIG. 19, in relation to the main constituent shown below. The samples thus obtained were subjected to the electromechanical coupling coefficient kr (%) measurement in the same manner as in Example 1. The results thus obtained are shown in FIG. 19.

Main Constituent:
(Pb_{0.995-0.03}Sr_{0.03}) [(Zn_{1/3}Nb_{2/3})_{0.1}Ti_{0.43}Zr_{0.47}]O₃

As can be seen from FIG. 19, the addition of Ta₂O₅, as the additive (fourth additive), was able to improve the electromechanical coupling coefficient kr (%), the effect due to the addition of CoO was attained, and the electromechanical coupling coefficient kr (%) was increased when the Cu paste was printed. However, when the content of Ta₂O₅ became too large, the electromechanical coupling coefficient kr (%) was decreased.

### Example 14

Samples were prepared in the same manner as in Example 1, except that additives (the first additive and the fourth additive) were added so as to give the contents shown in FIG. 20, in relation to the main constituent shown below. The samples thus obtained were subjected to the electromechanical coupling coefficient kr (%) measurement in the same manner as in Example 1. The results thus obtained are shown in FIG. 20.

Main Constituent:
(Pb_{0.995-0.03}Sr_{0.03}) [(Zn_{1/3}Nb_{2/3})_{0.1}Ti_{0.43}Zr_{0.47}]O₃

As can be seen from FIG. 20, the addition of Sb₂O₃, Nb₂O₅ or WO₃, as the additive (fourth additive) was able to improve the electromechanical coupling coefficient kr (%), the effect due to the addition of CoO was attained, and the electromechanical coupling coefficient kr (%) was increased when the Cu paste was printed. However, when the contents of these additives became too large, the electromechanical coupling coefficient kr (%) was decreased.

### Example 15

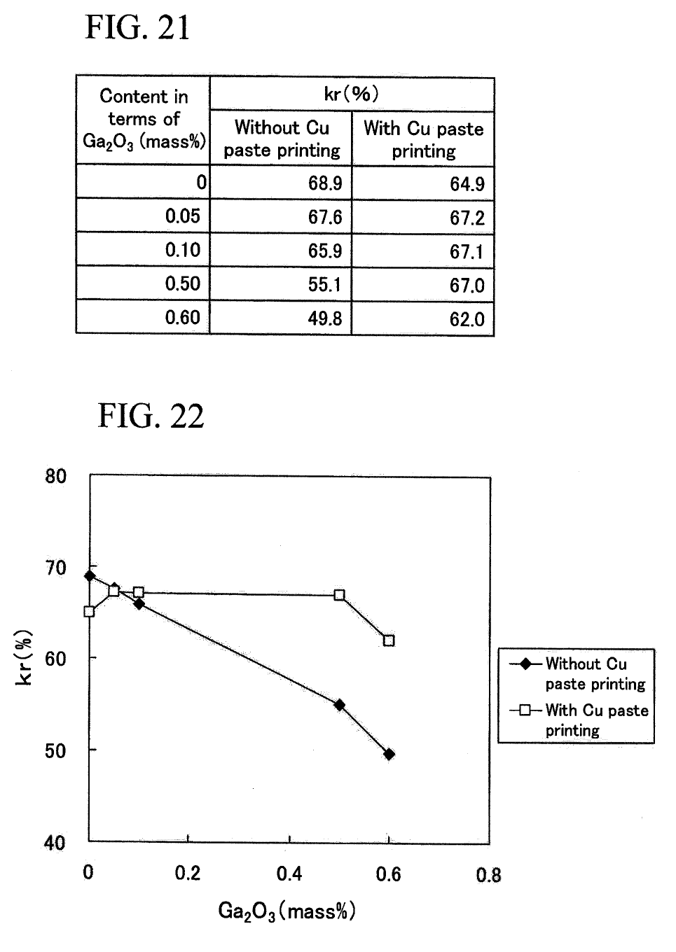

Samples were prepared in the same manner as in Example 1, except that Ga was added, in place of MgO, so as to give the contents in terms of Ga₂O₃ shown in FIG. 21, in relation to the main constituent shown below. The samples thus obtained were subjected to the electromechanical coupling coefficient kr (%) measurement in the same manner as in Example 1. The results thus obtained are shown in FIG. 21. FIG. 22 shows the relation between the content of Ga (Ga₂O₃) and the electromechanical coupling coefficient kr (%)

Main Constituent:
(Pb_{0.995-0.03}Sr_{0.03}) [(Zn_{1/3}Nb_{2/3})_{0.1}Ti_{0.43}Zr_{0.47}]O₃

As shown in FIGS. 21 and 22, the addition of Ga₂O₃ decreases the electromechanical coupling coefficient kr (%) when no Cu paste is printed, but improves the electromechanical coupling coefficient kr (%) when the Cu paste is printed. Consequently, it can be easily understood that when a laminated piezoelectric element using Cu as the conductive material for the internal electrodes is prepared, the addition of Ga₂O₃ improves the electromechanical coupling coefficient kr (%) even if the above-mentioned diffusion of Cu into the piezoelectric layers occurs. Thus, according to the present invention, the electromechanical coupling coefficient kr (%) can be improved in addition to the cost reduction that can be attained by using Cu as the electrode material.

### Example 16

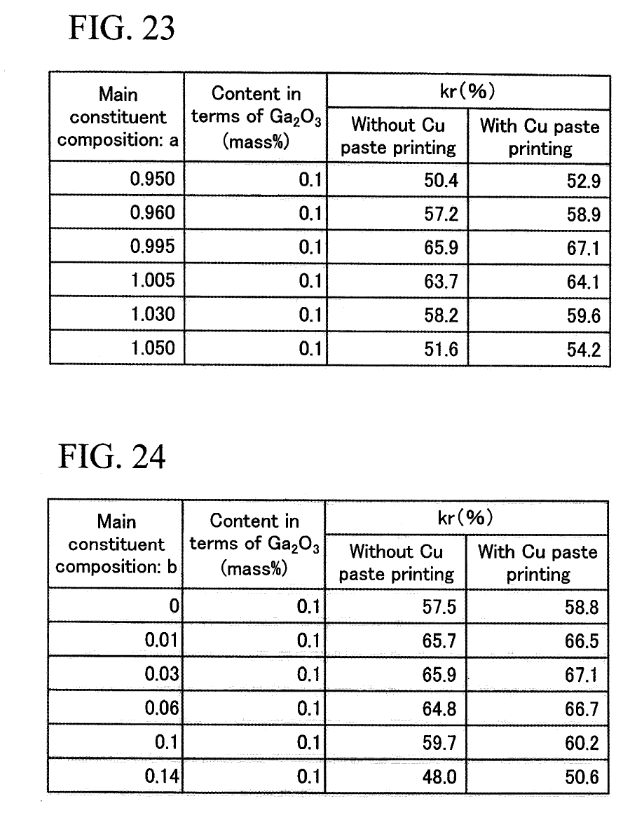

Samples were prepared in the same manner as in Example 1, except that a was set to have the values shown in FIG. 23 and Ga was added so as to give the content of Ga in terms of Ga₂O₃ shown in FIG. 23, in relation to the main constituent shown below. The samples thus obtained were subjected to the electromechanical coupling coefficient kr (%) measurement in the same manner as in Example 1. The results thus obtained are shown in FIG. 23.

Main Constituent:
(Pb_{a-0.03}Sr_{0.03}) [(Zn_{1/3}Nb_{2/3})_{0.1}Ti_{0.43}Zr_{0.47}]O₃

As shown in FIG. 23, each of the samples in which the Cu paste was printed was also able to attain an electromechanical coupling coefficient kr (%) of approximately 60% or more when “a” fell within a range from 0.96 to 1.03.

### Example 17

Samples were prepared in the same manner as in Example 1, except that b was set to have the values shown in FIG. 24 and Ga was added so as to give the content of Ga in terms of Ga₂O₃ shown in FIG. 24, in relation to the main constituent shown below. The samples thus obtained were subjected to the electromechanical coupling coefficient kr (%) measurement in the same manner as in Example 1. The results thus obtained are shown in FIG. 24.

Main Constituent:
(Pb_{0.995-b}Sr_{b}) [(Zn_{1/3}Nb_{2/3})_{0.1}Ti_{0.43}Zr_{0.47}]O₃

As can be seen from FIG. 24, substitution of Pb in the main constituent with Sr improves the electromechanical coupling coefficient kr (%), and the substitution amount (molar ratio) of Sr is preferably 0.1 or less.

### Example 18

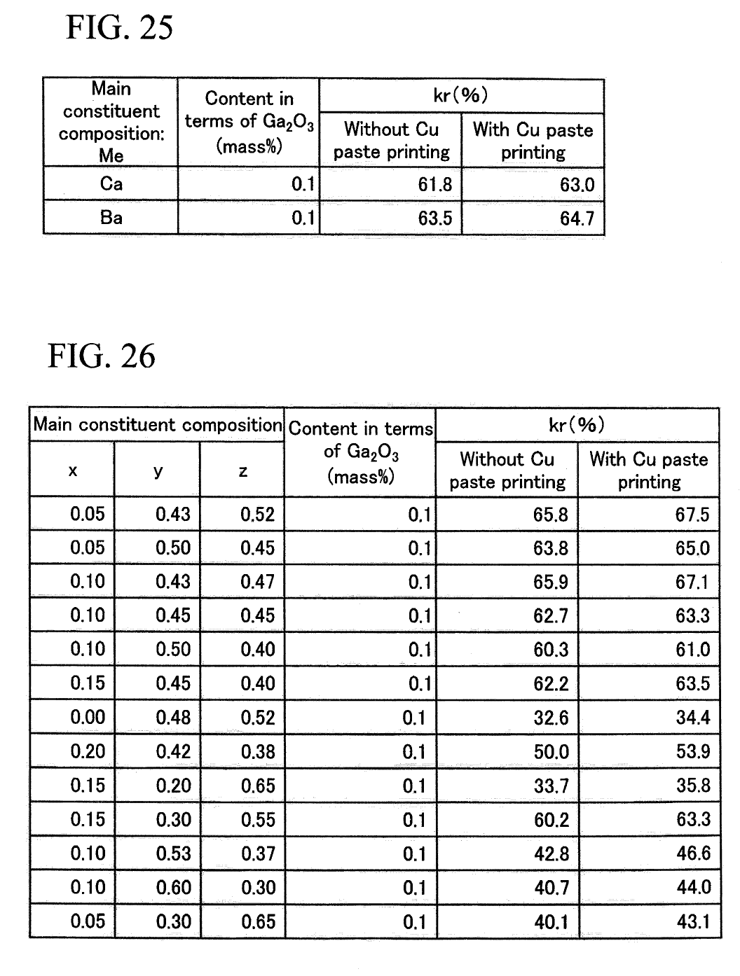

Samples were prepared in the same manner as in Example 1, except that Me was selected to be the elements shown in FIG. 25 and Ga was added so as to give the content of Ga in terms of Ga₂O₃ shown in FIG. 25, in relation to the main constituent shown below. The samples thus obtained were subjected to the electromechanical coupling coefficient kr (%) measurement in the same manner as in Example 1. The results thus obtained are shown in FIG. 25.

Main Constituent:
(Pb_{0.995-0.03}Me_{0.03}) [(Zn_{1/3}Nb_{2/3})_{0.1}Ti_{0.43}Zr_{0.47}]O₃

As shown in FIG. 25, when Ca or Ba is used as the substitutional element for Pb, similarly to the case where Sr is used, the improvement effect on the electromechanical coupling coefficient kr (%), due to the inclusion of Ga₂O₃, can also be enjoyed.

### Example 19

Samples were prepared in the same manner as in Example 1, except that x, y and z were set at the values shown in FIG. 26 and Ga was added so as to give the content of Ga in terms of Ga₂O₃ shown in FIG. 26, in relation to the main constituent shown below. The samples thus obtained were subjected to the electromechanical coupling coefficient kr (%) measurement in the same manner as in Example 1. The results thus obtained are shown in FIG. 26.

Main Constituent:
(Pb_{0.995-0.03}Sr_{0.03}) [(Zn_{1/3}Nb_{2/3})ₓTi_{y}Zr_{z}]O₃

As can be seen from FIG. 26, even when x, y and z for the B-site elements were varied, the effect due to the addition of CoO was also attained, and the electromechanical coupling coefficient kr (%) was increased by printing the Cu paste. However, when x, y and z fell outside the respective ranges, the electromechanical coupling coefficient kr (%) became small.

### Example 20

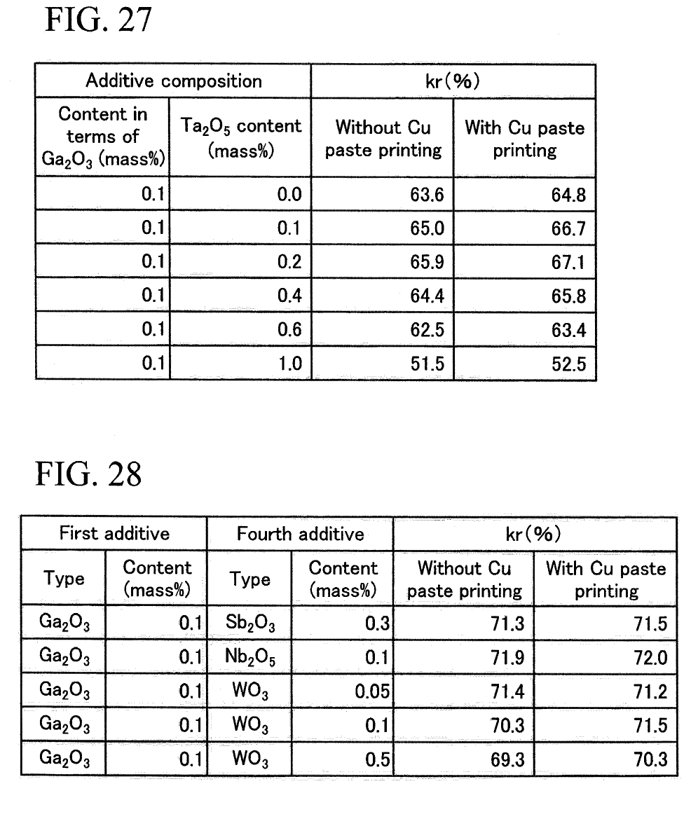

Samples were prepared in the same manner as in Example 1, except that additives (the first additive and the fourth additive) were added so as to give the contents shown in FIG. 27, in relation to the main constituent shown below. The samples thus obtained were subjected to the electromechanical coupling coefficient kr (%) measurement in the same manner as in Example 1. The results thus obtained are shown in FIG. 27.

Main Constituent:
(Pb_{0.995-0.03}Sr_{0.03}) [(Zn_{1/3}Nb_{2/3})_{0.1}Ti_{0.43}Zr_{0.47}]O₃

As can be seen from FIG. 27, the addition of Ta₂O₅ was able to improve the electromechanical coupling coefficient kr (%), the effect due to the addition of CoO was attained, and the electromechanical coupling coefficient kr (%) was increased when the Cu paste was printed. However, when the content of Ta₂O₅ became too large, the electromechanical coupling coefficient kr (%) was decreased.

### Example 21

Samples were prepared in the same manner as in Example 1, except that additives (the first additive and the fourth additive) were added so as to give the contents shown in FIG. 28, in relation to the main constituent shown below. The samples thus obtained were subjected to the electromechanical coupling coefficient kr (%) measurement in the same manner as in Example 1. The results thus obtained are shown in FIG. 28.

Main Constituent:
(Pb_{0.995-0.03}Sr_{0.03}) [(Zn_{1/3}Nb_{2/3})_{0.1}Ti_{0.43}Zr_{0.47}]O₃

As can be seen from FIG. 28, the addition of Sb₂O₃, Nb₂O₅ or WO₃, as the additive (fourth additive), was able to improve the electromechanical coupling coefficient kr (%),the effect due to the addition of Ga₂O₃ was attained, and the electromechanical coupling coefficient kr (%) was increased when the Cu paste was printed. However, when the contents of these additives became too large, the electromechanical coupling coefficient kr (%) was decreased.

### Example 22

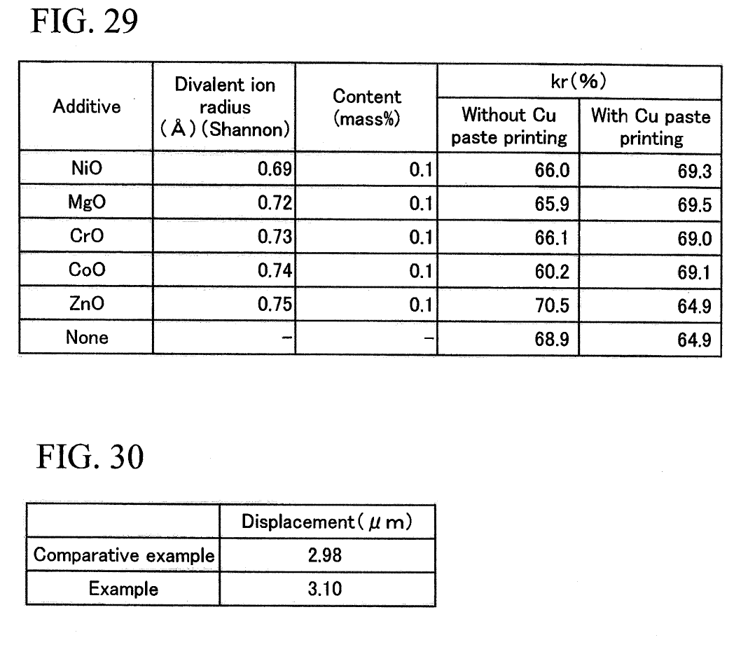

Samples were prepared in the same manner as in Example 1, except that each of the additives shown in FIG. 29 was added, in place of MgO, so as to give the content shown in FIG. 29, in relation to the main constituent shown below. The samples thus obtained were subjected to the electromechanical coupling coefficient kr (%) measurement in the same manner as in Example 1. The results thus obtained are shown in FIG. 29.

Main Constituent:
(Pb_{0.995-0.03}Sr_{0.03}) [(Zn_{1/3}Nb_{2/3})_{0.1}Ti_{0.43}Zr_{0.47}]O₃

As shown in FIG. 29, NiO and CrO, similarly to MgO and CoO, improve the electromechanical coupling coefficient kr (%) when the Cu paste is printed. Consequently, it can be easily understood that when a laminated piezoelectric element using Cu as the conductive material for the internal electrodes is prepared, the addition of NiO or CrO improves the electromechanical coupling coefficient kr (%) even if the above-mentioned diffusion of Cu into the piezoelectric layers occurs. Thus, according to the present invention, the electromechanical coupling coefficient kr (%) can be improved in addition to the cost reduction that can be attained by using Cu as the electrode material.

### Example 23

By using the powders before calcination, corresponding to the sample (comparative example) in which the content of Mg in terms of MgO is 0% by mass and the sample (example) in which the content of Mg in terms of MgO is 0.1% by mass, among the samples described in FIG. 4, laminated piezoelectric elements as shown in FIG. 1 were prepared. The thickness of each of the piezoelectric layers 11 sandwiched between the internal electrode layers 12 was set at 25 μm, and the lamination number of the piezoelectric layers was set at 100 in each of the samples. The dimension of each of the laminates was 4 mm long×4 mm wide. For the internal electrode layers 12, the same internal electrode Cu paste as used in Example 1 was used, and sintering was carried out in a reductive atmosphere falling within range of the reductive atmosphere recommended by the present invention. The piezoelectric elements thus obtained were subjected to a displacement magnitude measurement with an applied voltage of 43 V. The results thus obtained are shown in FIG. 30.

### Example 24

Description will be made on Examples 24 to 32 in which in addition to the first additive, the second additive and the third additive were further added.

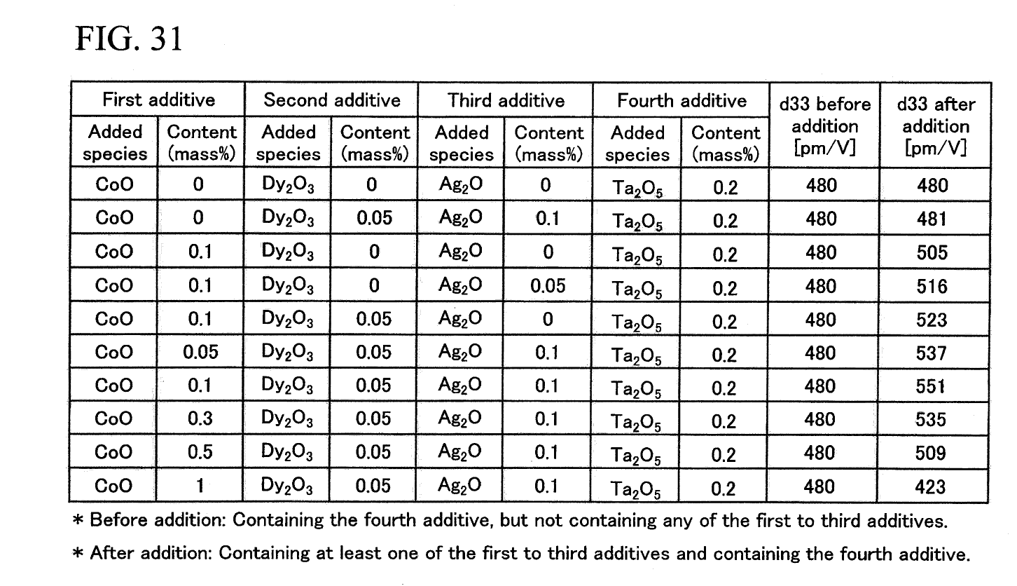

The first additive (CoO), the second additive (Dy₂O₃), the third additive (Ag₂O) and the fourth additive (Ta₂O₅) were added so as to give the contents shown in FIG. 31, in relation to the main constituent shown below, and the effects of these additives were examined.

Main Constituent:
(Pb_{0.995-0.03}Sr_{0.03}) [(Zn_{1/3}Nb_{2/3})_{0.1}Ti_{0.43}Zr_{0.47}]O₃

Each of the piezoelectric ceramic composition samples shown in FIG. 31 was prepared as follows. First, as the raw materials for the main constituent, a PbO powder, a SrCO₃ powder, a ZnO powder, a Nb₂O₅ powder, a TiO₂ powder and a ZrO₂ powder were prepared, and were weighed out to give the above-mentioned composition of the main constituent. Additionally, a CoO powder, a Dy₂O₃ powder, a Ag₂O powder and a Ta₂O₅ powder were prepared, and were added to the base composition of the main constituent to give the contents shown in FIG. 31. Then, these raw materials were wet mixed with a ball mill for 16 hours, and calcined in air at 700 to 900° C. for 2 hours.

The calcined mixture thus obtained was pulverized, and then wet milled with a ball mill for 16 hours. The milled mixture was dried, combined with an acrylic resin as a binder, and then granulated. The granulated mixture was compacted into a disc-shaped pellet of 17 mm in diameter and 1 mm in thickness with a uniaxial press molding machine under a pressure of approximately 445 MPa. After compacting, a Cu paste containing a Cu powder of 1.0 μm in particle size was printed on both sides of this disc. The pellet thus obtained was heat treated to evaporate the binder, and sintered at 950° C. for 8 hours in a low-oxygen reductive atmosphere (oxygen partial pressure: 1×10⁻¹⁰ to 1×10⁻⁶ atm). The sintered body thus obtained was sliced and lapped into a 0.6 mm thick disc; then the printed Cu paste was removed and at the same time machined into a shape suitable for the property evaluation. A silver paste was printed on both sides of the obtained sample, and baked at 350° C. The sample was subjected to a polarization treatment in a silicone oil set at 120° C. by applying an electric field of 3 kV for 15 minutes. Additionally, another sample was prepared in the same manner as described above, inclusive of the polarization treatment, except that neither Cu paste printing nor heat treatment for evaporating the binder was carried out.

The samples thus prepared were subjected to the piezoelectric constant d33 measurement. The piezoelectric constant d33 measurement was carried out by using an impedance analyzer (HP4194A, manufactured by Hewlett-Packard Co.) on the basis of the resonance-antiresonance method. The results thus obtained are also shown in FIG. 31.

From the results of the piezoelectric constant d33 measurement, the following were found.

When the first additive (CoO) is not contained, the piezoelectric strain constant is not improved even if the second additive (Dy₂O₃) and the third additive (Ag₂O) are contained.

By containing the first additive (CoO), the piezoelectric strain constant is improved even if either the second additive (Dy₂O₃) or the third additive (Ag₂O) are not contained.

By containing the first additive (CoO), and by further containing the second additive (Dy₂O₃) or the third additive (Ag₂O), the piezoelectric strain constant is improved, and by further containing the second additive (Dy₂O₃) and the third additive (Ag₂O), the piezoelectric strain constant is further improved.

As can be seen from the above, the first additive (CoO) can improve the piezoelectric strain constant even when added alone; however, by further containing any one or both of the second additive (Dy₂O₃) and the third additive (Ag₂O), the improvement effect on the piezoelectric strain constant becomes remarkable. On the other hand, the inclusion of the first additive (CoO) is a prerequisite for the improvement effect on the piezoelectric strain constant due to any one or both of the second additive (Dy₂O₃) and the third additive (Ag₂O).

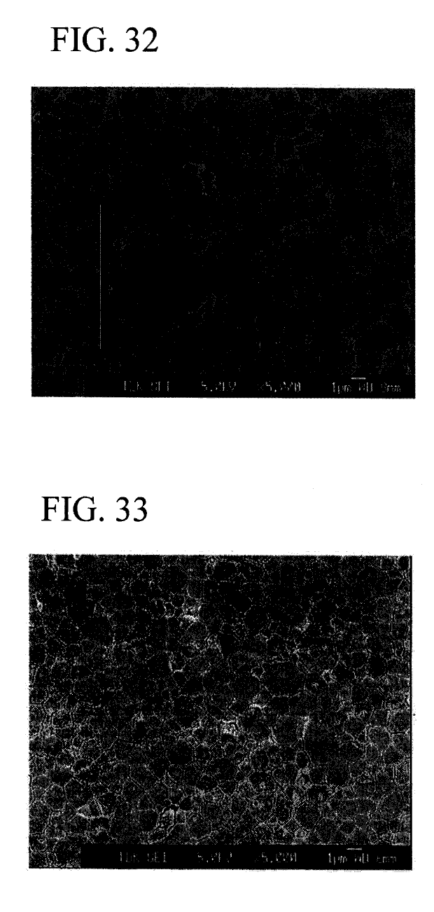

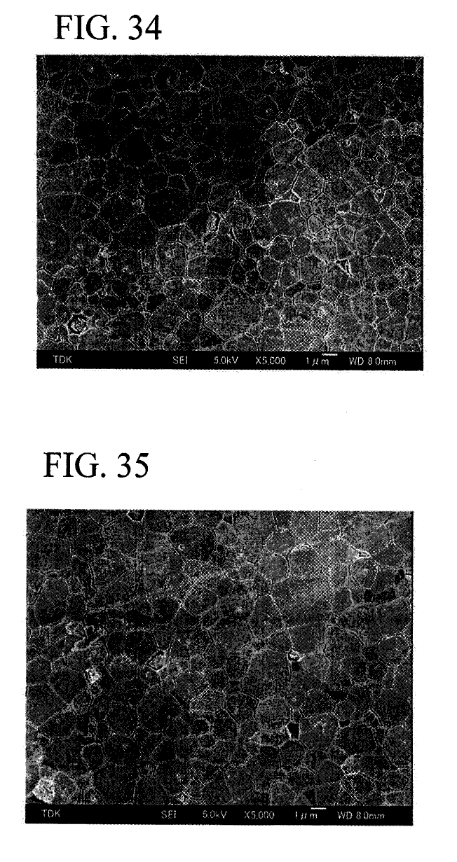

FIG. 32 is a microstructure photograph of a sintered body (d33=502 pm/V) obtained by sintering a compacted body containing a fourth additive but not containing any of first to third additives without coating a Cu paste on the compacted body. FIG. 33 is a microstructure photograph of a sintered body obtained by sintering a compacted body containing the fourth additive but not containing any of the first to the third additives with coating the Cu paste on the compacted body. FIG. 34 is a microstructure photograph of a sintered body obtained by sintering a compacted body containing both the first additive (CoO: 0.1% by mass) and the fourth additive but not containing either of the second additive and the third additive with coating the Cu paste on the compacted body. FIG. 35 is a microstructure photograph of a sintered body obtained by sintering a compacted body containing the first additive to the fourth additive (CoO: 0.1% by mass; Dy₂O₃: 0.05% by mass; Ag₂O: 0.1% by mass; Ta₂O₅: 0.2% by mass) with coating the Cu paste on the compacted body.

The grain size in FIG. 33 is smaller than that in FIG. 32. The sintered body shown in FIG. 33 underwent the diffusion of Cu into the sintered body as a result of the Cu paste coating; the presence of Cu in the sintered body inhibited the preferable grain size growth. This is inferred to be a factor for the degradation of the piezoelectric strain constant. As shown in FIG. 34, the sintered body combined with CoO is larger in grain size than the sintered body in FIG. 33; thus, it can be seen that CoO has an effect of promoting the grain growth. The grain size of the sintered body shown in FIG. 35 is of the same order of magnitude as that of the sintered body in FIG. 32; thus, it can be seen that the effect of CoO is attained even when the first additive to the fourth additive are contained in combination. Such preferable grain size growth makes it possible to enjoy the improvement effect on the piezoelectric strain constant.

When the content of the first additive (CoO) contained in a sintered body becomes large to reach 1.0% by mass, the improvement effect on the piezoelectric strain constant is reduced or lost. Accordingly, in the present invention, the content of the first additive (CoO) is set at 0.5% by mass or less. From the results shown in FIG. 31, the content of the first additive is preferably 0.03 to 0.4% by mass, and more preferably 0.05 to 0.3% by mass.

### Example 25

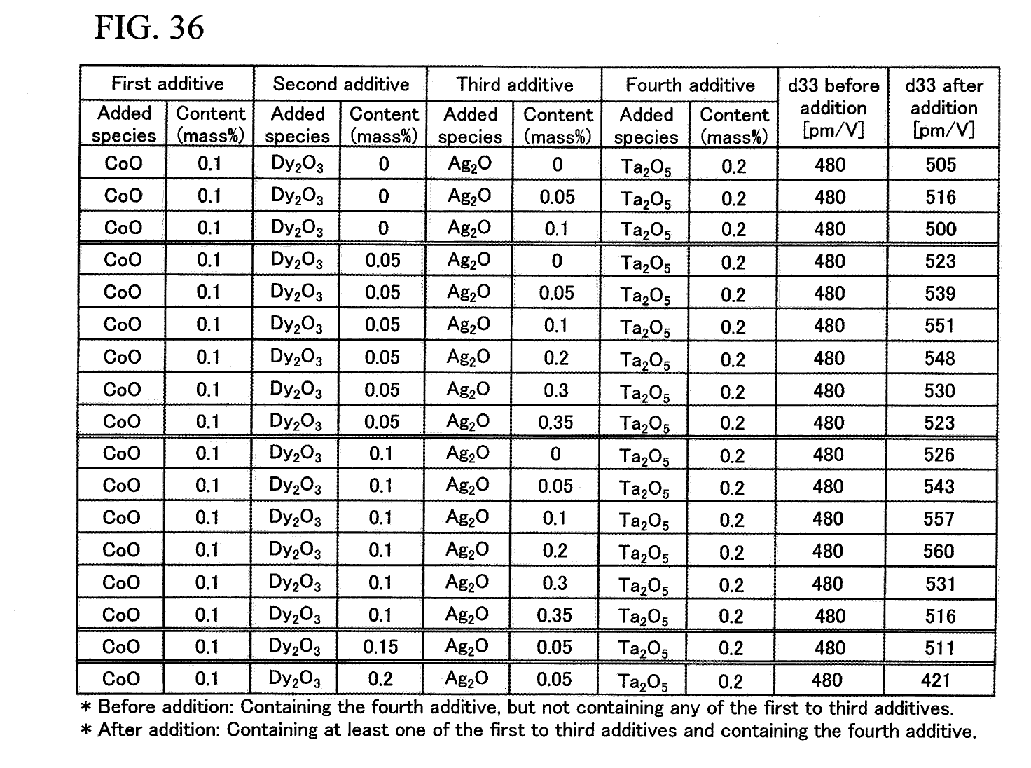

Samples were prepared, inclusive of the polarization treatment, in the same manner as in Example 24 except that the composition of the raw materials was adjusted so as for the first additive (CoO), the second additive (Dy₂O₃), the third additive (Ag₂O) and the fourth additive (Ta₂O₅) to have the contents shown in FIG. 36, in relation to the main constituent shown below. The samples were subjected to the piezoelectric constant d33 measurement in the same manner as in Example 24. The results thus obtained are shown in FIG. 36.

Main Constituent:
(Pb_{0.995-0.03}Sr_{0.03}) [(Zn_{1/3}Nb_{2/3})_{0.1}Ti_{0.43}Zr_{0.47}]O₃

As shown in FIG. 36, when the content of the second additive (Dy₂O₃) exceeds 0.15% by mass, the piezoelectric strain constant is decreased. From the viewpoint of the piezoelectric strain constant, the content of the second additive (Dy₂O₃) is preferably 0.02 to 0.1% by mass, and more preferably 0.03 to 0.07% by mass.

When the content of the third additive (Ag₂O) exceeds 0.1% by mass without containing the second additive (Dy₂O₃), the piezoelectric strain constant is decreased. From the viewpoint of the piezoelectric strain constant, the content of the third additive (Ag₂O) is preferably 0.02 to 0.08% by mass, and more preferably 0.03 to 0.07% by mass.

When the second additive (Dy₂O₃) is contained, the third additive (Ag₂O) contributes to a further improvement of the piezoelectric strain constant. However, when the content of the third additive (Ag₂O) exceeds 0.35% by mass, only low piezoelectric strain constants can be obtained. From the viewpoint of the piezoelectric strain constant, the content of the third additive is preferably 0.02 to 0.25% by mass, and more preferably 0.05 to 0.15% by mass.

### Example 26

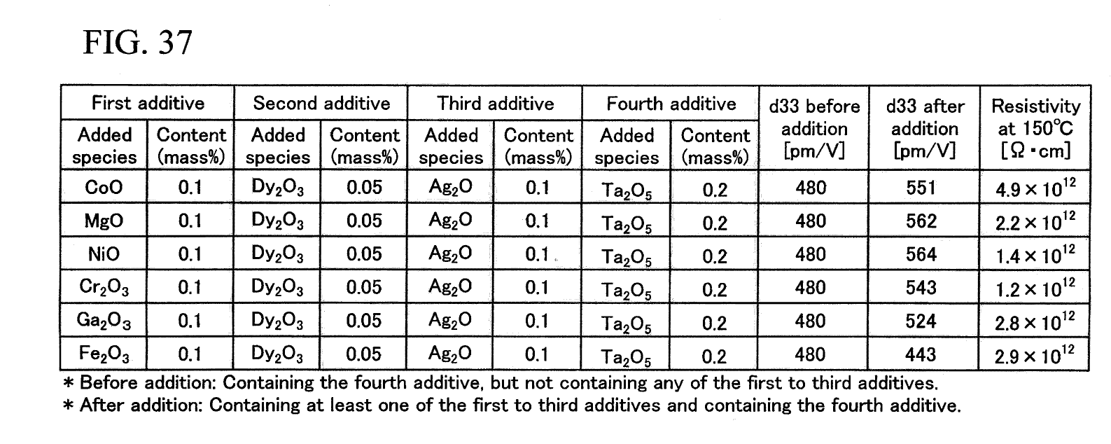

Samples were prepared, inclusive of the polarization treatment, in the same manner as in Example 24 except that the composition of the raw materials was adjusted so as for the first additive (CoO, MgO, NiO, Cr₂O₃, Ga₂O₃, or Fe₂O₃), the second additive (Dy₂O₃), the third additive (Ag₂O) and the fourth additive (Ta₂O₅) to have the contents shown in FIG. 37, in relation to the main constituent shown below. The samples were subjected to the piezoelectric constant d33 measurement in the same manner as in Example 24. Additionally, the samples were also subjected to the measurement of the resistivity at 150° C. The results thus obtained are shown in FIG. 37.

Main Constituent:
(Pb_{0.995-0.03}Sr_{0.03}) [(Zn_{1/3}Nb_{2/3})_{0.1}Ti_{0.43}Zr_{0.47}]O₃

It has been revealed that MgO, NiO, Cr₂O₃ and Ga₂O₃ contribute, similarly to CoO, to the improvement of the piezoelectric strain constant. Preferred from the viewpoint of the improvement effect on the piezoelectric strain constant are CoO, MgO and NiO. Additional consideration of the electric resistance required for the piezoelectric layers in a laminated piezoelectric element favors CoO as the second additive.

### Example 27

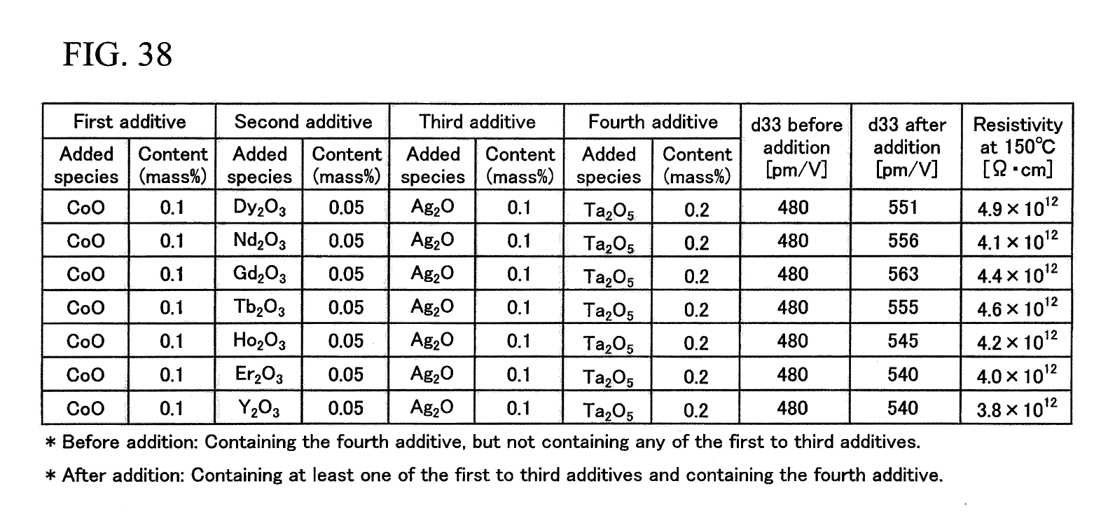

Samples were prepared, inclusive of the polarization treatment, in the same manner as in Example 24 except that the composition of the raw materials was adjusted so as for the first additive (CoO), the second additive (Dy₂O₃, Nd₂O₃, Gd₂O₃, Tb₂O₃, Ho₂O₃, Er₂O₃ or Y₂O₃), the third additive (Ag₂O) and the fourth additive (Ta₂O₅) to have the contents shown in FIG. 38, in relation to the main constituent shown below. The samples were subjected to the piezoelectric constant d33 measurement in the same manner as in Example 24, and the measurement of the resistivity at 150° C. The results thus obtained are shown in FIG. 38.

Main Constituent:
(Pb_{0.995-0.03}Sr_{0.03}) [(Zn_{1/3}Nb_{2/3})_{0.1}Ti_{0.43}Zr_{0.47}]O₃

It has been revealed that Nd₂O₃, Gd₂O₃, Tb₂O₃, Ho₂O₃, Er₂O₃ and Y₂O₃ also contribute, similarly to Dy₂O₃, to the improvement of the piezoelectric properties. Among these, Nd₂O₃, Gd₂O₃ and Tb₂O₃, remarkably contribute, similarly to Dy₂O₃, to the improvement effect on the piezoelectric strain constant. However, additional consideration of the electric resistance most favors Dy₂O₃, as the second additive.

### Example 28

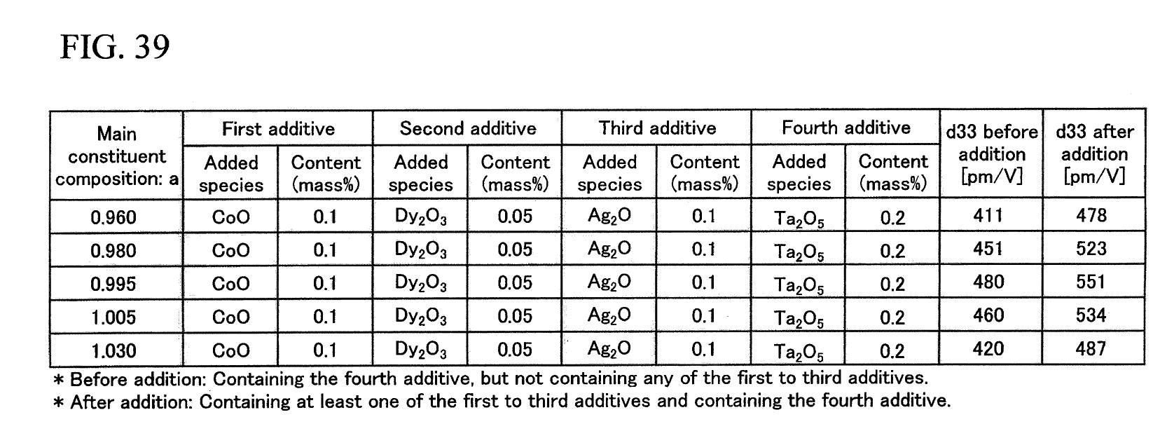

Samples were prepared in the same manner as in Example 24 except that the composition of the raw materials was adjusted so as for “a” to have the values shown in FIG. 39, and so as for the first additive (CoO), the second additive (Dy₂O₃), the third additive (Ag₂O) and the fourth additive (Ta₂O₅) to have the contents shown in FIG. 39, in relation to the main constituent shown below. The samples thus obtained were subjected to the piezoelectric constant d33 measurement in the same manner as in Example 24. The results obtained are shown in FIG. 39.

Main Constituent:
(Pb_{a-0.03}Sr_{0.03}) [(Zn_{1/3}Nb_{2/3})_{0.1}Ti_{0.43}Zr_{0.47}]O₃

As shown in FIG. 39, the piezoelectric strain constant can be ensured for a falling within a range from 0.96 to 1.03. Preferably “a” is 0.97 to 1.02, and more preferably “a” is 0.98 to 1.01.

### Example 29

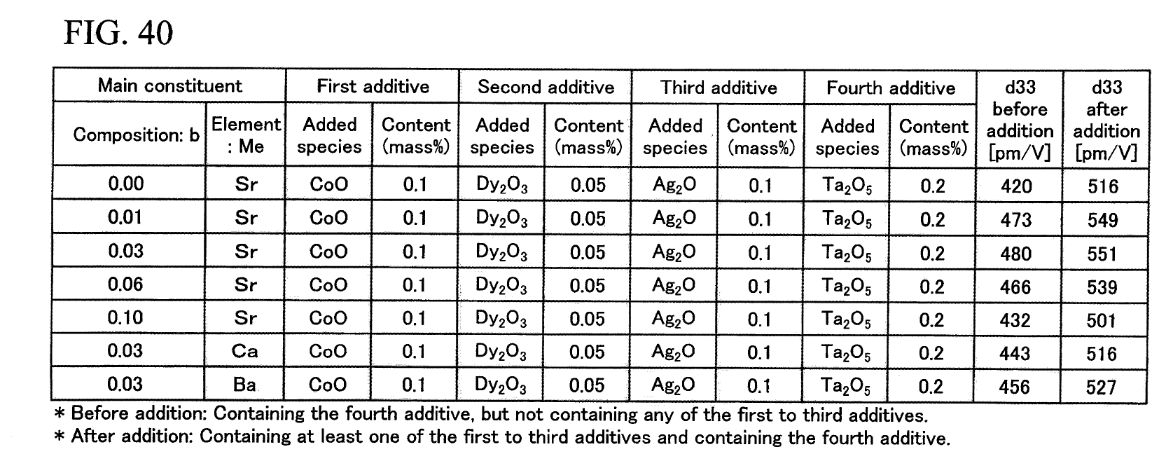

Samples were prepared in the same manner as in Example 24 except that the composition of the raw materials was adjusted so as for Me, b, the first additive (CoO), the second additive (Dy₂O₃), the third additive (Ag₂O) and the fourth additive (Ta₂O₅) to give the compositions shown in FIG. 40, in relation to the main constituent shown below. The samples thus obtained were subjected to the piezoelectric constant d33 measurement in the same manner as in Example 24. The results thus obtained are shown in FIG. 40.

Main Constituent:
(Pb_{0.995-b}Me_{b}) [(Zn_{1/3}Nb_{2/3})_{0.1}Ti_{0.43}Zr_{0.47}]O₃

As shown in FIG. 40, the piezoelectric strain constant can be ensured for b falling within a range from 0 to 0.1. Preferably b is 0.005 to 0.08, and more preferably b is 0.007 to 0.05.

### Example 30

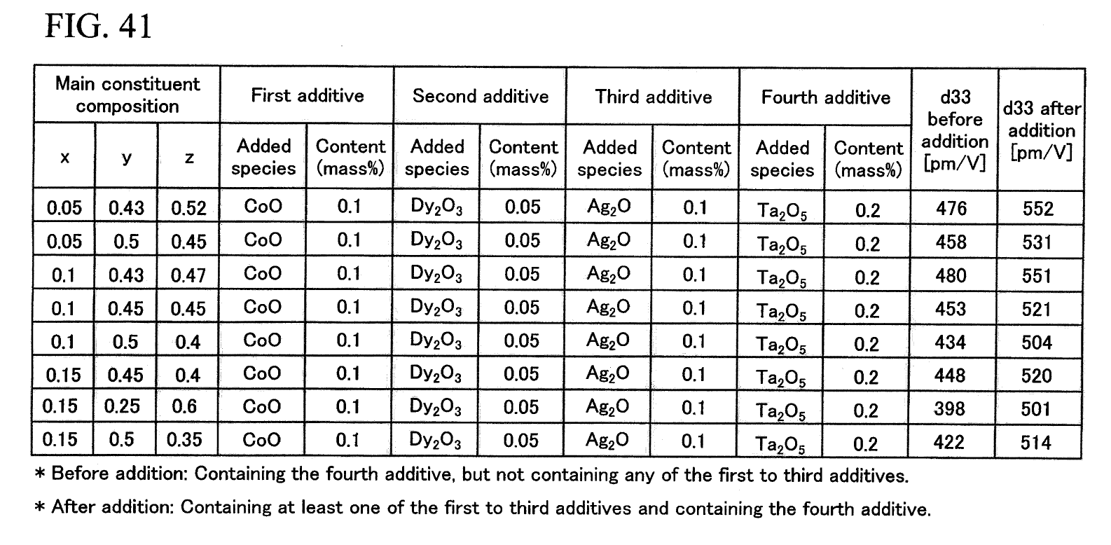

Samples were prepared in the same manner as in Example 24, except that the composition of the raw materials was adjusted so as for x, y and z to be set at the values shown in FIG. 41, and so as for the first additive (CoO), the second additive (Dy₂O₃), the third additive (Ag₂O) and the fourth additive (Ta₂O₅) to have the contents shown in FIG. 41, in relation to the main constituent shown below. The samples thus obtained were subjected to the piezoelectric constant d33 measurement in the same manner as in Example 24. The results thus obtained are shown in FIG. 41.

Main Constituent:
(Pb_{0.995-0.03}Sr_{0.03}) [(Zn_{1/3}Nb_{2/3})ₓTi_{y}Zr_{z}]O₃

As can be seen from FIG. 41, when the x, y and z for the B-site elements fall within the ranges of 0.05≦x≦0.15, 0.25≦y≦0.5 and 0.35≦z≦0.6, respectively, the improvement effect on the piezoelectric strain constant can be enjoyed.

### Example 31

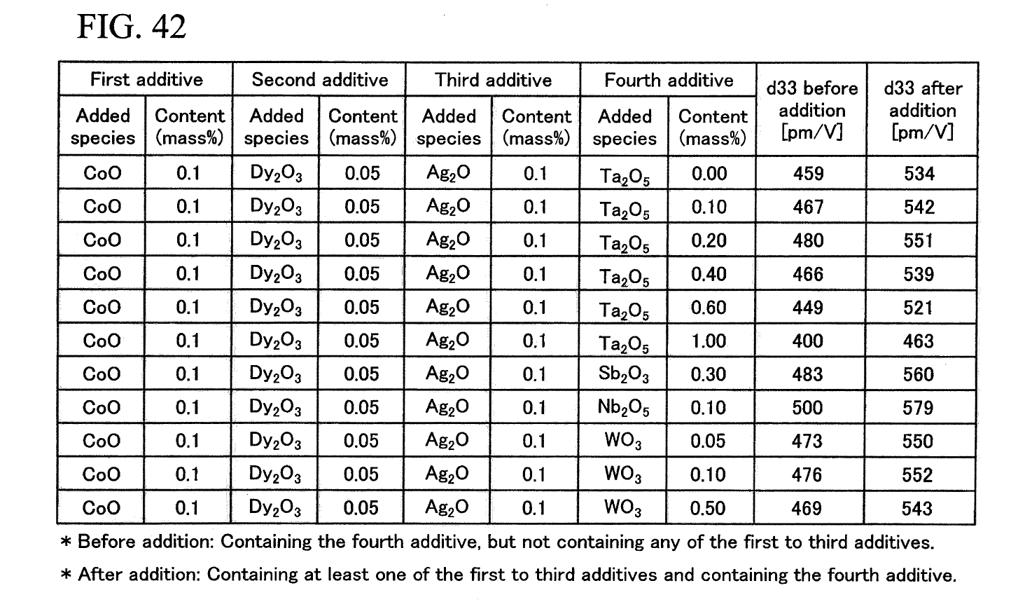

Samples were prepared in the same manner as in Example 24, except that the composition of the raw materials was adjusted so as for the first additive (CoO), the second additive (Dy₂O₃), the third additive (Ag₂O) and the fourth additive (Ta₂O₅, Sb₂O₃, Nb₂O₅ or WO₃) to have the contents shown in FIG. 42, in relation to the main constituent shown below. The samples thus obtained were subjected to the piezoelectric constant d33 measurement in the same manner as in Example 24. The results thus obtained are shown in FIG. 42.

Main Constituent:
(Pb_{0.995-0.03}Sr_{0.03}) [(Zn_{1/3}Nb_{2/3})_{0.1}Ti_{0.43}Zr_{0.47}]O₃

As shown in FIG. 42, the addition of the fourth additive Ta₂O₅ can improve the piezoelectric constant d33. However, when the content of Ta₂O₅ exceeds 0.5% by mass, the piezoelectric constant d33 becomes smaller than when Ta₂O₅ is not added. Accordingly, when Ta₂O₅ is contained, the content of Ta₂O₅ is preferably set at 0.5% by mass or less. The content of Ta₂O₅ is more preferably 0.05 to 0.4% by mass and furthermore preferably 0.15 to 0.35% by mass. As the fourth additives, Sb₂O₃, Nb₂O₅ and WO₃ are also effective in improving the piezoelectric strain constant, similarly to Ta₂O₅.

### Example 32

Example 32 presents an example of the preparation of a piezoelectric element.

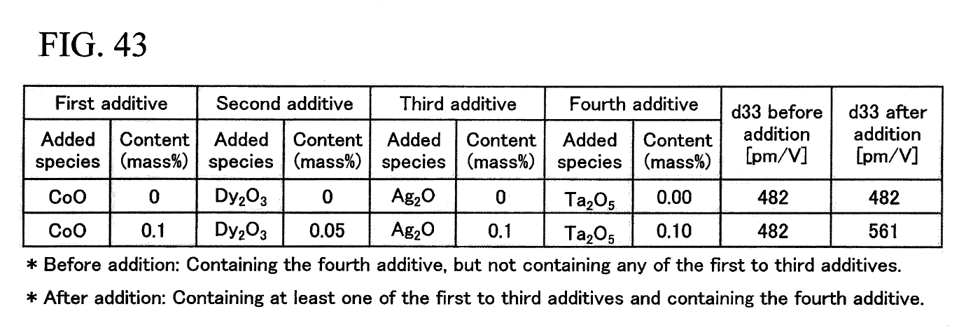

In the preparation of a laminated piezoelectric element, first, a calcined mixture (CoO: 0.1% by mass, Dy₂O₃: 0.05% by mass, Ag₂O: 0.1% by mass, Ta₂O₅: 0.2% by mass) obtained in the same manner as in Example 24 was pulverized. The piezoelectric ceramic composition powder thus obtained was combined with a vehicle, and kneaded to yield a piezoelectric layer paste. An internal electrode layer paste was also prepared by kneading a Cu powder as the conductive material with a vehicle. Then, by using the piezoelectric layer paste and the internal electrode layer paste, a green chip as a precursor for a laminate was prepared by means of a printing method. The lamination number of the piezoelectric layer paste was set at 300. The green chip was subject to a binder removal treatment, and then sintered under reductive sintering conditions to yield a laminate. The reductive sintering conditions were such that sintering was carried out in a reductive atmosphere (oxygen partial pressure: 1×10⁻¹⁰ to 1×10⁻⁶ atm) at sintering temperatures of 800 to 1200° C. For comparison, another laminate was prepared in the same manner as described above except that CoO, Dy₂O₃, and Ag₂O were not added. The laminates thus obtained were subjected to the piezoelectric constant d33 measurement in the same manner as in Example 24. The results thus obtained are shown in FIG. 43.

### Example 33

Examples 33 to 40 describe examples of the improvement of the high temperature electric resistance due to the presence of the CuO_{α} and examples of the improvement of the piezoelectric property due to the addition of the second additive.

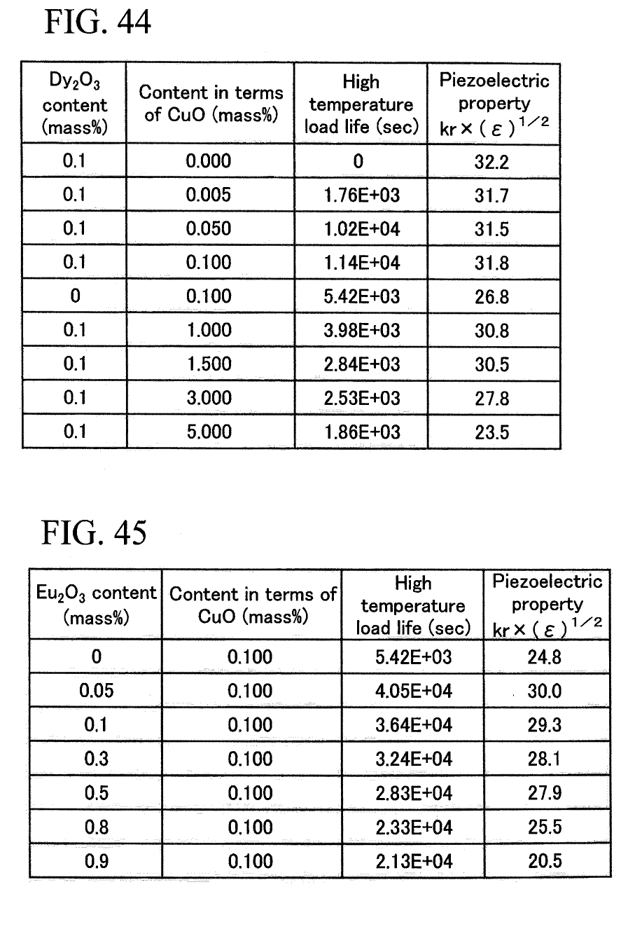

In Example 33, there were prepared piezoelectric ceramic compositions in each of which Dy₂O₃ was added as the oxide of a rare earth metal element in the content shown in FIG. 44 and CuO as CuO_{α} (α≧0) was added in the content shown in FIG. 44, in relation to the main constituent shown below. The effects of CuO_{α} (α≧0) and Dy₂O₃ were examined.

Main Constituent:
(Pb_{0.995-0.03}Sr_{0.03}) [(Zn_{1/3}Nb_{2/3})_{0.1}Ti_{0.43}Zr_{0.47}]O₃

Each of the piezoelectric ceramic compositions shown in FIG. 44 was prepared as follows. First, as the raw materials for the main constituent, a PbO powder, a SrCO₃ powder, a ZnO powder, a Nb₂O₅ powder, a TiO₂ powder, a ZrO₂ powder and a rare earth oxide powder were prepared, and were weighed out to give the above-mentioned composition of the main constituent. Then, these raw materials were wet mixed with a ball mill for 16 hours, and calcined in air at 700 to 900° C. for 2 hours.

The calcined mixture thus obtained was pulverized and combined with a raw material for CuO_{α} (α≧0) (added species: CuO), and then wet milled with a ball mill for 16 hours. The milled mixture was dried, combined with an acrylic resin as a binder, and then granulated. The granulated mixture was compacted into a disc of 17 mm in diameter and 1 mm in thickness with a uniaxial press molding machine under a pressure of approximately 445 MPa. After compacting, the disc was heat treated to evaporate the binder, and then sintered at 950° C. for 2 to 8 hours in a low-oxygen reductive atmosphere (oxygen partial pressure: 1×10⁻¹⁰ to 1×10⁻⁶ atm). The sintered body thus obtained was lapped into a 0.6 mm thick disc; then silver electrodes were formed on both sides of the disc by an evaporation method, and the disc was subjected to a polarization treatment in a silicone oil set at 120° C. by applying an electric field of 3 kV for 15 minutes.

The piezoelectric ceramic composition thus prepared was subjected to a high temperature load life test, and further to piezoelectric property evaluation.

The high temperature load life test is a test in which five specimens were used; a voltage of 3.2 kV was applied to each of the specimens at 250° C. so as for the electric field strength to be 8 kV/mm, and the time variation of the electric resistance of the specimen was measured; the life time of each of the specimens was defined as the time required for the electric resistance of the specimen to decrease by at least 0.5 orders of magnitude with respect to the electric resistance at the start of the test; the high temperature load life was the average of the five values thus measured.

The piezoelectric property was evaluated as the product between the electromechanical coupling coefficient kr (%) and the square root of the dielectric constant (ε^{1/2}). The electromechanical coupling coefficient kr (%) measurement was carried out by using an impedance analyzer (HP4194A, manufactured by Hewlett-Packard Co.). The results thus obtained are shown in FIG. 44. It is to be noted that “E+0n” in the column under the heading of the “high temperature load life” in FIG. 44 means “×10ⁿ.” Accordingly, for example, “1.76E+03” in FIG. 44 means “1.76×10³” and, for example, “1.14E+04” means “1.14×10⁴.” Hereinafter, the representation “E+0n” has the same meaning.

As can be seen from FIG. 44, the addition of CuO improves the high temperature load life. As can also be seen, although the addition of CuO leads to a tendency to degrade the piezoelectric property, the addition of Dy₂O₃ as the oxide of a rare earth metal element can prevent the degradation of the piezoelectric property. CuO is effective in an addition of 5.0% by mass for the high temperature load life, but degrades the piezoelectric property in addition exceeding 3.0% by mass. Accordingly, in the present invention, the content of CuO_{α} is set at 3.0% by mass or less in terms of CuO.

### Example 34

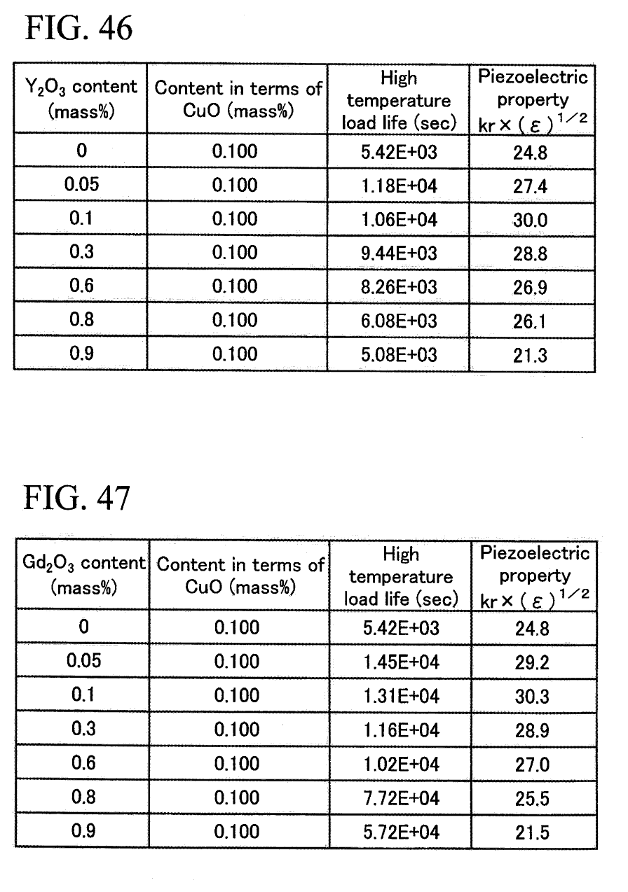

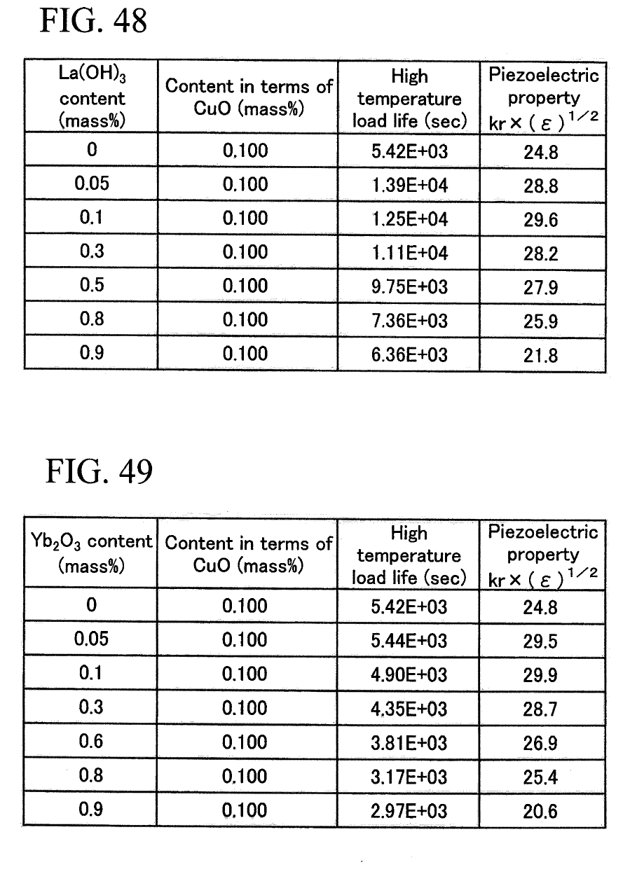

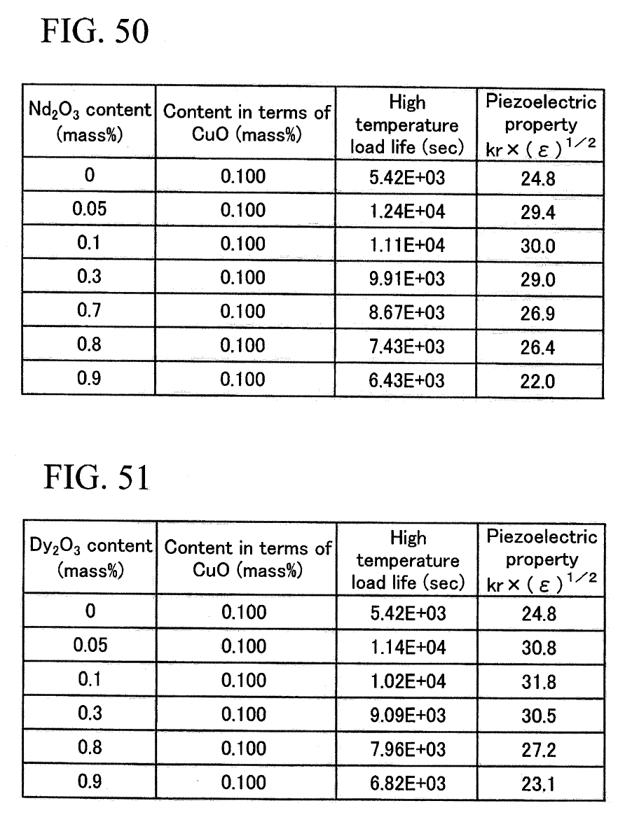

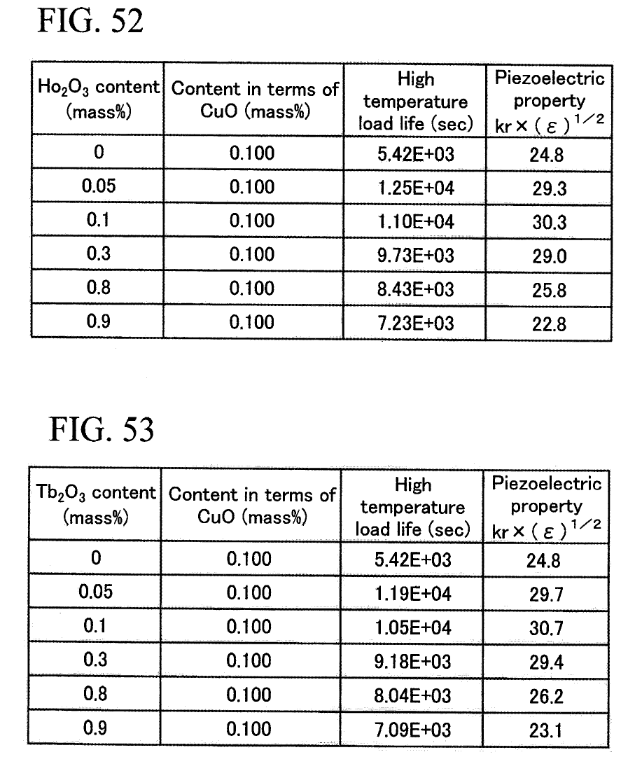

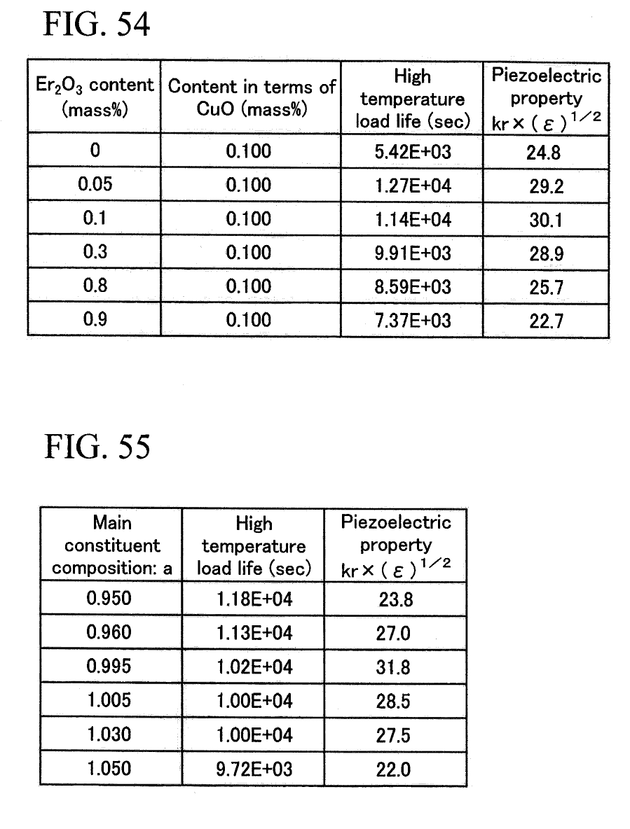

Example 34 presents the results of the experiments to verify the effects of the oxides of various rare earth metal elements by varying the contents of the oxides as shown in FIGS. 45 to 54. The piezoelectric ceramic compositions were prepared in the same manner as in Example 33 (after pulverization of the calcined mixtures, the raw material of CuO_{α} (α≧0) (added species: CuO) was added in a content of 0.100% by mass), and the high temperature load life and the piezoelectric property were evaluated in the same manner as in Example 33. The results thus obtained are shown in FIGS. 45 to 54.

As can be seen from FIGS. 45 to 54, the addition of the various rare earth metal elements to the piezoelectric ceramic compositions can improve the piezoelectric property. Gd, Dy, Ho and Tb are high in the improvement effect on the piezoelectric property, and in particular, Dy is excellent because Dy can attain excellent piezoelectric properties over a wide addition range thereof.

### Example 35

Example 35 presents the results of the experiments in which examination was carried out on the composition “a” of the A-site element of the main constituent.

Piezoelectric ceramic compositions were prepared by setting the composition of the main constituent as shown below, and by varying the composition a in the composition of the main constituent. The preparation method of each of the piezoelectric ceramic compositions was the same as that in Example 33; a calcined mixture prepared by adding Dy₂O₃ in a content of 0.1% by mass was pulverized, and then the pulverized mixture was combined with the raw material for CuO_{α} (α≧0) (added species: CuO) in a content of 0.1% by mass. Each of the thus obtained piezoelectric ceramic compositions was subjected to the evaluation of the high temperature load life and the piezoelectric property in the same manner as in Example 33. The results thus obtained are shown in FIG. 55; it has been verified that when the composition “a” falls within a range from 0.96 to 1.03, piezoelectric ceramic compositions excellent in high temperature load life and piezoelectric property can be obtained.

Main Constituent:
(Pb_{a-0.03}Sr_{0.03}) [(Zn_{1/3}Nb_{2/3})_{0.1}Ti_{0.43}Zr_{0.47}]O₃

### Example 36

Example 36 presents the results of the experiments in which examination was carried out on the composition b of the A-site element of the main constituent.

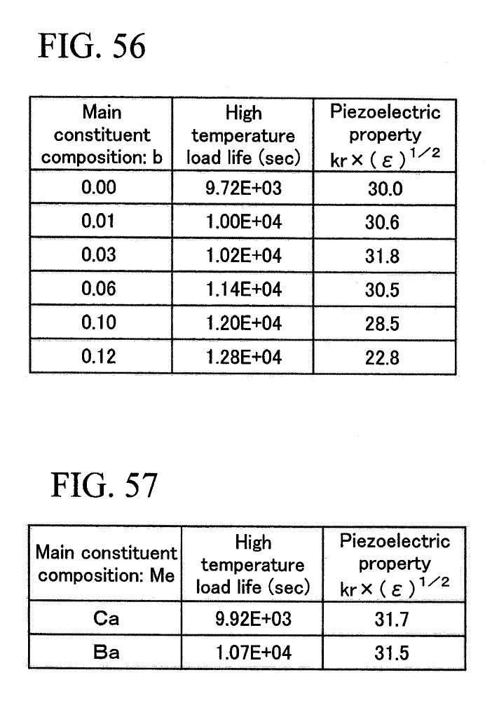

Piezoelectric ceramic compositions were prepared by setting the composition of the main constituent as shown below, and by varying the composition b in the composition of the main constituent. The preparation method of each of the piezoelectric ceramic compositions was the same as that in Example 33; a calcined mixture prepared by adding Dy₂O₃ in a content of 0.1% by mass was pulverized, and then the pulverized mixture was combined with the raw material for CuO_{α} (α≧0) (added species: CuO) in a content of 0.1% by mass. Each of the thus obtained piezoelectric ceramic compositions was subjected to the evaluation of the high temperature load life and the piezoelectric property in the same manner as in Example 33. The results thus obtained are shown in FIG. 56; it has been verified that when the composition b falls within a range of 0≦b≦0.1, piezoelectric ceramic compositions excellent in high temperature load life and piezoelectric property can be obtained.

Main Constituent:
(Pb_{0.995-b}Sr_{b}) [(Zn_{1/3}Nb_{2/3})_{0.1}Ti_{0.43}Zr_{0.47}]O₃

### Example 37

Example 37 presents the results of the experiments which were carried out by using Ca or Ba instead as the A-site substitutional element Me in the main constituent.

Piezoelectric ceramic compositions were prepared by setting the composition of the main constituent as shown below, and otherwise in the same manner as in Example 33. Specifically, for each of the piezoelectric ceramic compositions, a calcined mixture prepared by adding Dy₂O₃ in a content of 0.1% by mass was pulverized, and then the pulverized mixture was combined with the raw material for CuO_{α} (α≧0) (added species: CuO) in a content of 0.1% by mass. Each of the thus obtained piezoelectric ceramic compositions was subjected to the evaluation of the high temperature load life and the piezoelectric property in the same manner as in Example 33. The results thus obtained are shown in FIG. 57; it has been verified that when the substitutional element Me in the main constituent is changed from Sr to Ca or Ba, piezoelectric ceramic compositions excellent in high temperature load life and piezoelectric property can also be obtained.

Main Constituent:
(Pb_{0.995-0.03}Me_{0.03}) [(Zn_{1/3}Nb_{2/3})_{0.1}Ti_{0.43}Zr_{0.47}]O₃

### Example 38

Example 38 presents the results of the experiments in which examination was carried on x, y and z of the B-site elements of the main constituent.

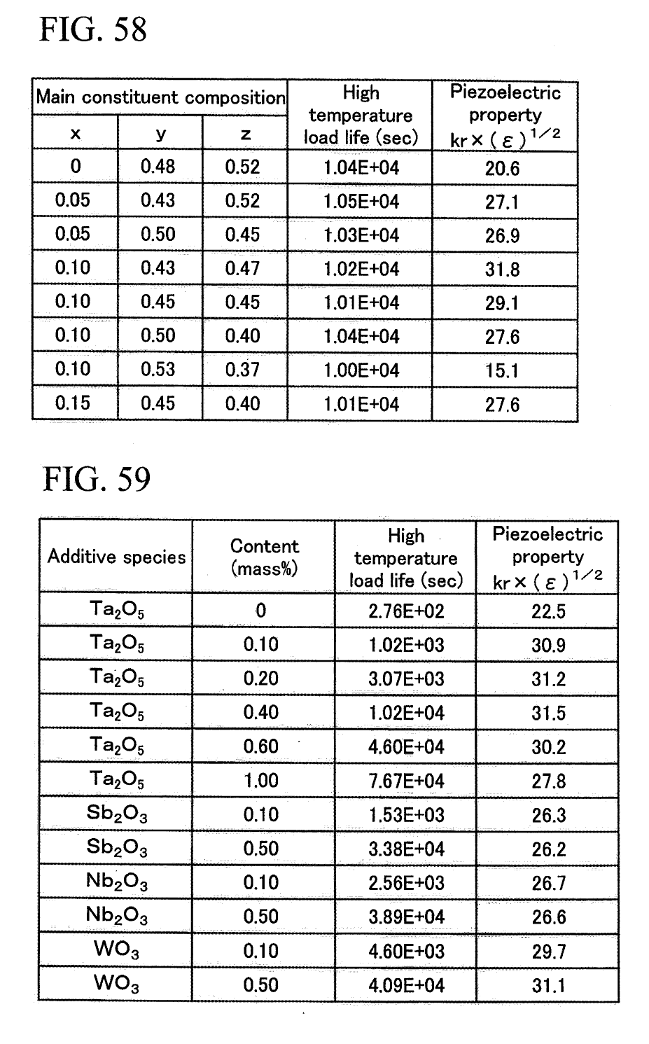

Piezoelectric ceramic compositions were prepared by setting the composition of the main constituent as shown below, and by varying x, y and z of the B-site elements of the composition in the main constituent. The preparation method of each of the piezoelectric ceramic compositions was the same as that in Example 33; a calcined mixture prepared by adding Dy₂O₃ in a content of 0.1% by mass was pulverized, and then the pulverized mixture was combined with the raw material for CuO_{α} (α≧0) (added species: CuO) in a content of 0.1% by mass. Each of the thus obtained piezoelectric ceramic compositions was subjected to the evaluation of the high temperature load life and the piezoelectric property in the same manner as in Example 33. The results thus obtained are shown in FIG. 58. As shown in FIG. 58, it has been verified that even when x, y and z of the B-site elements are varied within the ranges of the present invention, piezoelectric ceramic compositions excellent in high temperature load life and piezoelectric property can be obtained.

Main Constituent:
(Pb_{0.995-0.03}Sr_{0.03}) [(Zn_{1/3}Nb_{2/3})_{X}Ti_{y}Zr_{z}]O₃

### Example 39

Example 39 presents the results of the experiments which were carried out by adding each of the substances shown in FIG. 59 as the fourth additive in relation to the main constituent.

Piezoelectric ceramic compositions were prepared in the same manner as in Example 33 except that the composition of the main constituent was set as shown below, and the substances shown in FIG. 59 were added. In other words, a calcined mixture prepared by adding Dy₂O₃ in a content of 0.1% by mass was pulverized, and then the pulverized mixture was combined with the raw material for CuO_{α} (α≧0) (added species: CuO) in a content of 0.1% by mass. Each of the thus obtained piezoelectric ceramic compositions was subjected to the evaluation of the high temperature load life and the piezoelectric property in the same manner as in Example 33. The results thus obtained are shown in FIG. 59. As shown in FIG. 59, it has been verified that any additives and any additive amounts attain advantageous effects, and piezoelectric ceramic compositions excellent in high temperature load life and piezoelectric property can be obtained.

Main Constituent:
(Pb_{0.995-0.03}Sr_{0.03}) [(Zn_{1/3}Nb_{2/3})_{0.1}Ti_{0.43}Zr_{0.47}]O₃

### Example 40

Example 40 presents an example of the preparation of a laminated piezoelectric element.

In the preparation of the laminated piezoelectric element, first a vehicle was added to a piezoelectric ceramic composition powder obtained by pulverizing the calcined mixture (Dy₂O₃ was added in a content of 0.1% by mass) obtained in Example 33. The mixture thus obtained was kneaded to prepare a piezoelectric layer paste. A Cu powder as a conductive material was kneaded with a vehicle to prepare an internal electrode layer paste. Then, by using the piezoelectric layer paste and the internal electrode layer paste, a green chip as a precursor for a laminate was prepared by means of a printing method. The green chip was subject to a binder removal treatment, and then sintered under reductive sintering conditions to yield a laminate. The reductive sintering conditions were such that sintering was carried out in a reductive atmosphere (for example, under an oxygen partial pressure: 1×10⁻¹⁰ to 1×10⁻⁶ atm) at sintering temperatures of 800 to 1200° C.

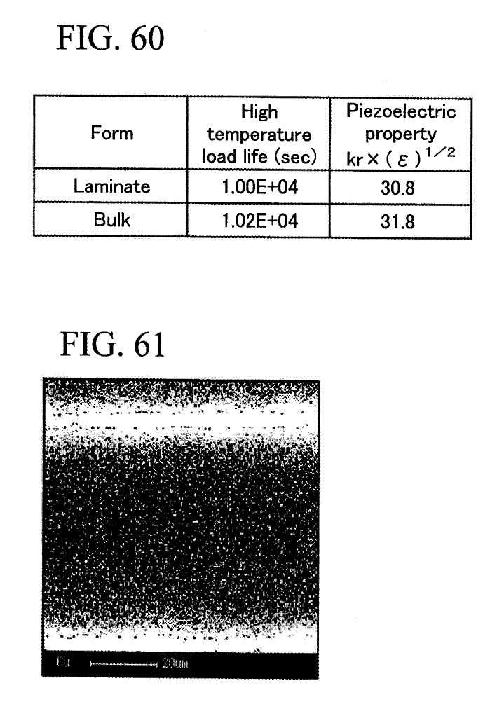

The laminate thus obtained was subjected to a laminate section measurement by using an EPMA (EPMA-1600). The obtained laminate was also subjected to the measurements of the high temperature load life and the piezoelectric property in the same manner as in Example 33. The results thus obtained are shown in FIG. 60.

The piezoelectric layers forming the laminate were sintered as a laminate, and consequently, the Cu of the electrodes diffused into the piezoelectric layers, and the high temperature electric resistance was markedly improved. The state of the presence of the Cu in the piezoelectric layers was examined by means of an EPMA; as shown in FIG. 61, the Cu did not show any segregation but was present uniformly.

### Example 41

Examples 41 to 50 describe the examples of the improvement of the high temperature electric resistance due to the presence of CuO_{α} and the examples of the improvement of the piezoelectric property due to the addition of the third additive.

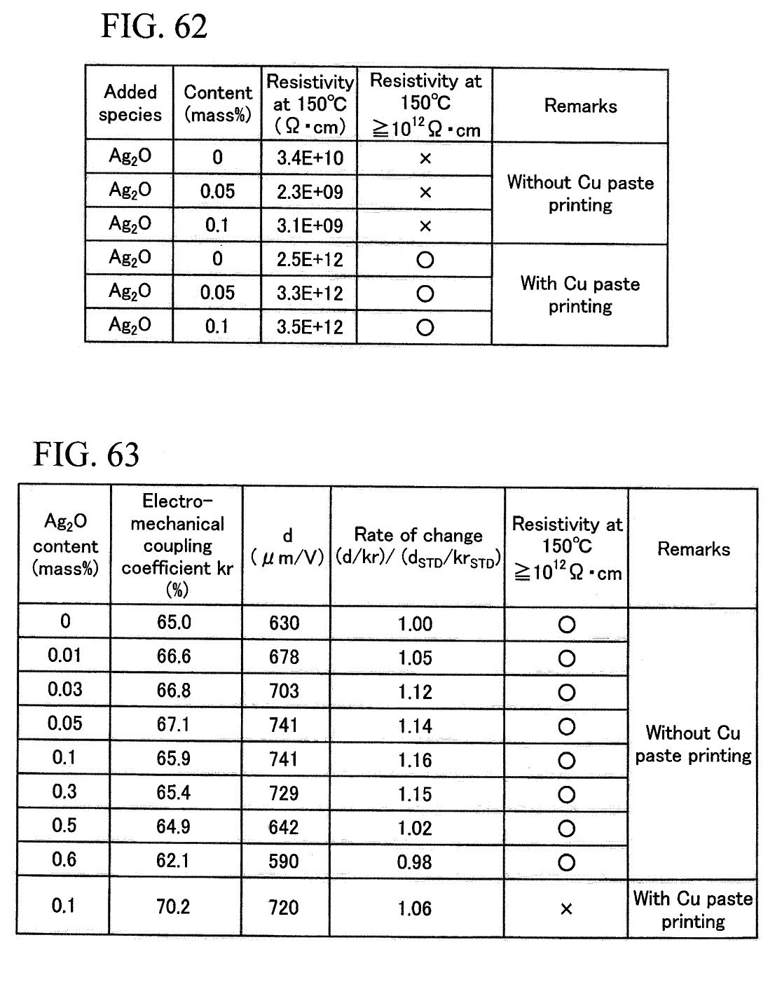

In present Example, Ag, as the third additive, was added so as to give the contents in terms of Ag₂O shown in FIG. 62, in relation to the main constituent shown below, and the effects of the addition of Ag were examined.

Main Constituent:
(Pb_{0.995-0.03}Sr_{0.03}) [(Zn_{1/3}Nb_{2/3})_{0.1}Ti_{0.43}Zr_{0.47}]O₃

Each of the piezoelectric ceramic compositions shown in FIG. 62 was prepared as follows. First, as the raw materials for the main constituent, a PbO powder, a SrCO₃ powder, a ZnO powder, a Nb₂O₅ powder, a TiO₂ powder and a ZrO₂ powder were prepared, and were weighed out to give the above-mentioned composition of the main constituent. Ag₂O was prepared as the added species of Ag, and was added to the base composition of the main constituent so as to give the contents shown in FIG. 62. A Ta₂O₅ powder was also added to the base composition of the main constituent in a content of 0.2% by mass. Then, these raw materials were wet mixed with a ball mill for 16 hours, and calcined in air at 700 to 900° C. for 2 hours.

The calcined mixture thus obtained was pulverized, and then wet milled with a ball mill for 16 hours. The milled mixture was dried, combined with an acrylic resin as a binder, and then granulated. The granulated mixture was compacted into a disc of 17 mm in diameter and 1 mm in thickness with a uniaxial press molding machine under a pressure of approximately 445 MPa.

After compacting, a Cu paste containing a Cu powder of 1.0 μm in particle size was printed on both sides of the disc. The sample thus obtained was heat treated to evaporate the binder, and sintered at 950° C. for 8 hours in a reductive atmosphere (oxygen partial pressure: 1×10⁻¹⁰ to 1×10⁻⁶ atm).

The sintered body thus obtained was sliced and lapped into a 0.6 mm thick disc; then the printed Cu paste was removed and at the same time machined into a shape suitable for the property evaluation. A silver paste was printed on both sides of the obtained sample, and baked at 350° C. The sample was subjected to a polarization treatment in a silicone oil set at 120° C. by applying an electric field of 3 kV for 15 minutes. Additionally, other samples were prepared in the same manner as described above, inclusive of the polarization treatment, except that neither Cu paste printing nor heat treatment for evaporating the binder was carried out.

The samples thus prepared were subjected to the measurement of the resistivity at 150° C. The results thus obtained are shown in FIG. 62. In FIG. 62, “E+0n” in the column for the resistivity means “×10ⁿ”. Accordingly, for example, “2.3E+09” in FIG. 62 means “2.3×10⁹” and, for example, “3.5E+12” means “3.5×10¹²”.

As can be seen from FIG. 62, the measurement results of the sample for which no Cu paste was printed show that the addition of Ag₂O decreases the resistivity. On the contrary, by printing the Cu paste, the resistivity at 150° C. was found to be 1×10¹² Ω·cm or more; thus, the addition of Ag₂O can inhibit the decrease of the electric resistance.

The sample printed with a Cu paste was subjected to ICP analysis. A preparation method of a sample for ICP was as follows: first, 0.1 g of an analyte sample was combined with 1 g of Li₂B₂O₇, and the mixture was melted at 1050° C. for 15 minutes; the obtained molten mixture was combined with 0.2 g of (COOH)₂ and 10 ml of HCl, heated for dissolution, and then the sample solution volume was adjusted to 100 ml. The ICP measurement was carried out by using ICP-AES (trade name ICPS-8000, manufactured by Shimadzu Corp.). Consequently, it was found that Cu was contained in a content of 0.1% by mass in terms of Cu₂O. The Cu can be identified to have diffused from the Cu paste during the sintering process, because no Cu was contained in the raw materials of the piezoelectric ceramic composition.

### Example 42

In present Example, samples were prepared, inclusive of the polarization treatment, in the same manner as in Example 41 except that the composition of the raw materials was adjusted so as for Ag to have the contents in terms of Ag₂O shown in FIG. 63, in relation to the main constituent shown below. Additionally, another sample for which no Cu paste was printed was also prepared.

Main Constituent:
(Pb_{0.995-0.03}Sr_{0.03}) [(Zn_{1/3}Nb_{2/3})_{0.1}Ti_{0.43}Zr_{0.47}]O₃

The samples thus prepared were subjected to the displacement magnitude measurement at a high voltage and the electromechanical coupling coefficient kr (%) measurement at a low voltage, according to the following procedures.

The displacement magnitude of each of the samples at a high voltage was measured by applying a voltage of 1.7 kV/mm to the sample and by measuring the resulting displacement with a laser Doppler displacement gauge. The displacement magnitude of each of the samples along the direction vertical to the electrode surfaces per 1 mm of the element at the applied voltage of 1.7 kV/mm was represented by D[μm/mm], and the displacement magnitude per unit voltage, d, was derived from d=D×1000/1.7.

The electromechanical coupling coefficient kr (%) measurement was carried by using an impedance analyzer (HP4194A, 0.2 V/mm, manufactured by Hewlett-Packard Co.).

Here, d and kr (%) of the sample in which Ag₂O was not added are represented by d_{STD} and kr_{STD}, respectively. For each of the other samples, the (d/kr)/(d_{STD}/kr_{STD}) value was derived; the values (rates of change in FIG. 63) derived by using this formula indicate the degree of the piezoelectric property improvement at the high voltage as compared to the sample in which Ag₂O was not added.

The results obtained as described above are shown in FIG. 63.

As shown in FIG. 63, the addition of Ag₂O increases the electromechanical coupling coefficient kr (%) at the low voltage by approximately 3% at a maximum. The addition of Ag₂O can improve the displacement magnitude d and the (d/kr)/(d_{STD}/kr_{STD}) at the high voltage by 15% or more. Thus, the addition of Ag₂O remarkably improves the piezoelectric properties at the high voltage. However, when the content of Ag₂O reaches 0.6% by mass, d and (d/kr)/(d_{STD}/kr_{STD}) become smaller than when Ag₂O is not added. Accordingly, in the present invention, the content of Ag is set at 0.5% by mass or less in terms of Ag₂O. The content of Ag is preferably 0.01 to 0.4% by mass and more preferably 0.02 to 0.35% by mass, in terms of Ag₂O.

### Example 43

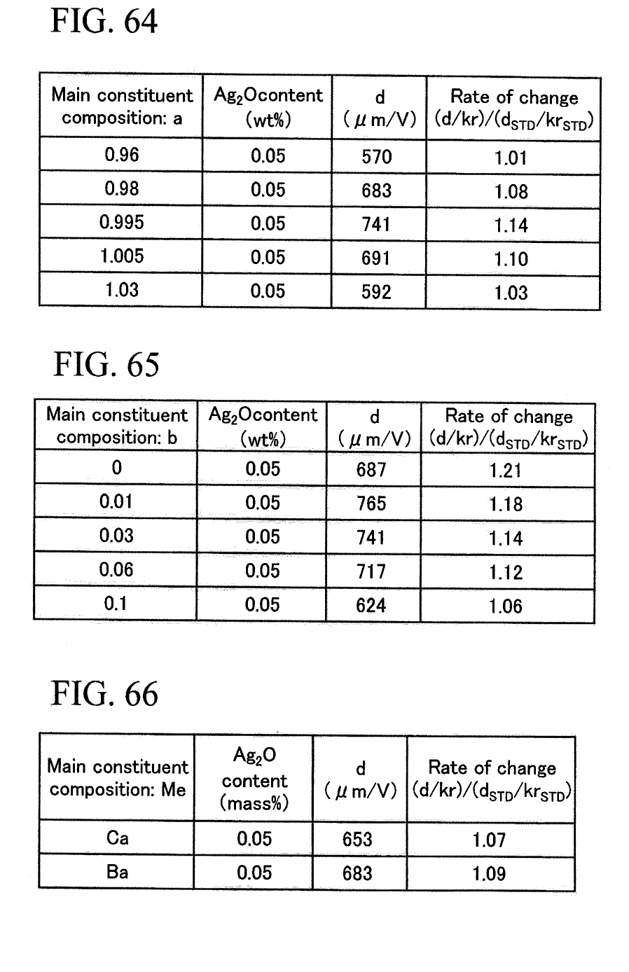

Samples were prepared in the same manner as in Example 41 except that the composition of the raw materials was adjusted so as for “a” to have the values shown in FIG. 64 and so as for Ag to have the content in terms of Ag₂O shown in FIG. 64, in relation to the main constituent shown below. The samples thus obtained were subjected to the evaluation of the d values and the (d/kr(%))/(d_{STD}/kr(%)_{STD}) values in the same manner as in Example 42. The results thus obtained are shown in FIG. 64. It is to be noted that the d_{STD}/kr (%)_{STD} values of the respective samples are the values obtained for the samples in which “a” in the main constituent was such that a=0.96, 0.98, 0.995, 1.005 and 1.03, and Ag₂O was not contained.

Main Constituent:
(Pb_{a-0.03}Sr_{0.03}) [(Zn_{1/3}Nb_{2/3})_{0.1}Ti_{0.43}Zr_{0.47}]O₃

As shown in FIG. 64, when “a” falls within the range from 0.96 to 1.03, the piezoelectric properties at the high voltage can be ensured. Preferably “a” is 0.97 to 1.02, and more preferably “a” is 0.98 to 1.01.

### Example 44

Samples were prepared in the same manner as in Example 41 except that the composition of the raw materials was adjusted so as for b to have the values shown in FIG. 65 and so as for Ag to have the content in terms of Ag₂O shown in FIG. 65, in relation to the main constituent shown below. The samples thus obtained were subjected to the evaluation of the d values and the (d/kr)/(d_{STD}/kr_{STD}) values in the same manner as in Example 42. The results thus obtained are shown in FIG. 65. It is to be noted that the d_{STD}/kr_{STD} values of the respective samples are the values obtained for the samples in which b in the main constituent was such that b=0, 0.01, 0.03, 0.06 and 0.1, and Ag₂O was not contained.

Main Constituent:
(Pb_{0.995-b}Sr_{b}) [(Zn_{1/3}Nb_{2/3})_{0.1}Ti_{0.43}Zr_{0.47}]O₃

As shown in FIG. 65, when b falls within the range from 0 to 0.1, the piezoelectric properties at the high voltage can be ensured.

### Example 45

Samples were prepared in the same manner as in Example 41 except that the composition of the raw materials was adjusted so as for Me to be the elements shown in FIG. 66 and so as for Ag₂O to have the contents shown in FIG. 66, in relation to the main constituent shown below. The samples thus obtained were subjected to the evaluation of the d values and the (d/kr)/(d_{STD}/kr_{STD}) values in the same manner as in Example 42. The results thus obtained are shown in FIG. 66.

Main Constituent:
(Pb_{0.995-0.03}Me_{0.03}) [(Zn_{1/3}Nb_{2/3})_{0.1}Ti_{0.43}Zr_{0.47}]O₃

As shown in FIG. 66, even when Ca or Ba is used as the substitutional element for Pb, similarly to the case where Sr is used, the improvement effect on the piezoelectric properties at the high voltage can also be enjoyed. It is to be noted that the d_{STD}/kr(%)_{STD} values of the respective samples are the values obtained for the samples in which Me in the main constituent was Ca or Ba, and Ag₂O was not contained.

### Example 46

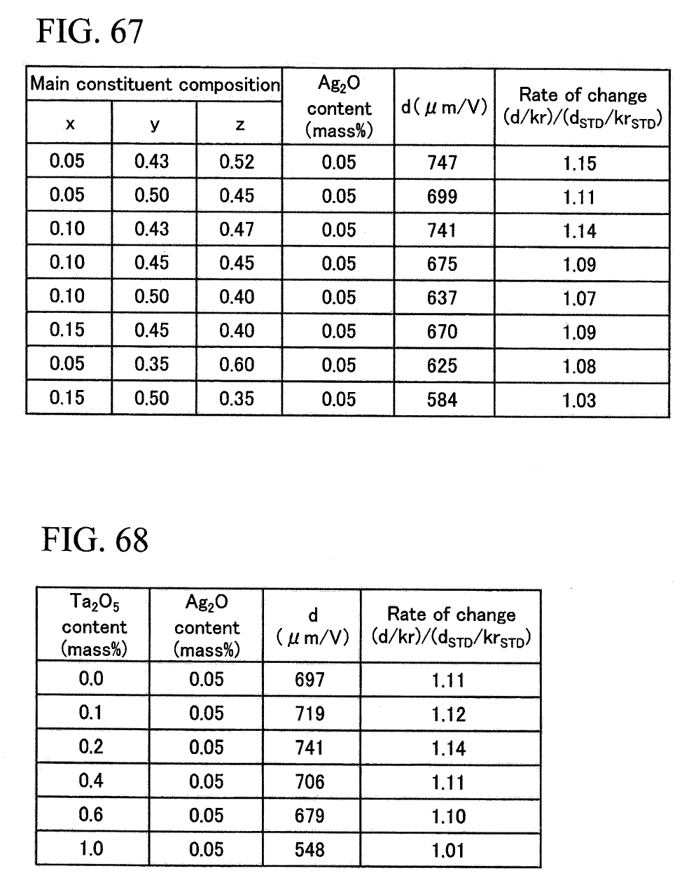

Samples were prepared in the same manner as in Example 41, except that the composition of the raw materials was adjusted so as for x, y and z to have the values shown in FIG. 67 and so as for Ag to have the content in terms of Ag₂O shown in FIG. 67, in relation to the main constituent shown below. The samples thus obtained were subjected to the evaluation of the d values and the (d/kr)/(d_{STD}/kr_{STD}) values in the same manner as in Example 42. The results thus obtained are shown in FIG. 67.

Main Constituent:
(Pb_{0.995-0.03}Sr_{0.03}) [(Zn_{1/3}Nb_{2/3})ₓTi_{y}Zr_{z}]O₃

As can be seen from FIG. 67, when x, y and z for the B-site elements fall within the ranges of 0.05≦x≦0.15, 0.25≦y≦0.5 and 0.35≦z≦0.6, respectively, the improvement effect on the piezoelectric properties at the high voltage can be enjoyed. It is to be noted that the d_{STD}/kr_{STD} values of the respective samples are the values obtained for the samples which did not contain Ag₂O.

### Example 47

Samples were prepared in the same manner as in Example 41, except that the composition of the raw materials was adjusted so as for Ag and Ta, as the additives, to have the contents in terms of Ag₂O and Ta₂O₅, respectively, shown in FIG. 68, in relation to the main constituent shown below. The samples thus obtained were subjected to the evaluation of the d values and the (d/kr)/(d_{STD}/kr_{STD}) values in the same manner as in Example 42. The results thus obtained are shown in FIG. 68.

Main Constituent:
(Pb_{0.995-0.03}Sr_{0.03}) [(Zn_{1/3}Nb_{2/3})_{0.1}Ti_{0.43}Zr_{0.47}]O₃

As shown in FIG. 68, the addition of Ta₂O₅, as an additive, can improve d and (d/kr)/(d_{STD}/kr_{STD}). However, when the content of Ta₂O₅ exceeds 0.5% by mass, d and (d/kr)/(d_{STD}/kr_{STD}) are degraded. Accordingly, when Ta₂O₅ is contained, the content of Ta₂O₅ is set at 0.5% by mass or less. The content of Ta₂O₅ is preferably 0.05 to 0.4% by mass and more preferably 0.15 to 0.35% by mass. It is to be noted that the d_{STD}/kr_{STD} values of the respective samples are the values obtained for the samples which did not contain Ag₂O.

### Example 48

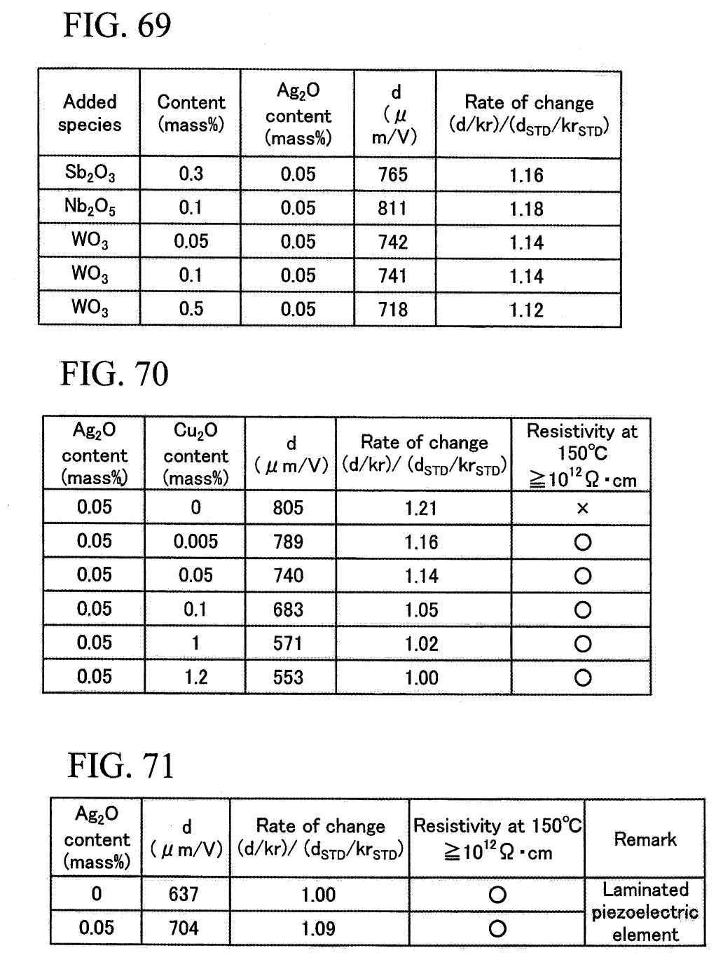

Samples were prepared in the same manner as in Example 41, except that the composition of the raw materials was adjusted to give the contents shown in FIG. 69, in relation to the main constituent shown below. The samples thus obtained were subjected to the evaluation of the d values and the (d/kr)/(d_{STD}/kr_{STD}) values in the same manner as in Example 42. The results thus obtained are shown in FIG. 69.

Main Constituent:
(Pb_{0.995-0.03}Sr_{0.03}) [(Zn_{1/3}Nb_{2/3})_{0.1}Ti_{0.43}Zr_{0.47}]O₃

As shown in FIG. 69, the addition of Sb₂O₃, Nb₂O₅ or WO₃, as the additive, can also enjoy the improvement effect on the piezoelectric properties at the high voltage. It is to be noted that the d_{STD}/kr_{STD} values of the respective samples are the values obtained for the samples which did not contain the added species shown in FIG. 69.

### Example 49

Samples were prepared, inclusive of sintering and polarization, in the same manner as in Example 41, except that the calcined mixtures were combined with Cu₂O in the contents shown in FIG. 70, the main constituent of each of the samples being as shown below. It is to be noted that no Cu paste printing was carried out. The samples thus obtained were subjected to the evaluation of the d values and the (d/kr)/(d_{STD}/kr_{STD}) values in the same manner as in Example 42. The results thus obtained are shown in FIG. 70.

Main Constituent:
(Pb_{0.995-0.03}Sr_{0.03}) [(Zn_{1/3}Nb_{2/3})_{0.1}Ti_{0.43}Zr_{0.47}]O₃

As shown in FIG. 70, the addition of Cu (Cu₂O) can also enjoy the improvement effect on the piezoelectric properties at the high voltage, in a way other than the diffusion of Cu into the sintered body. However, when the content of Cu₂O reaches 1.2% by mass, the (d/kr)/(d_{STD}/kr_{STD}) value becomes 1 to give no difference from a piezoelectric ceramic composition in which Ag₂O and Cu₂O were not added. Accordingly, in the present invention, the content of Cu is set at 1.0% by mass or less in terms of Cu₂O. It is to be noted that the content of Cu in terms of Cu₂O in each of the samples was the same as the content of added Cu₂O.

### Example 50

Example 50 presents an example of the preparation of a laminated piezoelectric element.

In the preparation of a laminated piezoelectric element, first, a calcined mixture (Ag₂O: 0.05% by mass) obtained in Example 41 was pulverized. The piezoelectric ceramic composition powder thus obtained was combined with a vehicle, and kneaded to yield a piezoelectric layer paste. An internal electrode layer paste was also prepared by kneading a Cu powder as the conductive material with a vehicle. Then, by using the piezoelectric layer paste and the internal electrode layer paste, a green chip as a precursor for a laminate was prepared by means of a printing method. The lamination number of the piezoelectric layer paste was set at 300. The green chip was subject to a binder removal treatment, and then sintered under reductive sintering conditions to yield a laminate. The reductive sintering conditions were such that sintering was carried out in a reductive atmosphere (oxygen partial pressure: 1×10⁻¹⁰ to 1×10⁻⁶ atm) at sintering temperatures of 800 to 1200° C. For comparison, another laminate was prepared in the same manner as described above except that Ag₂O was not added.

The laminates thus obtained were subjected to the evaluation of the d values and the (d/kr)/(d_{STD}/kr_{STD}) values in the same manner as in Example 42. The results thus obtained are shown in FIG. 71.

### Example 51

Examples 51 to 59 describe the effects due to the combined addition of the second additive and the third additive under the conditions that CuO_{α} was absent.

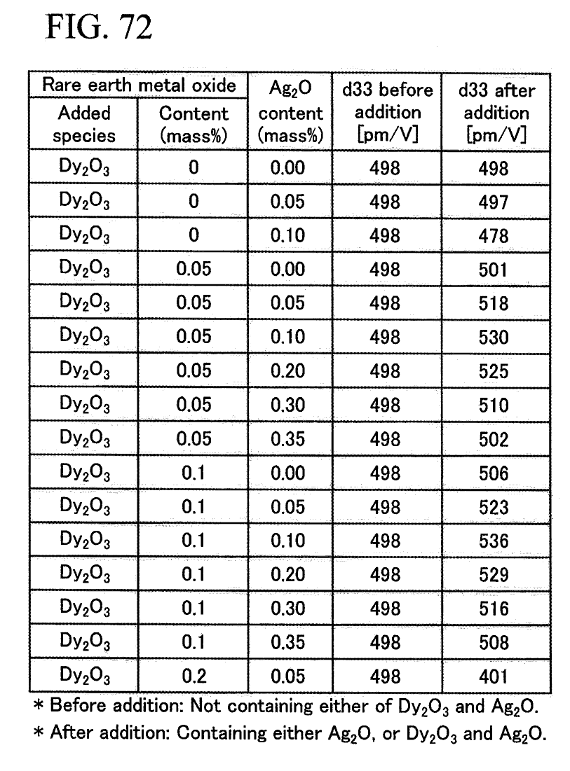

In present Example, Dy₂O₃ and Ag₂O were added to give the contents shown in FIG. 72, in relation to the main constituent shown below, and the effects of Dy₂O₃ and Ag₂O were examined.

Main Constituent:
(Pb_{0.995-0.03}Sr_{0.03}) [(Zn_{1/3}Nb_{2/3})_{0.1}Ti_{0.43}Zr_{0.47}]O₃

Each of the piezoelectric ceramic compositions shown in FIG. 72 was prepared as follows. First, as the raw materials for the main constituent, a PbO powder, a SrCO₃ powder, a ZnO powder, a Nb₂O₅ powder, a TiO₂ powder and a ZrO₂ powder were prepared, and were weighed out to give the above-mentioned composition of the main constituent. A Dy₂O₃ powder and a Ag₂O powder were also prepared, and added to the base composition of the main constituent so as to give the contents shown in FIG. 72. A Ta₂O₅ powder was further added to the base composition of the main constituent in a content of 0.2% by mass. Then, these raw materials were wet mixed with a ball mill for 16 hours, and the mixture thus obtained was calcined in air at 700 to 900° C. for 2 hours.

The calcined mixture thus obtained was pulverized, and then wet milled with a ball mill for 16 hours. The milled mixture was dried, combined with an acrylic resin as a binder, and then granulated. The granulated mixture was compacted into a cylinder of 3.5 mm in diameter and approximately 9 mm in length with a uniaxial press molding machine under a pressure of approximately 445 MPa. After compacting, the cylinder was heat treated to evaporate the binder, and then sintered at 950° C. for 2 to 8 hours in a low-oxygen reductive atmosphere (oxygen partial pressure: 1×10⁻¹⁰ to 1×10⁻⁶ atm). The sintered body thus obtained was machined into a 7.5 mm long cylinder; then a silver paste was printed on the top face and the bottom face and baked at 350° C., and the cylinder was subjected to a polarization treatment in a silicone oil set at 120° C. by applying an electric field of 3 kV/mm for 15 minutes.

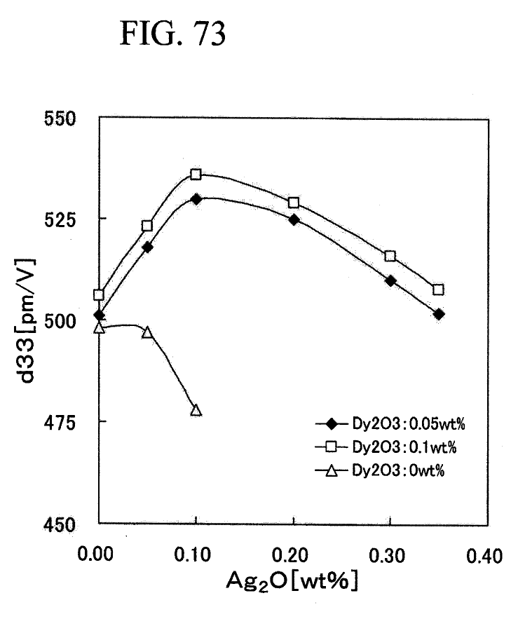

The samples thus prepared were subjected to the piezoelectric constant d33 measurement. The piezoelectric constant d33 measurement was carried out by using an impedance analyzer (HP4194A, manufactured by Hewlett-Packard Co.) on the basis of the resonance-antiresonance method. The results thus obtained are also shown in FIG. 72. FIG. 73 shows the relation between the content of Dy₂O₃ and the piezoelectric constant d33 and the relation between the content of Ag₂O and the piezoelectric constant d33.

As can be seen from FIGS. 72 and 73, when only Ag₂O is added to the main constituent without adding Dy₂O₃, the piezoelectric constant d33 is degraded; on the contrary, when Dy₂O₃ is added together with Ag₂O, the piezoelectric constant d33 is improved. However, when the content of Ag₂O exceeds 0.35% by mass, the piezoelectric constant d33 becomes smaller than when Ag₂O is not added. Also as shown in FIG. 72, the content of Dy₂O₃ reaches 0.2% by mass, the piezoelectric constant d33 becomes extremely small.

### Example 52

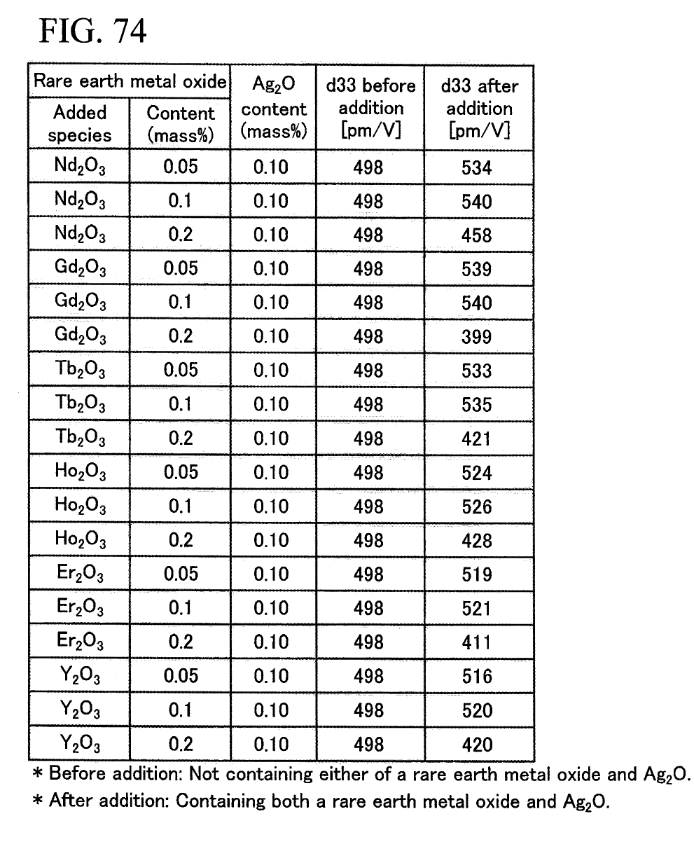

In present Example, samples were prepared, inclusive of the polarization treatment, in the same manner as in Example 51 except that the composition of the raw materials was adjusted so as for the oxide of a rare earth metal element and Ag₂O to have the contents shown in FIG. 74, in relation to the main constituent shown below. The samples thus prepared were subjected to the piezoelectric constant d33 measurement in the same manner as in Example 51. The results thus obtained are shown in FIG. 74. The oxides other than Dy₂O₃ shown in Example 51 can improve the piezoelectric constant d33 by the concomitant presence of Ag₂O. As the rare earth metal elements, Dy, Nd, Gd and Tb are advantageous for the purpose of obtaining a high piezoelectric constant d33.

Main Constituent:
(Pb_{0.995-0.03}Sr_{0.03}) [(Zn_{1/3}Nb_{2/3})_{0.1}Ti_{0.43}Zr_{0.47}]O₃

### Example 53

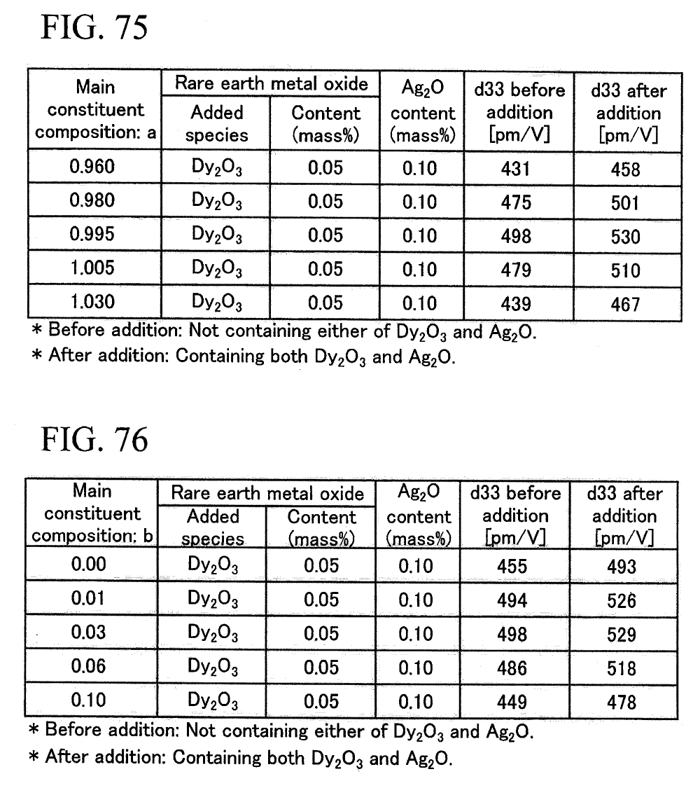

Samples were prepared in the same manner as in Example 51 except that the composition of the raw materials was adjusted so as for “a” to have the values shown in FIG. 75 and so as for Dy₂O₃ and Ag₂O to have the contents shown in FIG. 75, in relation to the main constituent shown below. The samples thus obtained were subjected to the piezoelectric constant d33 measurement in the same manner as in Example 51. The results thus obtained are shown in FIG. 75.

Main Constituent:
(Pb_{a-0.03}Sr_{0.03}) [(Zn_{1/3}Nb_{2/3})_{0.1}Ti_{0.43}Zr_{0.47}]O₃

As shown in FIG. 75, the piezoelectric properties at the high voltage can be ensured for “a” falling within a range from 0.96 to 1.03. Preferably “a” is 0.97 to 1.02, and more preferably “a” is 0.98 to 1.01.

### Example 54

Samples were prepared in the same manner as in Example 51 except that the composition of the raw materials was adjusted so as for b to have the values shown in FIG. 76 and so as for Dy₂O₃ and Ag₂O to have the contents shown in FIG. 76, in relation to the main constituent shown below. The samples thus obtained were subjected to the piezoelectric constant d33 measurement in the same manner as in Example 51. The results thus obtained are shown in FIG. 76.

Main Constituent:
(Pb_{0.995-b}Sr_{b}) [(Zn_{1/3}Nb_{2/3})_{0.1}Ti_{0.43}Zr_{0.47}]O₃

As shown in FIG. 76, the piezoelectric properties at the high voltage can be ensured for b falling within a range from 0 to 0.1. Preferably b is 0.005 to 0.08, and more preferably b is 0.007 to 0.05.

### Example 55

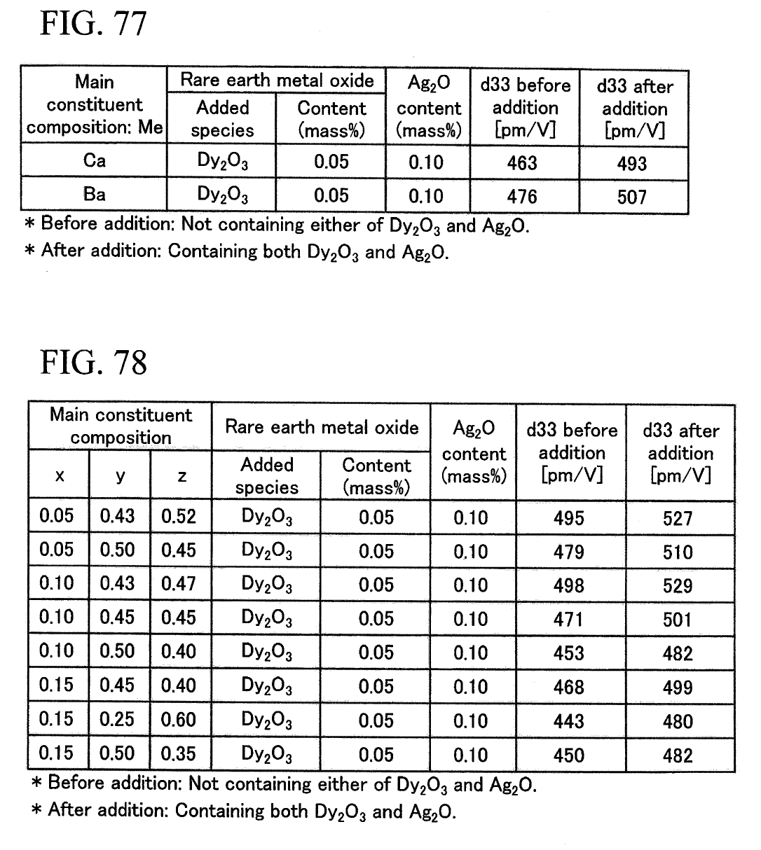

Samples were prepared in the same manner as in Example 51 except that the composition of the raw materials was adjusted so as for Me to be the elements shown in FIG. 77 and so as for Dy₂O₃ and Ag₂O to have the contents shown in FIG. 77, in relation to the main constituent shown below. The samples thus obtained were subjected to the piezoelectric constant d33 measurement in the same manner as in Example 51. The results thus obtained are shown in FIG. 77.

Main Constituent:
(Pb_{0.995-0.03}Me_{0.03}) [(Zn_{1/3}Nb_{2/3})_{0.1}Ti_{0.43}Zr_{0.47}]O₃

As shown in FIG. 77, when Ca or Ba is used as the substitutional element for Pb, similarly to the case where Sr is used, the improvement effect on the piezoelectric properties at the high voltage can also be enjoyed.

### Example 56

Samples were prepared in the same manner as in Example 51 except that the composition of the raw materials was adjusted so as for x, y and z to have the values shown in FIG. 78 and so as for Dy₂O₃ and Ag₂O to have the contents shown in FIG. 78, in relation to the main constituent shown below. The samples thus obtained were subjected to the piezoelectric constant d33 measurement in the same manner as in Example 51. The results thus obtained are shown in FIG. 78.

Main Constituent:
(Pb_{0.995-0.03}Sr_{0.03}) [(Zn_{1/3}Nb_{2/3})ₓTi_{y}Zr_{z}]O₃

As can be seen from FIG. 78, when the x, y and z for the B-site elements fall within the ranges of 0.05≦x≦0.15, 0.25≦y≦0.5 and 0.35≦z≦0.6, respectively, the improvement effect on the piezoelectric properties can be enjoyed.

### Example 57

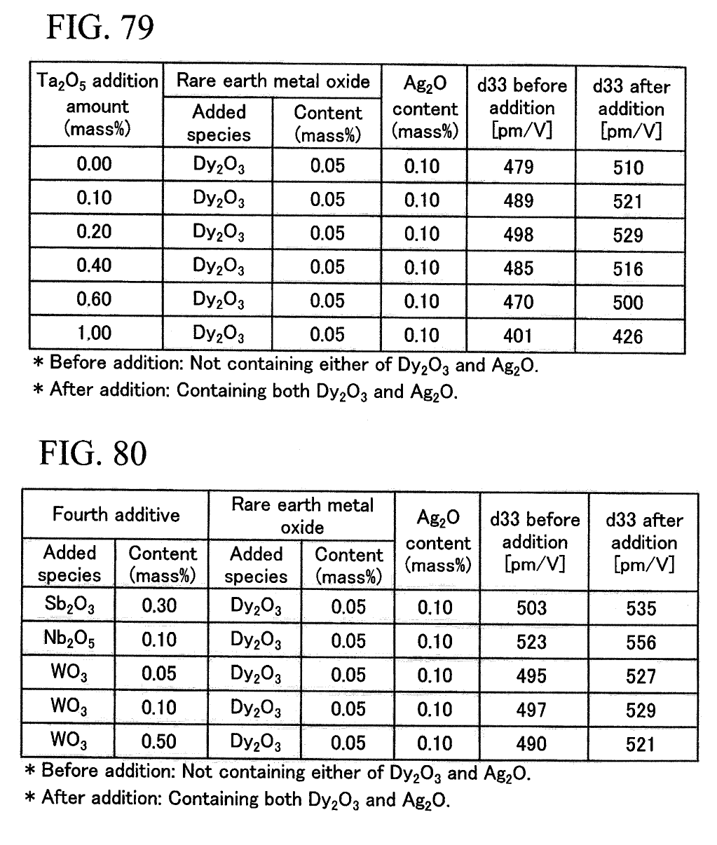

Samples were prepared in the same manner as in Example 51 except that the composition of the raw materials was adjusted so as for Ta₂O₅, Dy₂O₃ and Ag₂O, as the additives, to have the contents shown in FIG. 79, in relation to the main constituent shown below. The samples thus obtained were subjected to the piezoelectric constant d33 measurement in the same manner as in Example 51. The results thus obtained are shown in FIG. 79.

Main Constituent:
(Pb_{0.995-0.03}Sr_{0.03}) [(Zn_{1/3}Nb_{2/3})_{0.1}Ti_{0.43}Zr_{0.47}]O₃

As shown in FIG. 79, the addition of Ta₂O₅ as an additive can improve the piezoelectric constant d33. However, when the content of the Ta₂O₅ exceeds 0.6% by mass, the piezoelectric constant d33 becomes smaller than when Ta₂O₅ is not added. Accordingly, when Ta₂O₅ is contained, the content of Ta₂O₅ is set at 0.6% by mass or less. The content of Ta₂O₅ is preferably 0.05 to 0.4% by mass and more preferably 0.1 to 0.35% by mass.

### Example 58

Samples were prepared in the same manner as in Example 51 except that the composition of the raw materials was adjusted so as for the additives to have the contents shown in FIG. 80, in relation to the main constituent shown below. The samples thus obtained were subjected to the piezoelectric constant d33 measurement in the same manner as in Example 51. The results thus obtained are shown in FIG. 80.

Main Constituent:
(Pb_{0.995-0.03}Sr_{0.03}) [(Zn_{1/3}Nb_{2/3})_{0.1}Ti_{0.43}Zr_{0.47}]O₃

As shown in FIG. 80, the addition of Sb₂O₃, Nb₂O₅ or WO₃ can also enjoy the improvement effect on the piezoelectric properties according to the present invention.

### Example 59

Example 59 presents an example of the preparation of a laminated piezoelectric element.

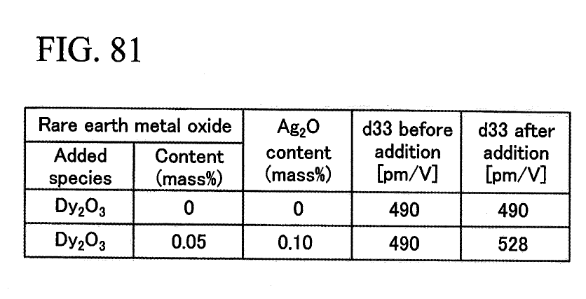

In the preparation of a laminated piezoelectric element, first, a calcined mixture (Dy₂O₃: 0.05% by mass, Ag₂O: 0.1% by mass) obtained in Example 1 was pulverized. The piezoelectric ceramic composition powder thus obtained was combined with a vehicle, and kneaded to yield a piezoelectric layer paste. An internal electrode layer paste was also prepared by kneading a Cu powder as the conductive material with a vehicle. Then, by using the piezoelectric layer paste and the internal electrode layer paste, a green chip as a precursor for a laminate was prepared by means of a printing method. The lamination number of the piezoelectric layer paste was set at 300. The green chip was subject to a binder removal treatment, and then sintered under reductive sintering conditions to yield a laminate. The reductive sintering conditions were such that sintering was carried out in a reductive atmosphere (oxygen partial pressure: 1×10⁻¹⁰ to 1×10⁻⁶ atm) at sintering temperatures of 800 to 1200° C. For comparison, another laminate was prepared in the same manner as described above except that neither Dy₂O₃ nor Ag₂O was added. The laminates thus obtained were subjected to the piezoelectric constant d33 measurement in the same manner as in Example 51. The results thus obtained are shown in FIG. 81.

What is claimed is:

1. A piezoelectric ceramic composition comprising:
a composite oxide, as a main constituent thereof, represented by (Pb_{a-b}Me_{b}) [(Zn_{1/3}Nb_{2/3})ₓTi_{y}Zr_{z}]O₃ with the proviso that
0.96≦a≦1.03,
0≦b≦0.1,
0.05≦x≦0.15,
0.25≦y≦0.5,
0.35≦z≦0.6, and
x+y+z=1, and
Me represents at least one selected from Sr, Ca and Ba; and
at least one selected from Co, Mg, Ni, Cr and Ga as a first additive to said main constituent in a content of 0.5% by mass or less (not inclusive of 0) in terms of oxide, wherein an electrode made of Cu is to be disposed on the piezoelectric ceramic composition.

2. The piezoelectric ceramic composition according to claim 1, comprising at least one selected from Co, Mg and Ga, as said first additive, in a content of 0.03 to 0.4% by mass in terms of oxide in relation to said main constituent.

3. The piezoelectric ceramic composition according to claim 1, further comprising a rare earth metal element, as a second additive, in a content of 0.15% by mass or less (not inclusive of 0) in terms of oxide in relation to said main constituent.

4. The piezoelectric ceramic composition according to claim 1, further comprising Ag, as a third additive, in a content of 0.08% by mass or less (not inclusive of 0) in terms of Ag₂O in relation to said main constituent.

5. The piezoelectric ceramic composition according to claim 1, further comprising in relation to said main constituent:
a rare earth metal element, as a second additive, in a content of 0.15% by mass or less (not inclusive of 0) in terms of oxide; and
Ag, as a third additive, in a content of 0.35% by mass or less (not inclusive of 0) in terms of Ag₂O.

6. The piezoelectric ceramic composition according to claim 5, comprising at least one selected from Ta, Sb, Nb and W, as a fourth additive, in a content of 1.0% by mass or less (not inclusive of 0) in terms of oxide in relation to said main constituent.

7. The piezoelectric ceramic composition according to claim 5, comprising Dy, as said second additive, in a content of 0.15% by mass or less in terms of oxide.

8. The piezoelectric ceramic composition according to claim 5, comprising a rare earth metal element, as said second additive, in a content of 0.02 to 0.1% by mass in terms of oxide.

9. The piezoelectric ceramic composition according to claim 5, comprising Ag, as said third additive, in a content of 0.02 to 0.25% by mass in terms of Ag₂O.

10. A laminated piezoelectric element comprising:
a plurality of piezoelectric layers; and
a plurality of internal electrode layers formed between said piezoelectric layers and comprising Cu as a conductive material, wherein:
said piezoelectric layers are formed of said piezoelectric ceramic composition according to claim 1.

11. The laminated piezoelectric element according to claim 10, further comprising a rare earth metal element, as a second additive, in a content of 0.15% by mass or less (not inclusive of 0) in terms of oxide in relation to said main constituent.

12. The laminated piezoelectric element according to claim 10, further comprising Ag, as a third additive, in a content of 0.08% by mass or less (not inclusive of 0) in terms of Ag₂O in relation to said main constituent.

13. The laminated piezoelectric element according to claim 10, further comprising in relation to said main constituent:
a rare earth metal element, as a second additive, in a content of 0.15% by mass or less (not inclusive of 0) in terms of oxide; and
Ag, as a third additive, in a content of 0.35% by mass or less (not inclusive of 0) in terms of Ag₂O.

14. The laminated piezoelectric element according to claim 10, wherein the Cu contained in said internal electrode layers has diffused into said piezoelectric layers.

15. A piezoelectric ceramic composition comprising:
a composite oxide, as a main constituent thereof, represented by (Pb_{a-b}Me_{b}) [(Zn_{1/3}Nb_{2/3})ₓTi_{y}Zr_{z}]O₃ with the proviso that
0.96≦a≦1.03,
0≦b≦0.1,
0.05≦x≦0.15,
0.25≦y≦0.5,
0.35≦z≦0.6, and
x+y+z=1, and Me represents at least one selected from Sr, Ca and Ba; and
at least one of the constituents represented by CuO_{α} (α≧0) in a content of 3.0% by mass or less (not inclusive of 0) in terms of CuO and a rare earth metal element in a content of 0.8% by mass or less (not inclusive of 0) in terms of oxide in relation to said main constituent.

16. A piezoelectric ceramic composition comprising:
a composite oxide, as a main constituent thereof, represented by (Pb_{a-b}Me_{b}) [(Zn_{1/3}Nb_{2/3})ₓTi_{y}Zr_{z}]O₃ with the proviso that
0.96≦a≦1.03,
0≦b≦0.1,
0.05≦x≦0.15,
0.25≦y≦0.5,
0.35≦z≦0.6, and
x+y+z=1, and Me represents at least one selected from Sr, Ca and Ba; and
Cu in a content of 1.0% by mass or less (not inclusive of 0) in terms of Cu₂O and Ag in a content of 0.5% by mass or less (not inclusive of 0) in terms of Ag₂O, in relation to said main constituent.

17. A piezoelectric ceramic composition comprising:
a composite oxide, as a main constituent thereof, represented by (Pb_{a-b}Me_{b}) [(Zn_{1/3}Nb_{2/3})ₓTi_{y}Zr_{z}]O₃ with the proviso that
0.96≦a≦1.03,
0≦b≦0.1,
0.05≦x≦0.15,
0.25≦y≦0.5,
0.35≦z≦0.6, and
x+y+z=1, and Me represents at least one selected from Sr, Ca and Ba; and
a rare earth metal element in a content of 0.15% by mass or less (not inclusive of 0) in terms of oxide and Ag in a content of 0.35% by mass or less (not inclusive of 0) in terms of Ag₂O, in relation to said main constituent.
